(19) United States
(12) Patent Application Publication
(10) Pub. No.: US 2024/0240024 A1
(43) Pub. Date: Jul. 18, 2024

(54) PHOTOSENSITIVE RESIN COMPOSITION, PHOTOSENSITIVE RESIN LAYER USING THE SAME, AND COLOR FILTER

(71) Applicant: SAMSUNG SDI CO., LTD., Yongin-si (KR)

(72) Inventors: Heejo MOON, Suwon-si (KR); Chang-Hyun KWON, Suwon-si (KR); Juho JUNG, Suwon-si (KR); Baek Soung PARK, Suwon-si (KR)

(21) Appl. No.: 18/382,734

(22) Filed: Oct. 23, 2023

(30) Foreign Application Priority Data
Dec. 23, 2022 (KR) 10-2022-0183423

(51) Int. Cl. C09B 57/00; C09B 67/20; C09D 4/06; C09D 5/32; C09D 7/41; C09D 7/45; C09D 7/63; C09D 133/06; G02B 1/04; G03F 7/038

(52) U.S. Cl. CPC C09B 57/007; C09B 67/0063; C09D 4/06; C09D 5/32; C09D 7/41; C09D 7/45; C09D 7/63; C09D 133/064; G02B 1/04; G03F 7/0382; G02B 5/22

(57) ABSTRACT

A photosensitive resin composition, a photosensitive resin layer, and a color filter manufactured using the same, the photosensitive resin composition includes a colorant; a photopolymerizable compound; a photopolymerization initiator; a binder resin; and a solvent; wherein the colorant includes a pigment, a dispersant, and a dispersion aid represented by Chemical Formula 1,

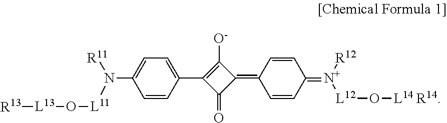

### CROSS-REFERENCE TO RELATED APPLICATION

This application claims priority to and the benefit of Korean Patent Application No. 10-2022-0183423 filed in the Korean Intellectual Property Office on Dec. 23, 2022, the entire contents of which are incorporated herein by reference.

### BACKGROUND

### 1. Field

Embodiments relate to a photosensitive resin composition, a photosensitive resin layer using the same, and a color filter.

### 2. Description of the Related Art

A liquid crystal display device among many types of displays has an advantage of lightness, thinness, low cost, low power consumption for operation, and improved adherence to an integrated circuit and has been used for a laptop computer, a monitor, and a TV screen.

The liquid crystal display device may include a lower substrate on which a black matrix, a color filter, and an ITO pixel electrode are formed, and an upper substrate on which an active circuit portion including a liquid crystal layer, a thin film transistor, and a capacitor layer and an ITO pixel electrode are formed.

Color filters may be formed in a pixel region by sequentially stacking a plurality of color filters (e.g., formed of three primary colors red (R), green (G), and blue (B)) in a predetermined order to form each pixel, and a black matrix layer may be disposed in a predetermined pattern on a transparent substrate to form a boundary between the pixels.

A pigment dispersion method (e.g., one of methods of forming a color filter) may provide a colored thin film by repeating a series of processes such as coating a photopolymerizable composition including a colorant on a transparent substrate including a black matrix, exposing a formed pattern to light, removing a non-exposed part with a solvent, and thermally curing the same.

### SUMMARY

The embodiments may be realized by providing a photosensitive resin composition including a colorant; a photopolymerizable compound; a photopolymerization initiator; a binder resin; and a solvent; wherein the colorant includes a pigment, a dispersant, and a dispersion aid represented by Chemical Formula 1,

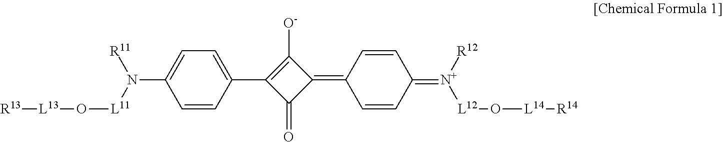

in Chemical Formula 1, R¹¹ and R¹² are each independently a substituted or unsubstituted C1 to C20 alkyl group, a substituted or unsubstituted C3 to C20 cycloalkyl group, a substituted or unsubstituted C6 to C20 aryl group, or a substituted or unsubstituted C2 to C20 heteroaryl group, R¹³ and R¹⁴ are each independently *—SO₃⁻, *—COOH, *—N(R^{a})₂, *—N⁺(R^{b})₃, or a N-phthalimidyl group, R^{a} and R^{b} are each independently a hydrogen atom or a substituted or unsubstituted C1 to C20 alkyl group, L¹¹ and L¹² are each independently a substituted or unsubstituted C6 to C20 arylene group, and L¹³ and L¹⁴ are each independently a substituted or unsubstituted C1 to C20 alkylene group.

The embodiments may be realized by providing a photosensitive resin layer manufactured using the photosensitive resin composition according to an embodiment.

The embodiments may be realized by providing a color filter including the photosensitive resin layer according to an embodiment.

The embodiments may be realized by providing a display device including the color filter according to an embodiment.

### DETAILED DESCRIPTION OF THE EMBODIMENTS

Example embodiments will now be described more fully hereinafter; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. As used herein, the term “or” is not necessarily an exclusive term, e.g., “A or B” would include A, B, or A and B.

As used herein, when specific definition is not otherwise provided, “substituted” refers to replacement of at least one hydrogen atom of a compound by a substituent of a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C30 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, or a combination thereof.

As used herein, when specific definition is not otherwise provided, “heteroaryl group” means that at least one hetero atom of N, O, S or P is present in each aryl ring compound.

As used herein, when specific definition is not otherwise provided, a “heterocycloalkyl group”, a “heterocycloalkenyl group”, a “heterocycloalkynyl group,” and a “heterocycloalkylene group” refer to each cyclic compound of cycloalkyl, cycloalkenyl, cycloalkynyl, and cycloalkylene including at least one heteroatom of N, O, S, or P.

As used herein, when specific definition is not otherwise provided, “(meth)acrylate” refers to both “acrylate” and “methacrylate”.

As used herein, when a definition is not otherwise provided, the term “combination” refers to mixing or copolymerization. Additionally, “copolymerization” refers to block copolymerization to random copolymerization, and “copolymer” refers to block copolymerization to random copolymerization.

As used herein, when a definition is not otherwise provided, hydrogen is bonded at the position when a chemical bond is not drawn where supposed to be given.

As used herein, when specific definition is not otherwise provided, “**” refers to a linking point with the same or different atom or chemical formula.

As used herein, when a definition is not otherwise provided, “particle diameter” may mean a diameter of a particle, and the diameter of the particle may be a Z-average value of the particle diameter measured through dynamic light scattering.

### (Photosensitive Resin Composition)

Some example embodiments provide a photosensitive resin composition including, e.g., (A) a colorant; (B) a photopolymerizable compound; (C) a photopolymerization initiator; (D) a binder resin; and (E) a solvent. In an implementation, the colorant may include, e.g., a pigment, a dispersant, and a dispersion aid represented by Chemical Formula 1.

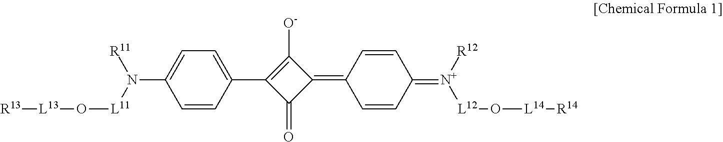

In Chemical Formula 1, R¹¹ and R¹² may each independently be or include, e.g., a substituted or unsubstituted C1 to C20 alkyl group, a substituted or unsubstituted C3 to C20 cycloalkyl group, a substituted or unsubstituted C6 to C20 aryl group, or a substituted or unsubstituted C2 to C20 heteroaryl group. R¹³ and R¹⁴ may each independently be or include, e.g., *—SO₃⁻, *—COOH, *—N(R^{a})₂, *—N⁺(R^{b})₃, or a N-phthalimidyl group. R^{a} and R^{b} may each independently be or include, e.g., a hydrogen atom or a substituted or unsubstituted C1 to C20 alkyl group. L¹¹ and L¹² may each independently be or include, e.g., a substituted or unsubstituted C6 to C20 arylene group. L¹³ and L¹⁴ may each independently be or include, e.g., a substituted or unsubstituted C1 to C20 alkylene group.

### (A) Colorant

The photosensitive resin composition of some example embodiments may be a pigment-type photosensitive resin composition, and the colorant may include a pigment. A color filter manufactured by using a pigment-type photosensitive resin composition could have a limit in terms of luminance and a contrast ratio caused by a pigment particle size. In order to be applied to image sensors, a resin composition made of smaller particles may be required to form fine patterns. In order to achieve this, a compound and a composition using the same that helps disperse the pigment and prevent re-agglomeration may be implemented.

In an implementation, the colorant may include the dispersion aid represented by Chemical Formula 1. In an implementation, the dispersion aid represented by Chemical Formula 1 may have both benzene rings of a squarene (SQ) mother moiety substituted with *-L¹¹-O-L¹³-R¹³ and *-L¹²-O-L¹⁴-R¹⁴, respectively, and thus may interact with the pigment, the dispersant, or both. In an implementation, in the dispersion aid represented by Chemical Formula 1, *-L¹¹-O-L¹³-R¹³ and the *-L¹²-O-L¹⁴-R¹⁴ may be covalently bonded with the dispersant or dispersion resin, and the phthalocyanine mother moiety may be covalently bonded with the pigment, and thus it may help an interaction between the pigment and the dispersant. In an implementation, it is possible to implement a photosensitive resin composition that has high dispersibility and dispersion stability of the pigment and has excellent coloring power and contrast ratio when implementing a color filter. In an implementation, in the dispersion aid represented by Chemical Formula 1, the squarene mother moiety may express a green color, so that when implementing a color filter of a photosensitive resin composition containing it, the green coloring power and contrast ratio may be further improved.

In an implementation, the dispersion aid represented by Chemical Formula 1 may function as a dispersion aid and as a coloring aid. By using the photosensitive resin composition according to some example embodiments including this, a color filter and display device with excellent color reproducibility and contrast ratio may be implemented.

Descriptions of each substituent in Chemical Formula 1 is as follows.

L¹¹ and L¹² may each independently be or include, e.g., a substituted or unsubstituted C6 to C20 arylene group.

In an implementation, both L¹¹ and L¹² may include a phenylene group. In an implementation, the dispersion aid may be represented by Chemical Formula 1-1.

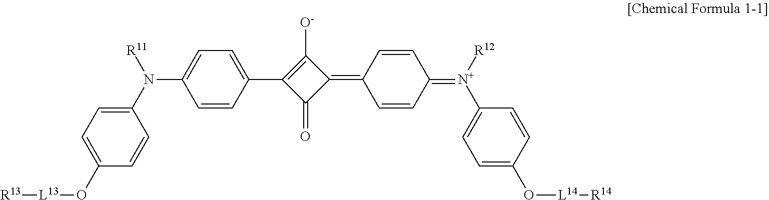

In Chemical Formula 1-1, the definition of each substituent may be the same as those described above.

L¹³ and L¹⁴ may each independently be, e.g., a substituted or unsubstituted C2 to C20 alkylene group.

In an implementation, L¹³ and L¹⁴ may each independently be, e.g., a substituted or unsubstituted C4 to C6 alkylene group.

R¹¹ and R¹² may each independently be, e.g., a substituted or unsubstituted C1 to C20 alkyl group, a substituted or unsubstituted C3 to C20 cycloalkyl group, a substituted or unsubstituted C6 to C20 aryl group, or a substituted or unsubstituted C2 to C20 heteroaryl group.

In an implementation, R¹¹ and R¹² may each independently be, e.g., C5 or C6 cycloalkyl group.

R¹³ and R¹⁴ may each independently be, e.g., *—SO₃⁻, *—COOH, *—N(R^{a})₂, *—N⁺(R^{b})₃, or a N-phthalimidyl group. In an implementation, R^{a} may be, e.g., a hydrogen atom or substituted or unsubstituted C1 to C20 alkyl group, and RD may be, e.g., a hydrogen atom or substituted or unsubstituted C1 to C20 alkyl group.

In an implementation, R¹³ and R¹⁴ may each independently be, e.g., *—SO₃⁻, *—COOH, *—NH₂, *—N(CH₂CH₃)₂, *—N⁺H₃, *—N⁺(CH₂CH₃)₃, or N-phthalimidyl group.

In an implementation, the dispersion aid may be represented by Chemical Formula 1, and it may have a symmetric structure or an asymmetric structure. In an implementation, a symmetric structure may be advantageous over an asymmetric structure in that the synthesis step may be short and easy, thereby lowering the manufacturing cost.

In an implementation the dispersion aid may be represented by one of the following chemical formulae.

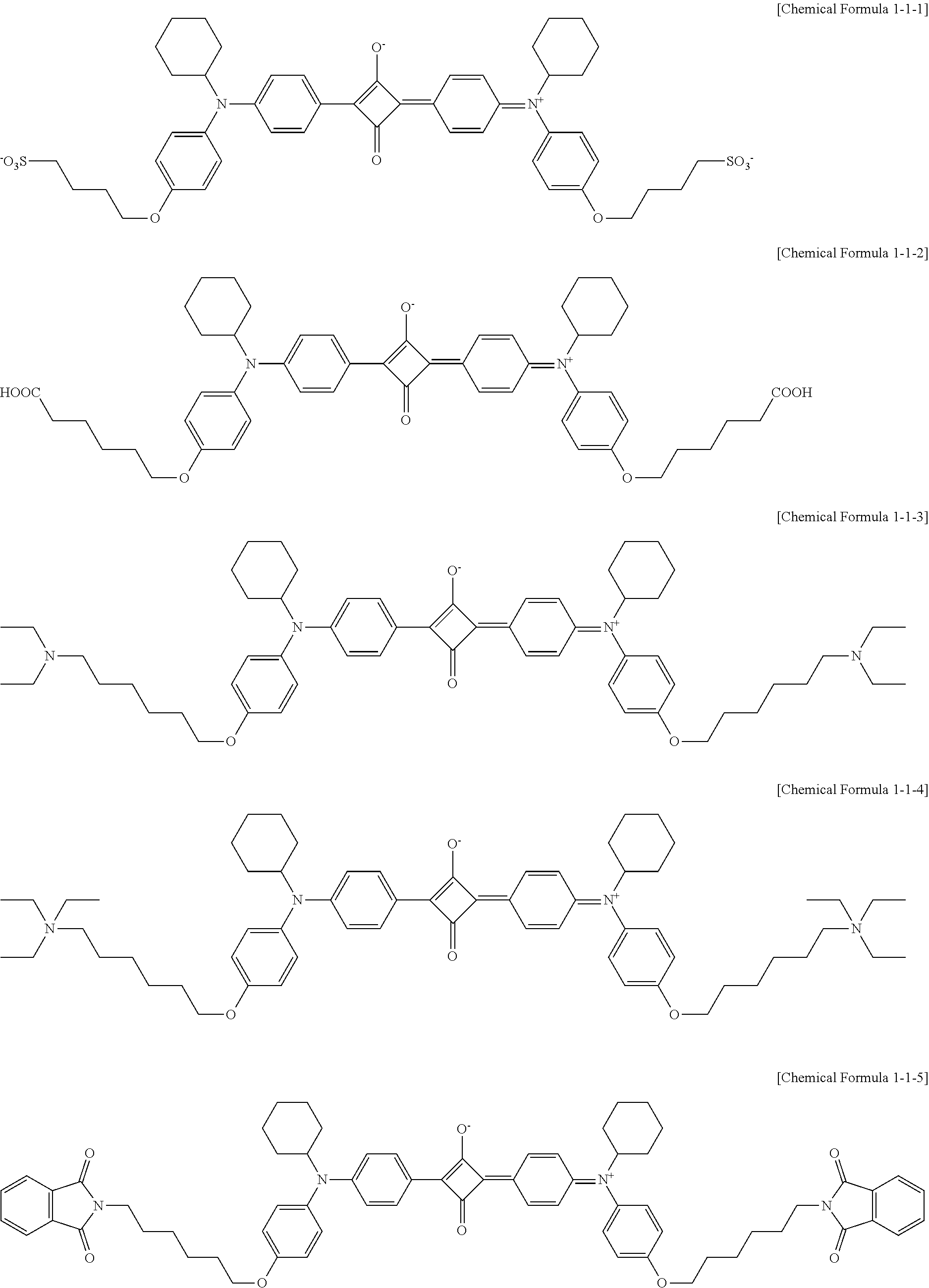

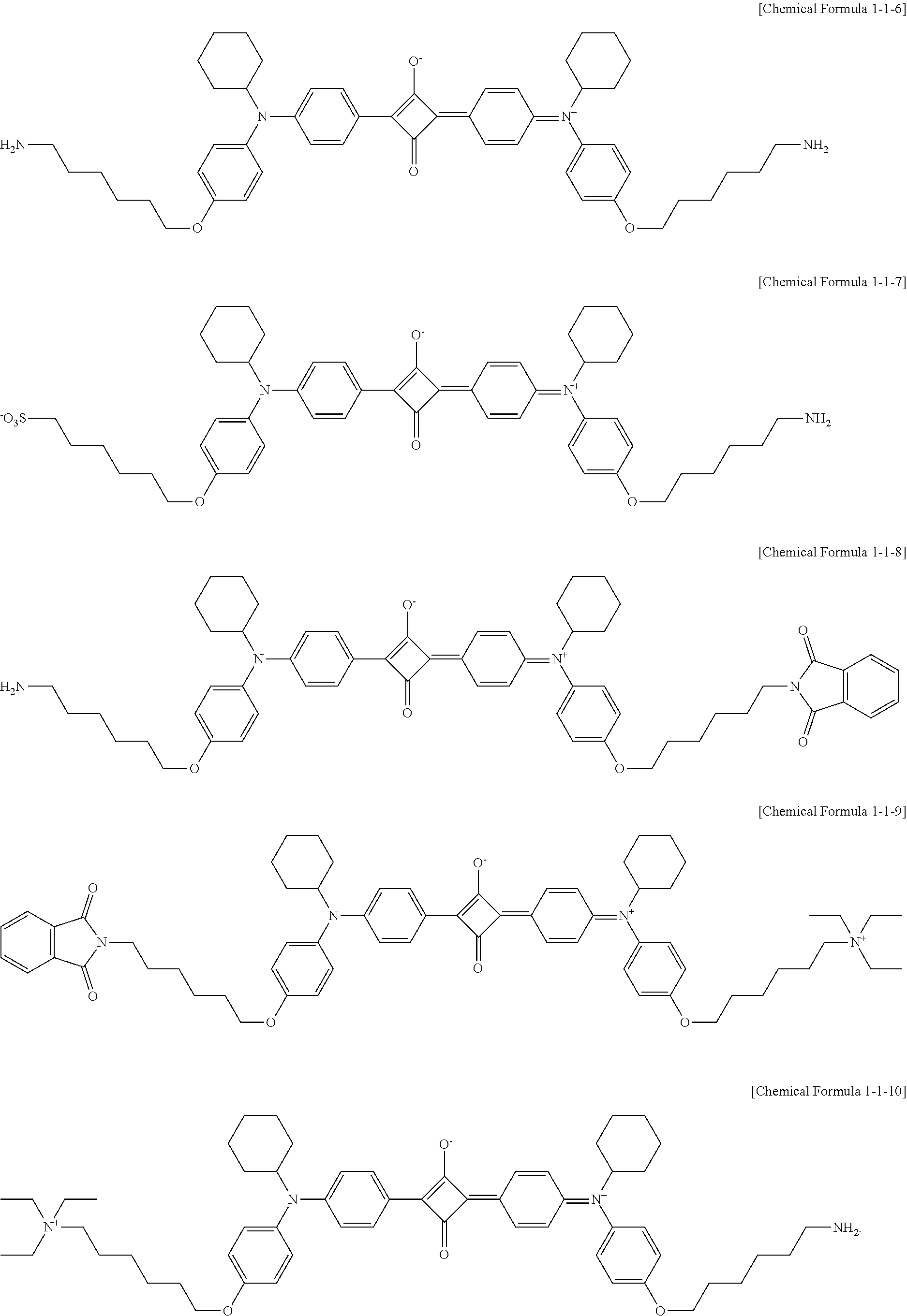

In an implementation, the dispersion aid may be a compound with a core-shell structure in which the shell, which is a macrocyclic compound, surrounds the compound represented by Chemical Formula 1.

In an implementation, the dispersion aid may include the compound represented by Chemical Formula 1 as a core and may further include a shell surrounding the core. In an implementation, the shell may be a compound represented by Chemical Formula 2.

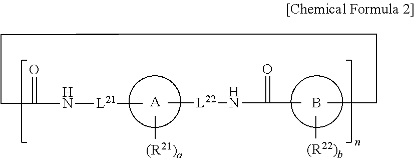

In Chemical Formula 2, A and B may each independently be or include, e.g., a benzene ring, a pyridine ring, or a furan ring. R²¹ and R²² may each independently be or include, e.g., a halogen atom or a substituted or unsubstituted C1 to C10 alkyl group. L²¹ and L²² may each independently be or include, e.g., a substituted or unsubstituted C1 to C20 alkylene group or a substituted or unsubstituted C6 to C20 arylene group. a and b may each independently be, e.g., an integer of 0 to 4. n may be, e.g., an integer of 2 to 10.

A description of each substituent in Chemical Formula 2 may be as follows.

In Chemical Formula 2, A and B may each independently be, e.g., a benzene ring, a pyridine ring, or a furan ring.

In an implementation, A may be a benzene ring, and B may be a benzene ring, a pyridine ring, or a furan ring. In an implementation, the shell may be represented by one of Chemical Formulas 2-1 to 2-3.

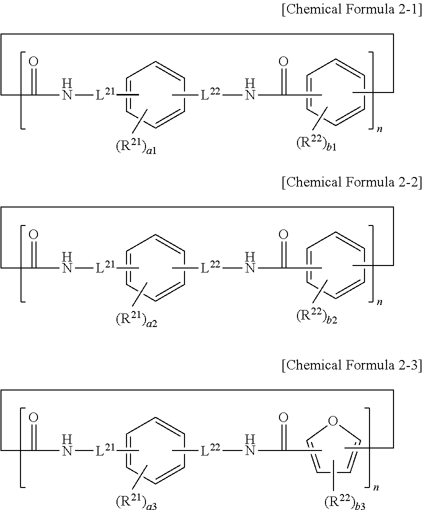

In Chemical Formulas 2-1 to 2-3, R²¹ and R²² may each independently be, e.g., a halogen atom. L²¹ and L²² may each independently be, e.g., a substituted or unsubstituted C1 to C20 alkylene group. a1 and b1 may each independently be, e.g., an integer of 0 to 3. a2 and b2 may each independently be, e.g., an integer of 0 to 4. a3 and b3 may each independently be, e.g., an integer of 0 to 2. n may be, e.g., an integer of 2 to 10.

L²¹ and L²² may each independently be, e.g., a substituted or unsubstituted C1 to C20 alkylene group or a substituted or unsubstituted C6 to C20 arylene group.

In an implementation, L²¹ and L²² may each independently be, e.g., a substituted or unsubstituted C1 alkylene group (e.g., *—CH₂—*).

R²¹ and R²² may each independently be, e.g., a halogen atom or a substituted or unsubstituted C1 to C10 alkyl group. In an implementation, both R²¹ and R²² may be fluorine atoms.

n may be an integer of 2 to 10, e.g., 2.

Representative examples of such shells may be as follows.

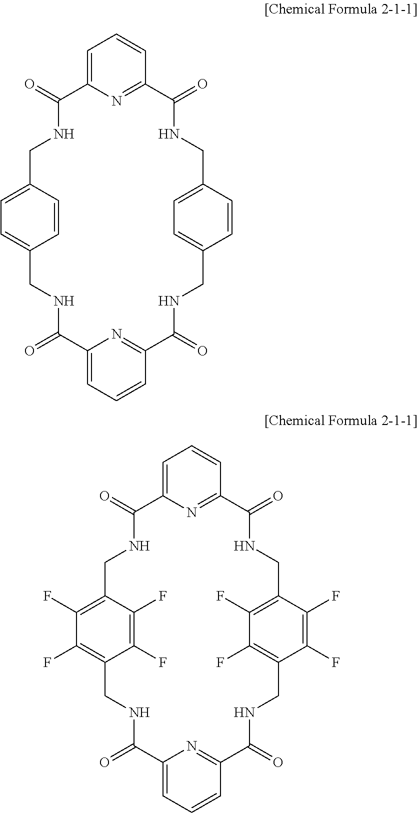 [SMILES: O=C1NCc2ccc(cc2)CNC(=O)c2cccc(n2)C(=O)NCc2ccc(cc2)CNC(=O)c2cccc1n2 ; O=C1NCc2c(F)c(F)c(c(F)c2F)CNC(=O)c2cccc(n2)C(=O)NCc2c(F)c(F)c(c(F)c2F)CNC(=O)c2cccc1n2]

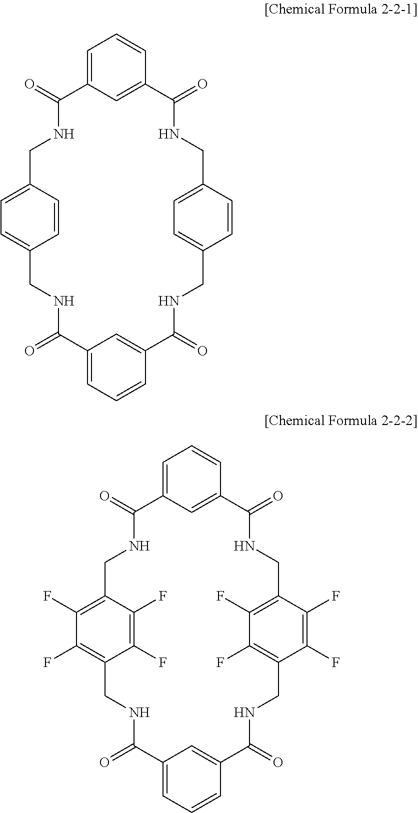 [SMILES: O=C1NCc2ccc(cc2)CNC(=O)c2cccc(c2)C(=O)NCc2ccc(cc2)CNC(=O)c2cccc1c2 ; O=C1NCc2c(F)c(F)c(c(F)c2F)CNC(=O)c2cccc(c2)C(=O)NCc2c(F)c(F)c(c(F)c2F)CNC(=O)c2cccc1c2]

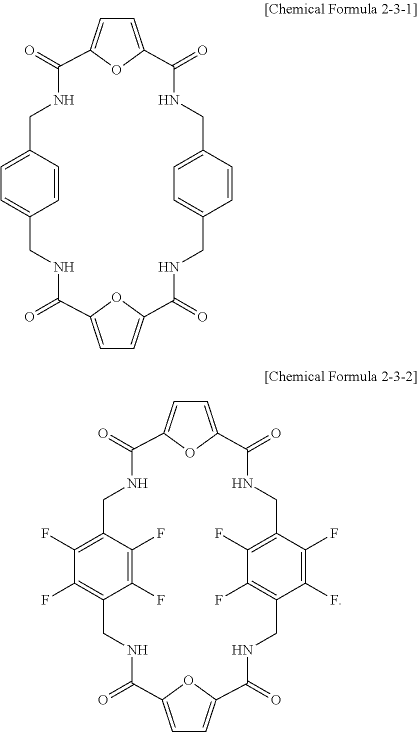 [SMILES: O=C1NCc2ccc(cc2)CNC(=O)c2ccc(o2)C(=O)NCc2ccc(cc2)CNC(=O)c2ccc1o2 ; O=C1NCc2c(F)c(F)c(c(F)c2F)CNC(=O)c2ccc(o2)C(=O)NCc2c(F)c(F)c(c(F)c2F)CNC(=O)c2ccc1o2]

In an implementation, the dispersion aid may be a core-shell structured compound. In an implementation, the core-shell structured compound may be represented by one of the following Chemical Formulae.

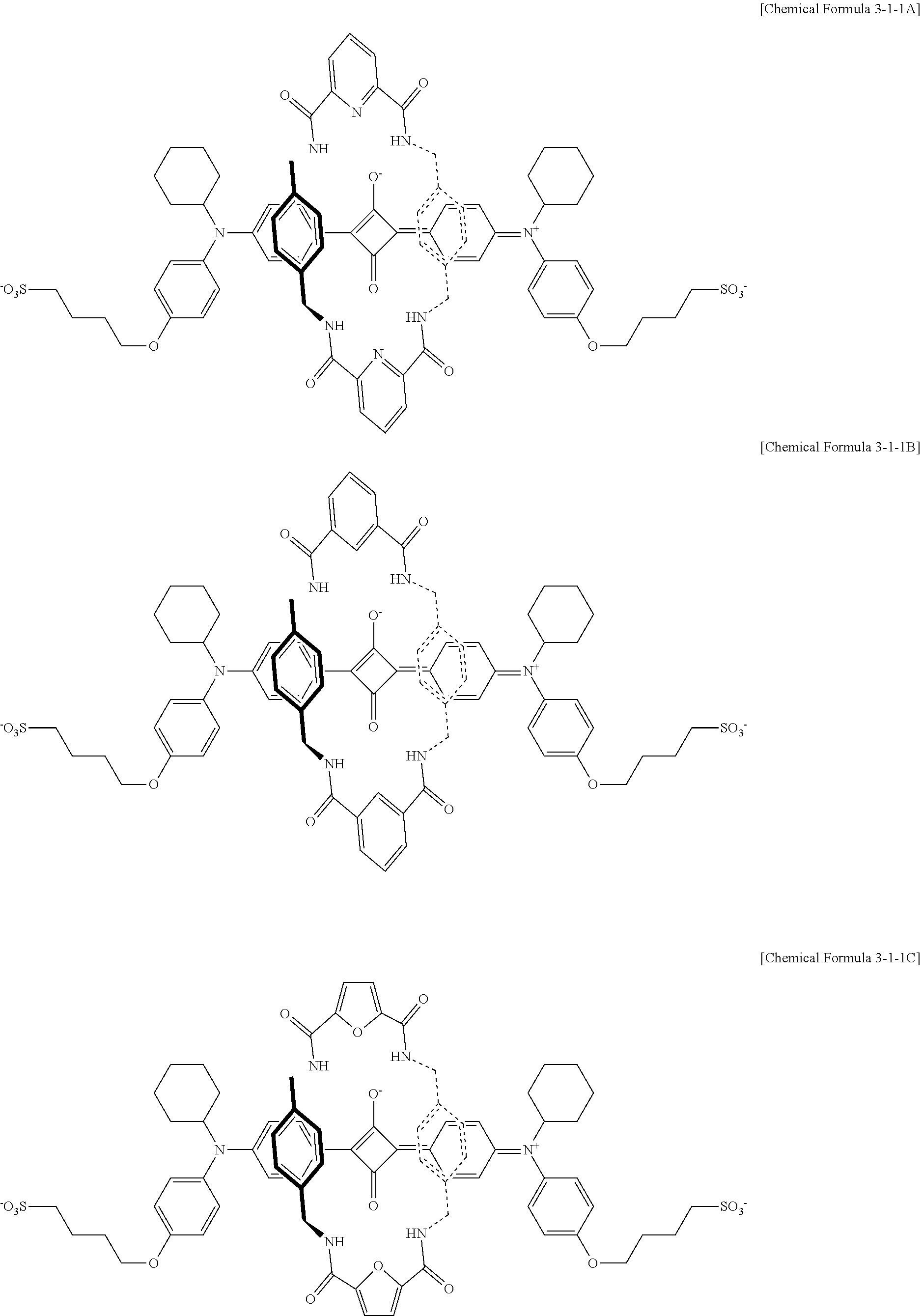

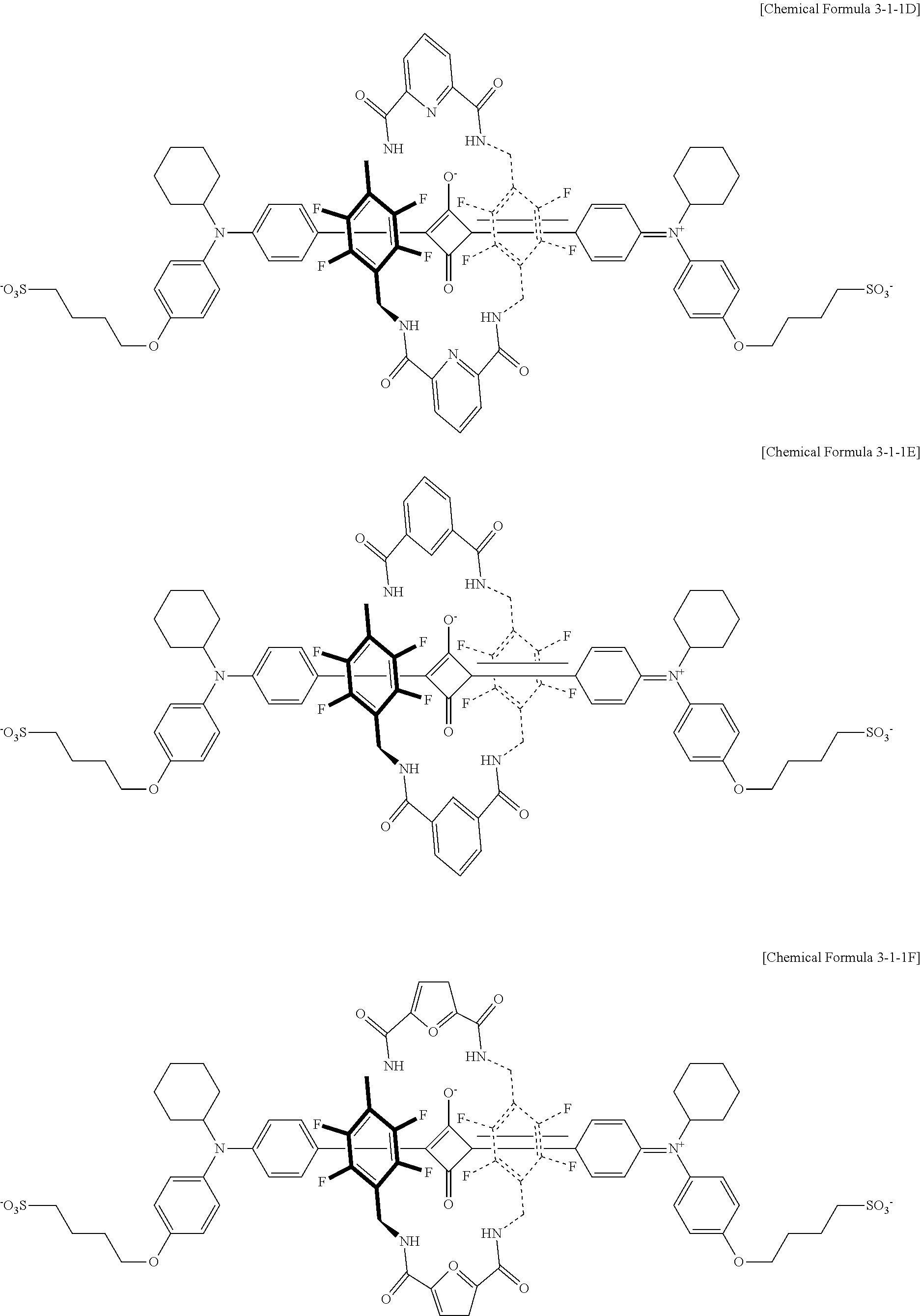

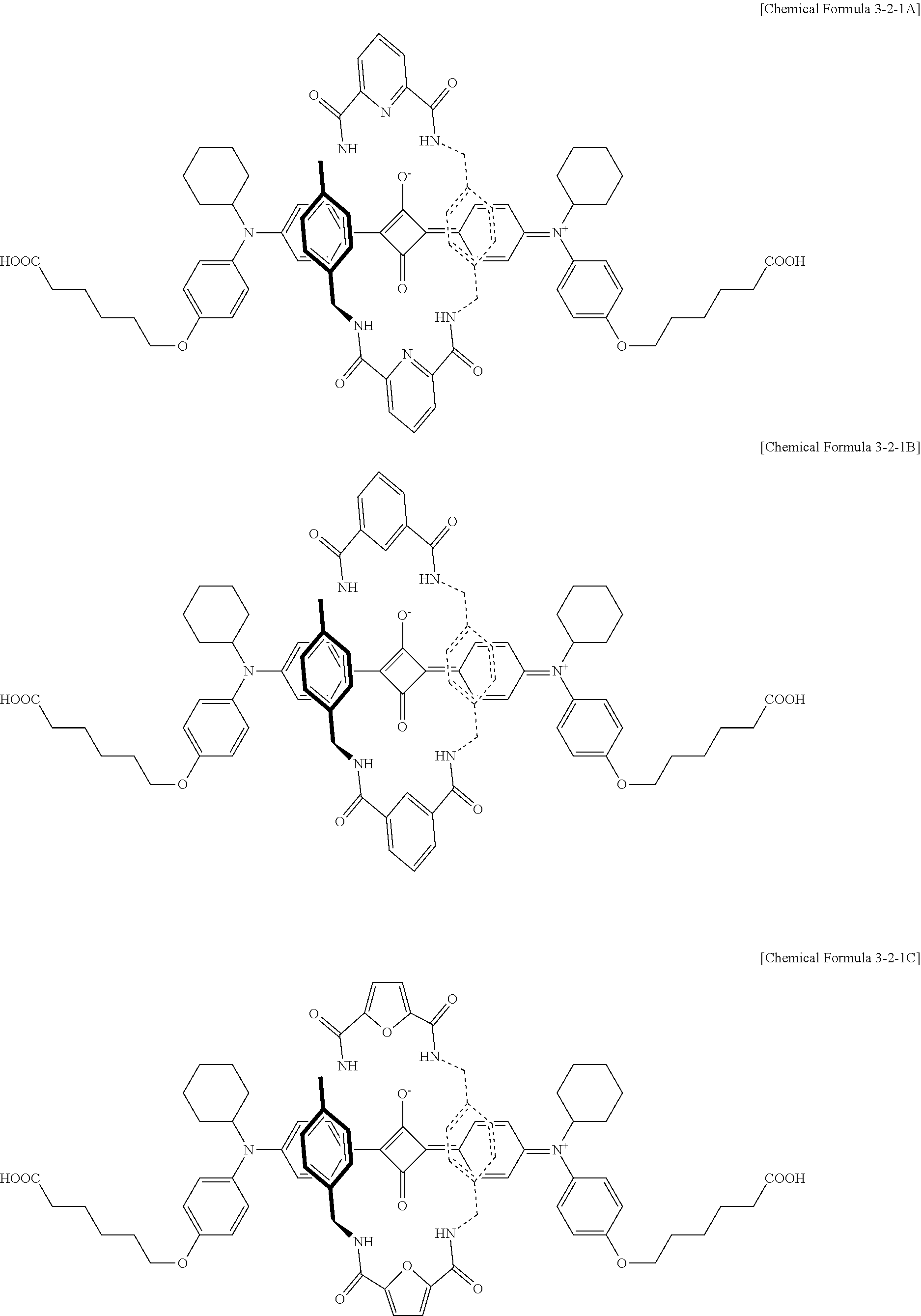

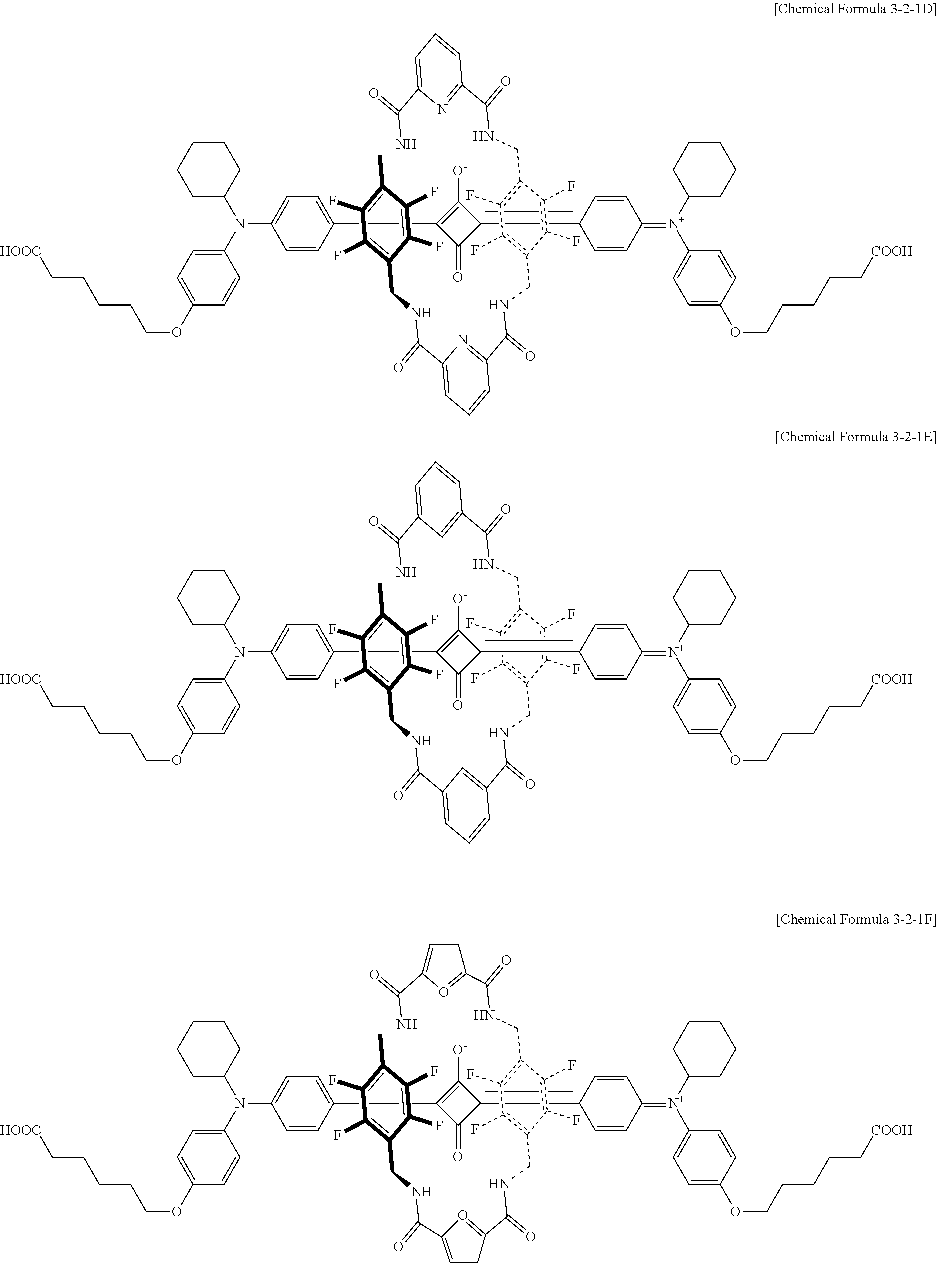

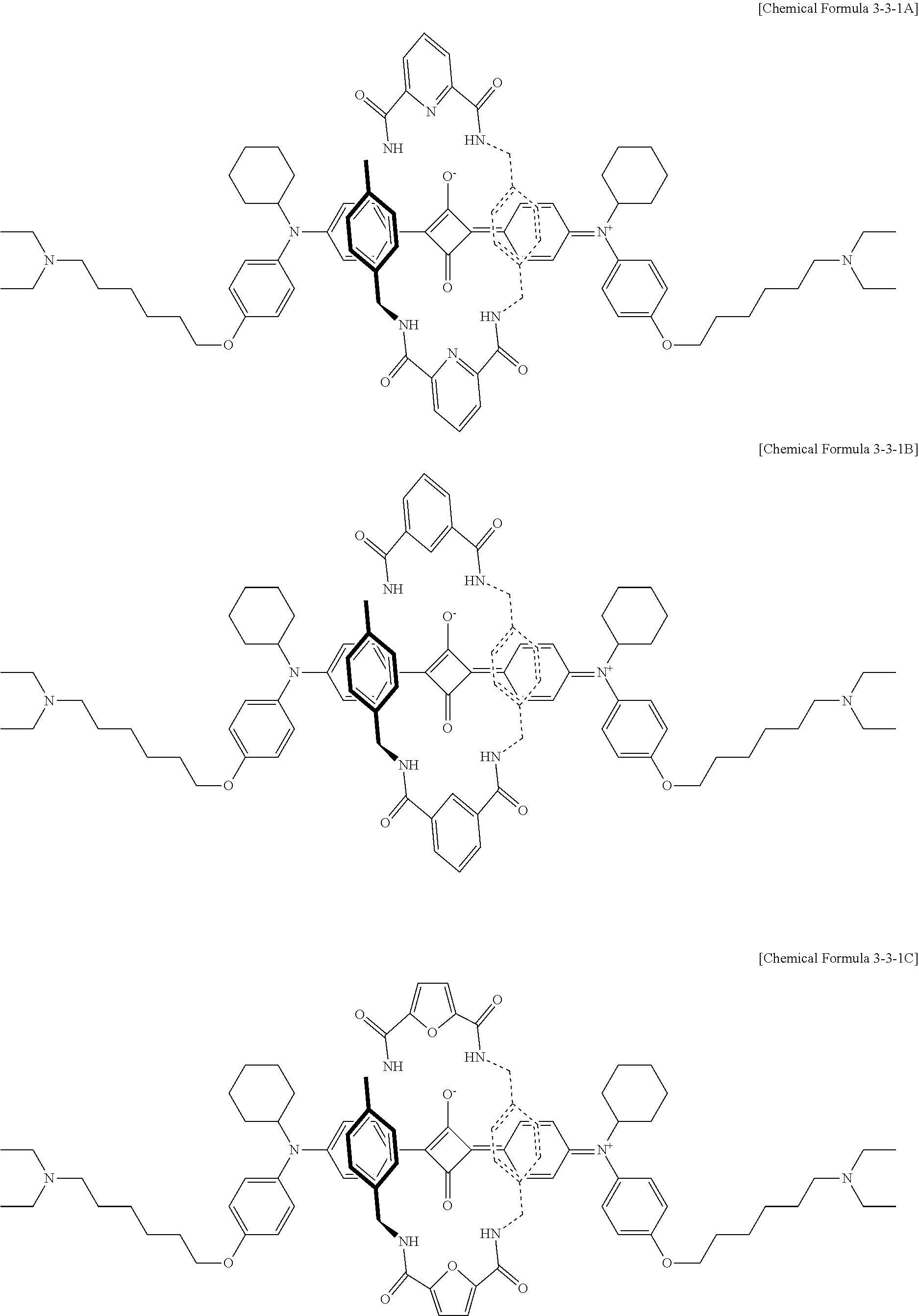

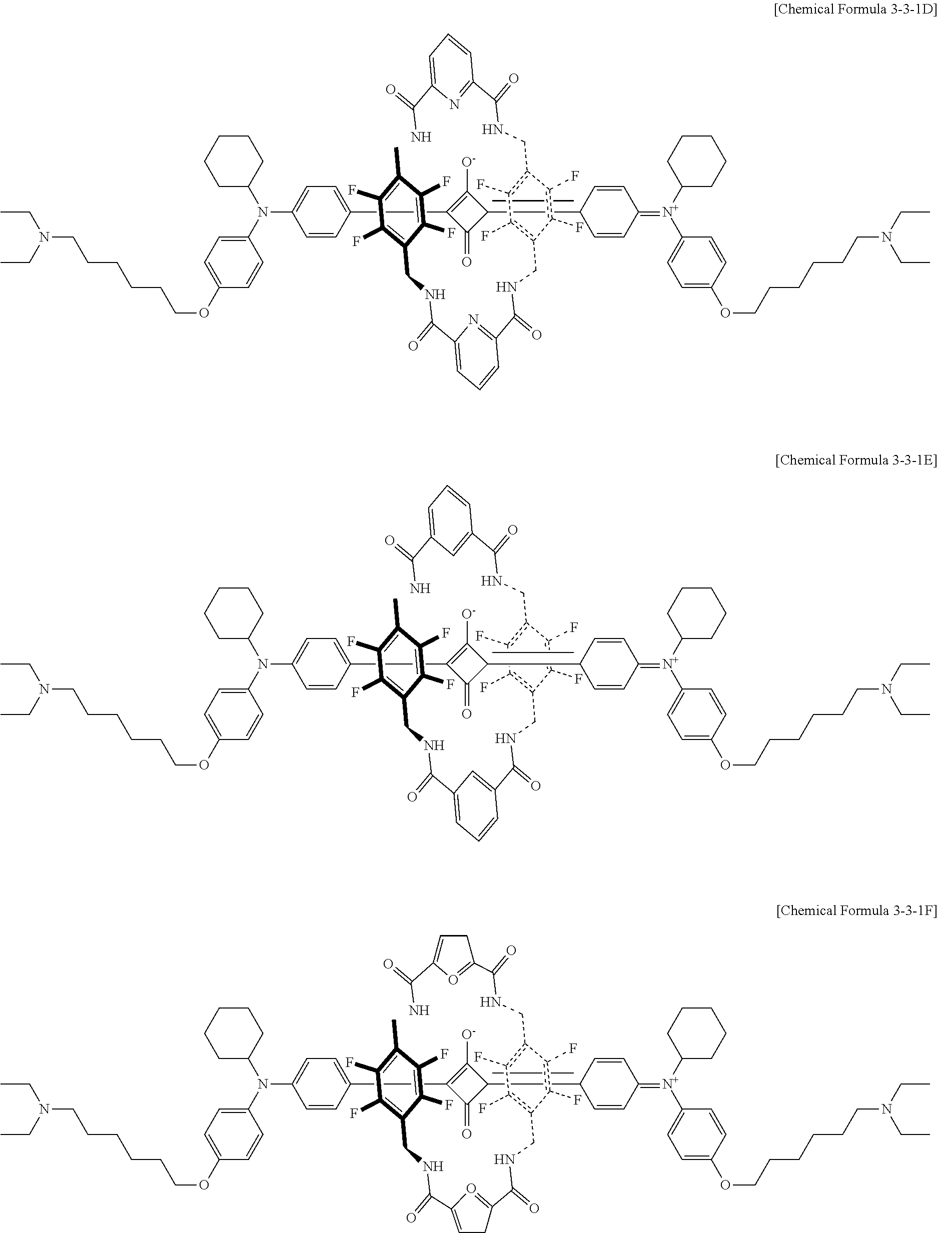

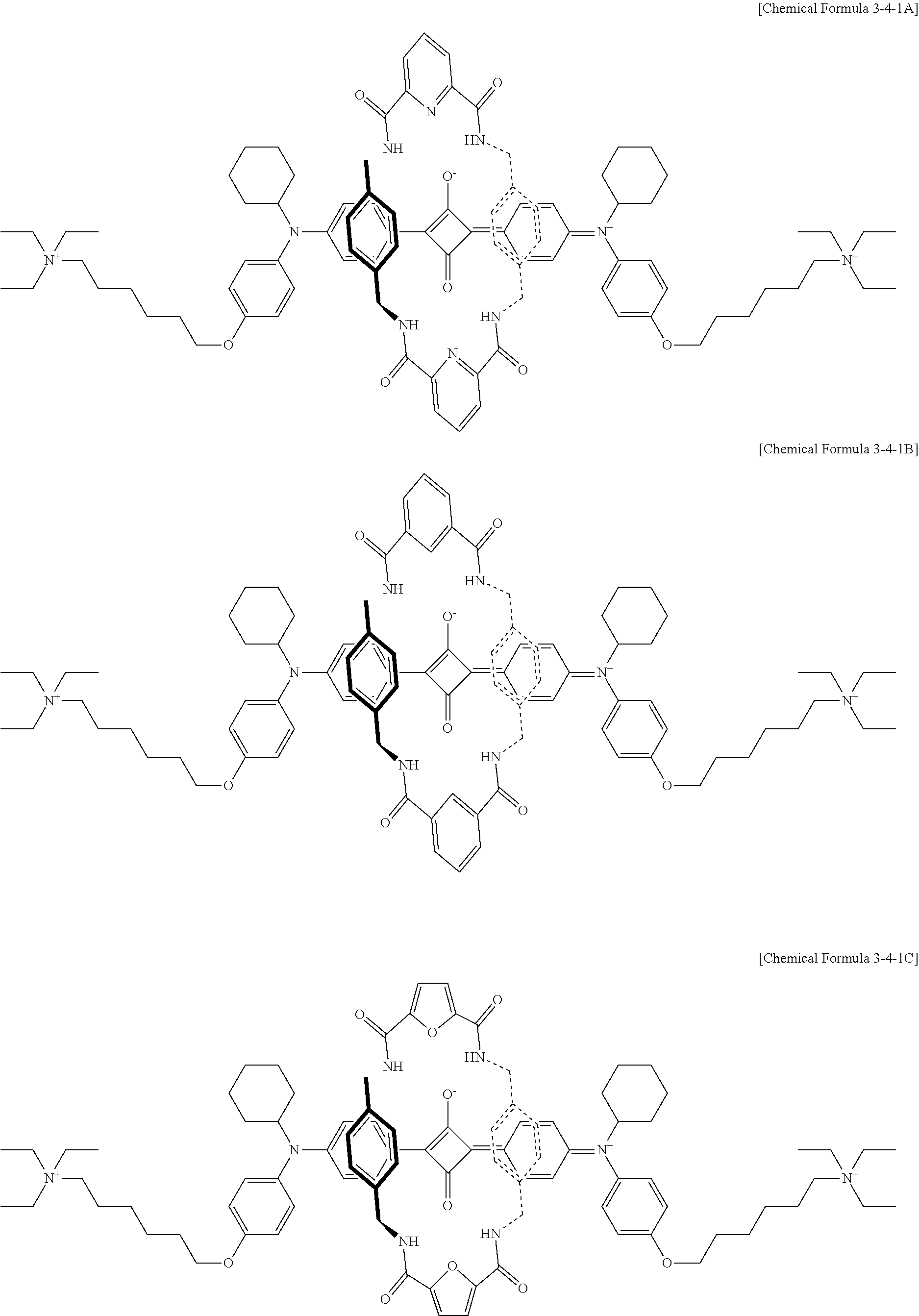

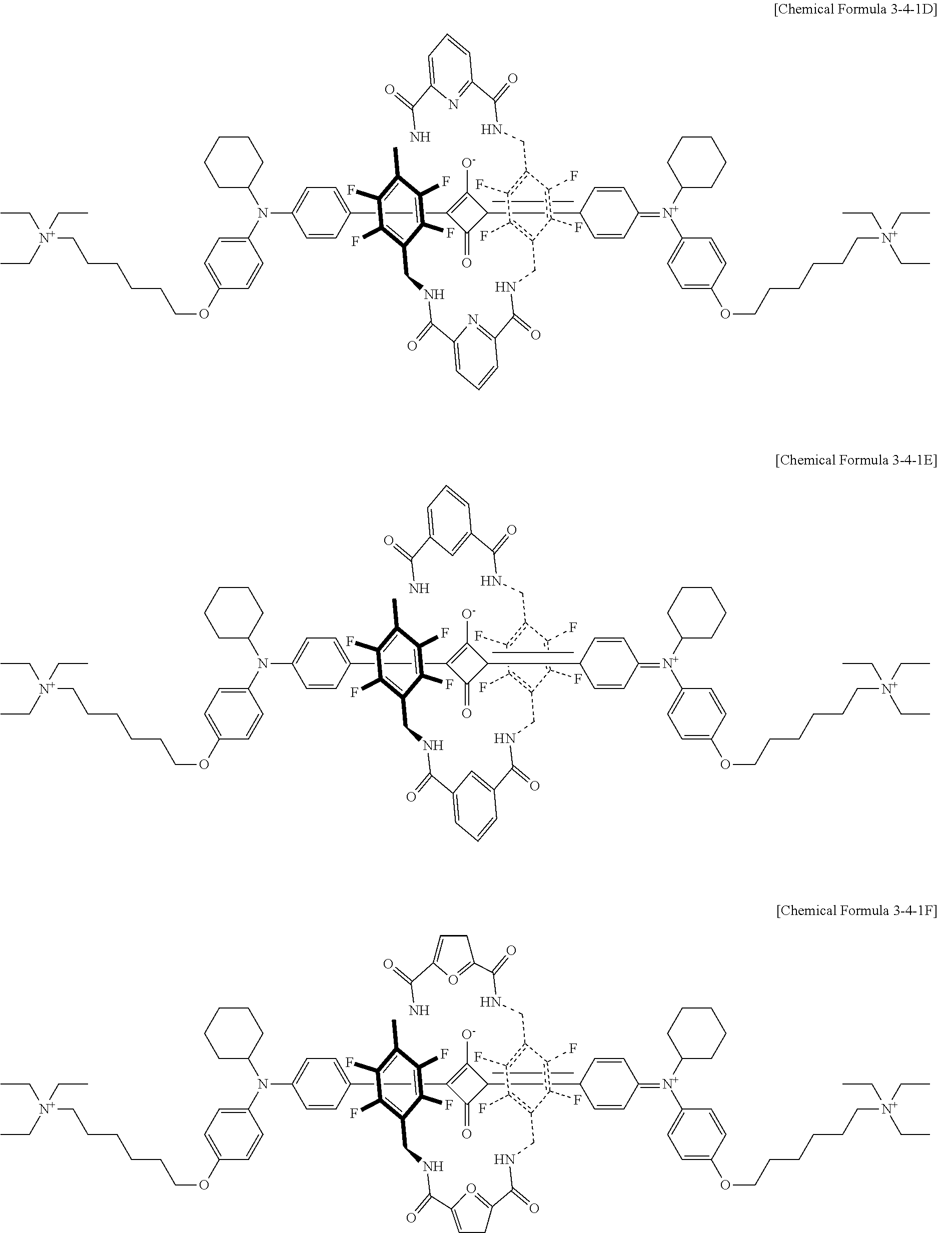

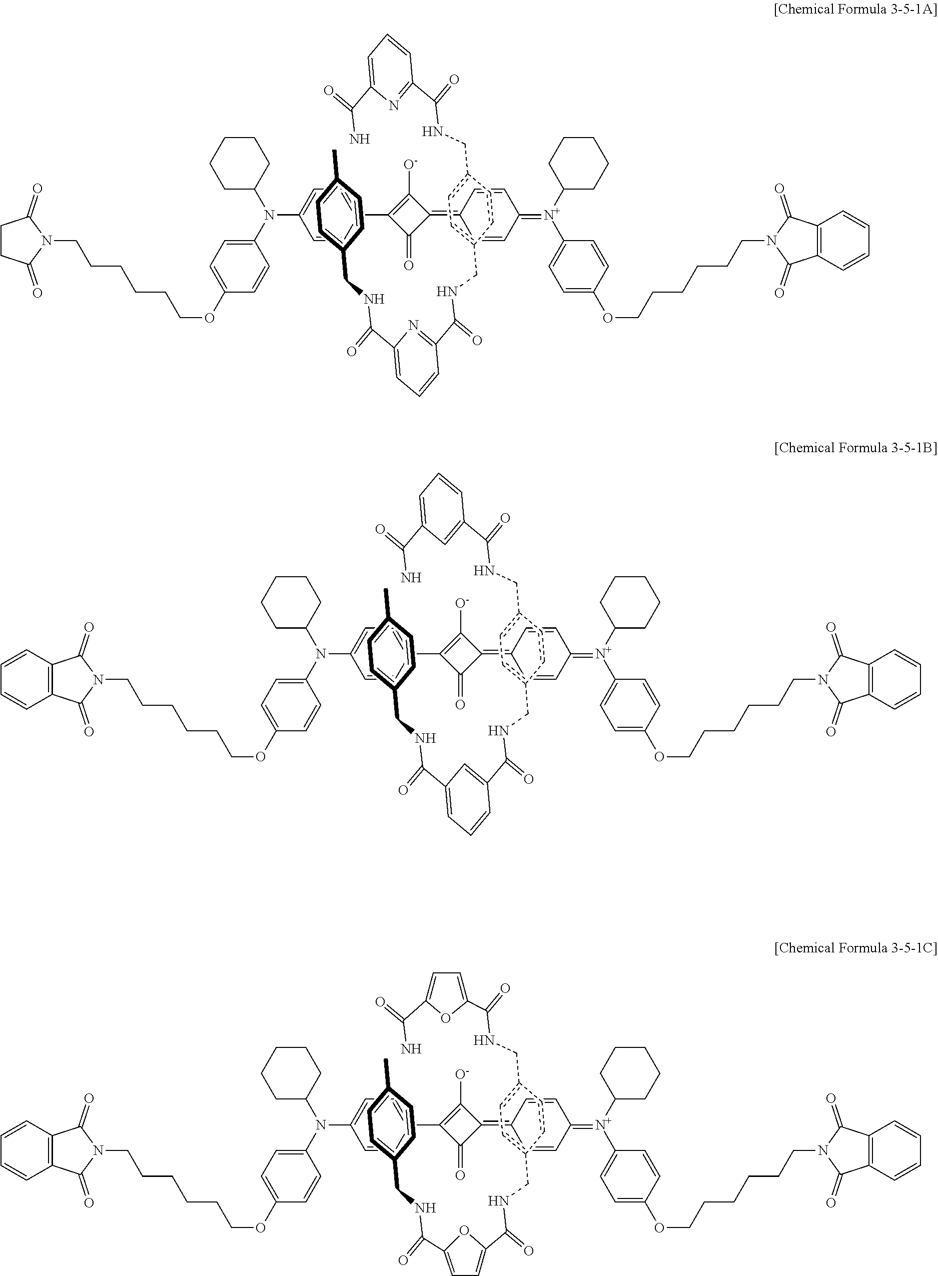

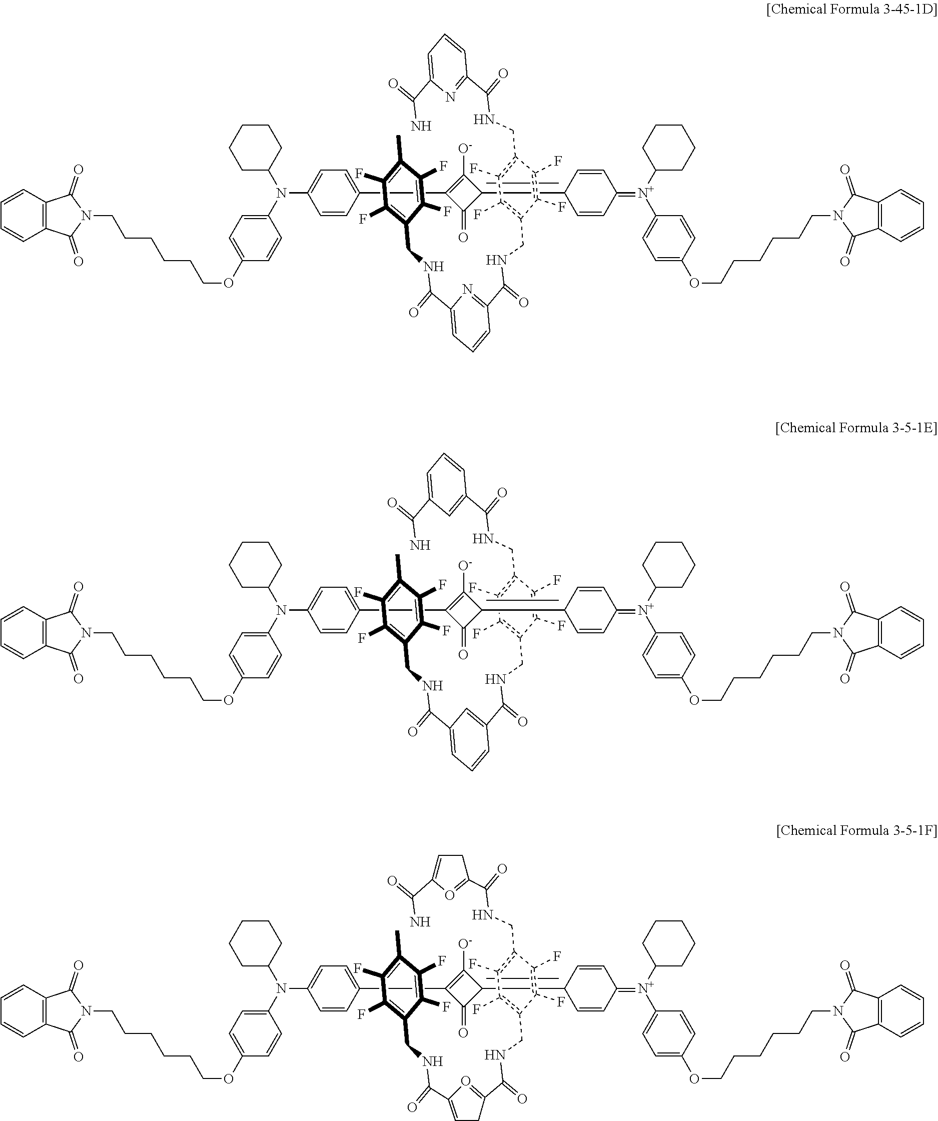

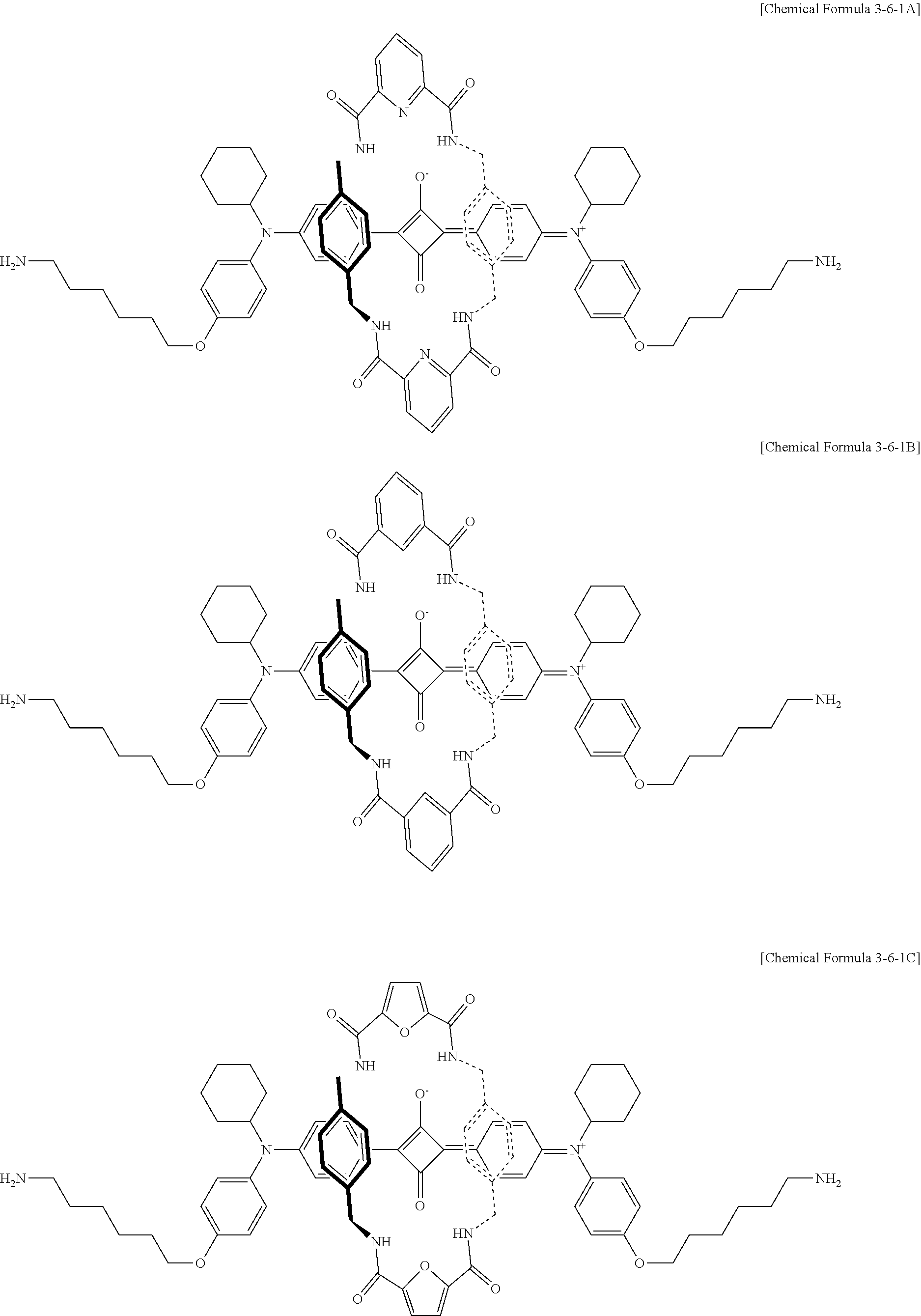

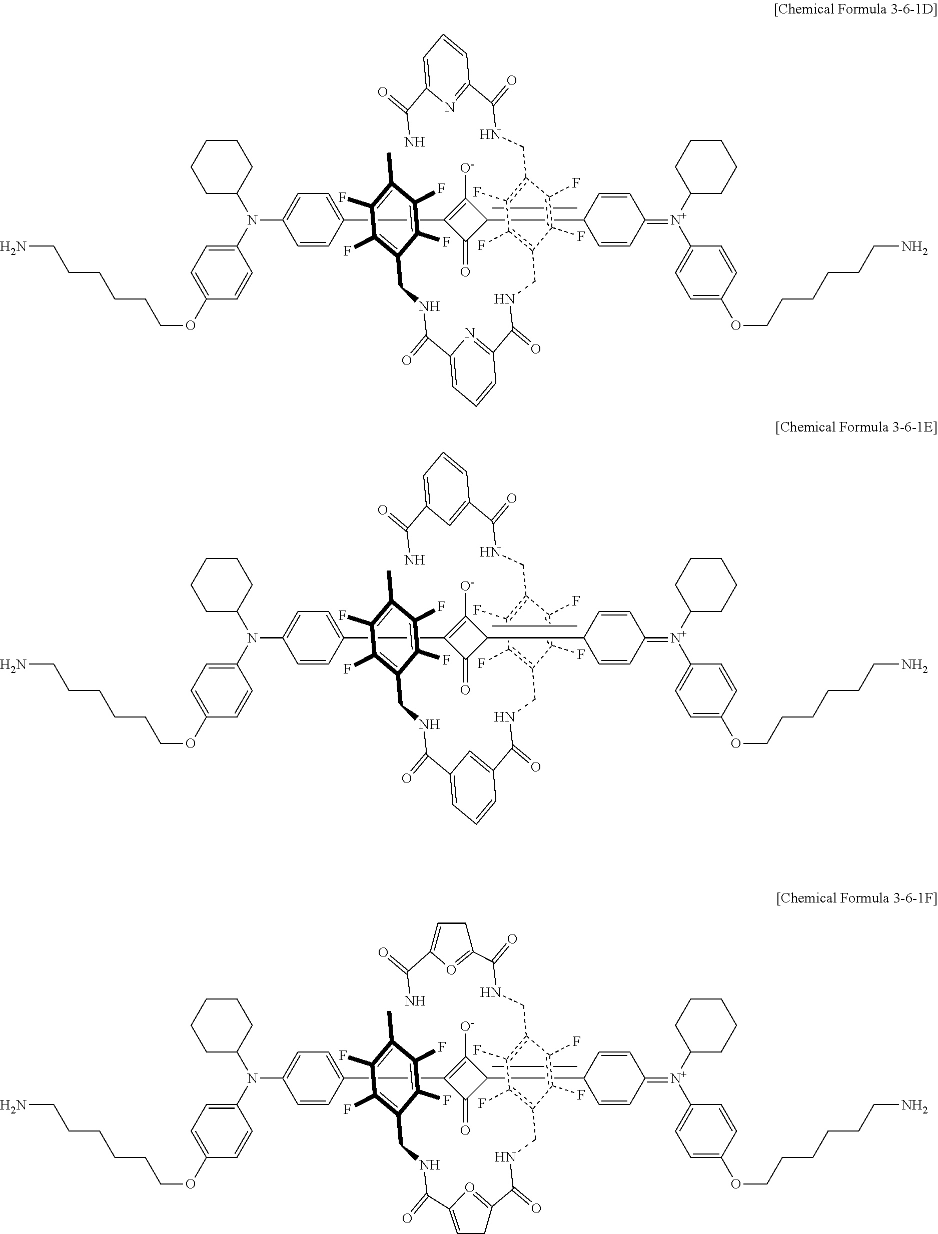

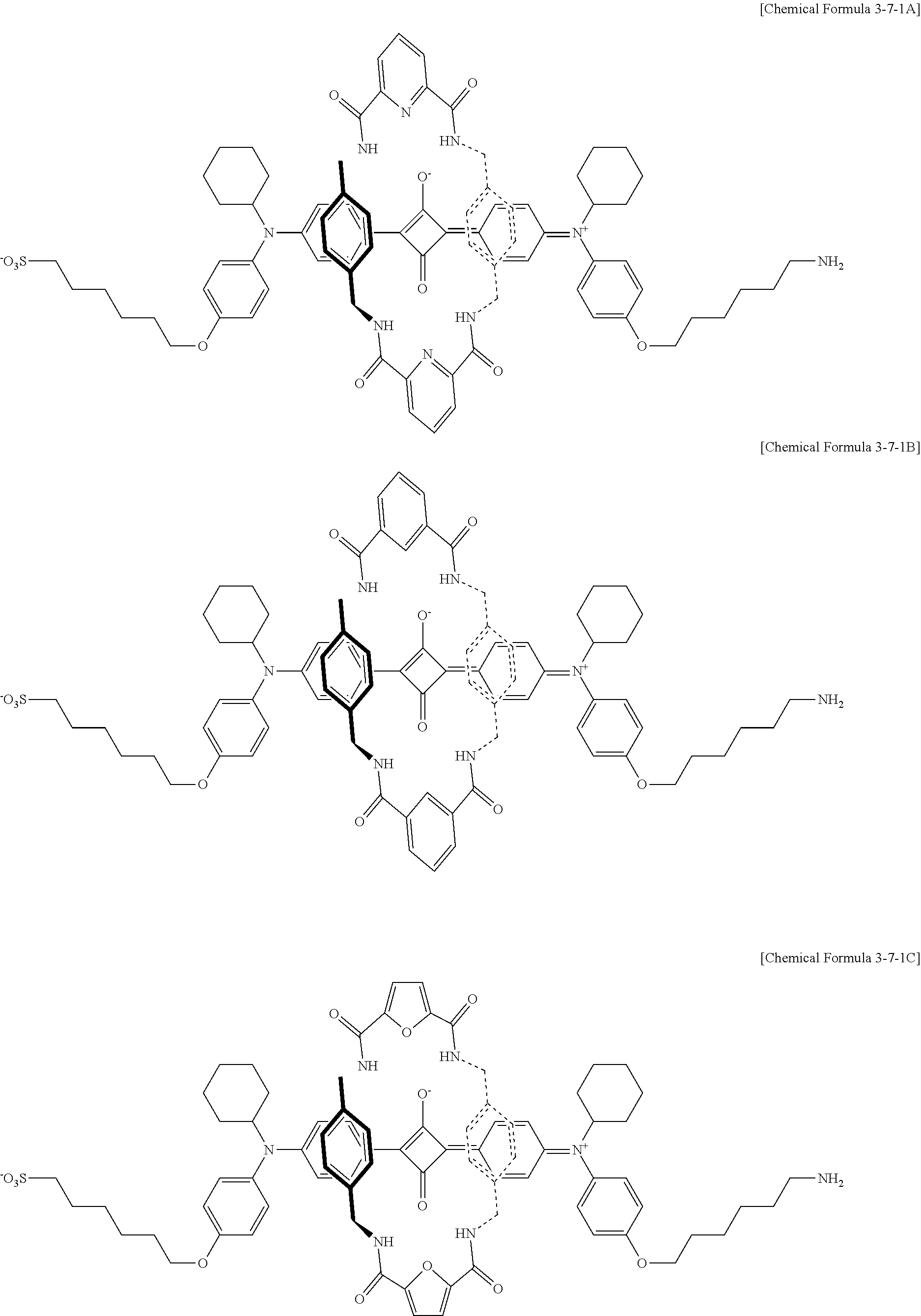

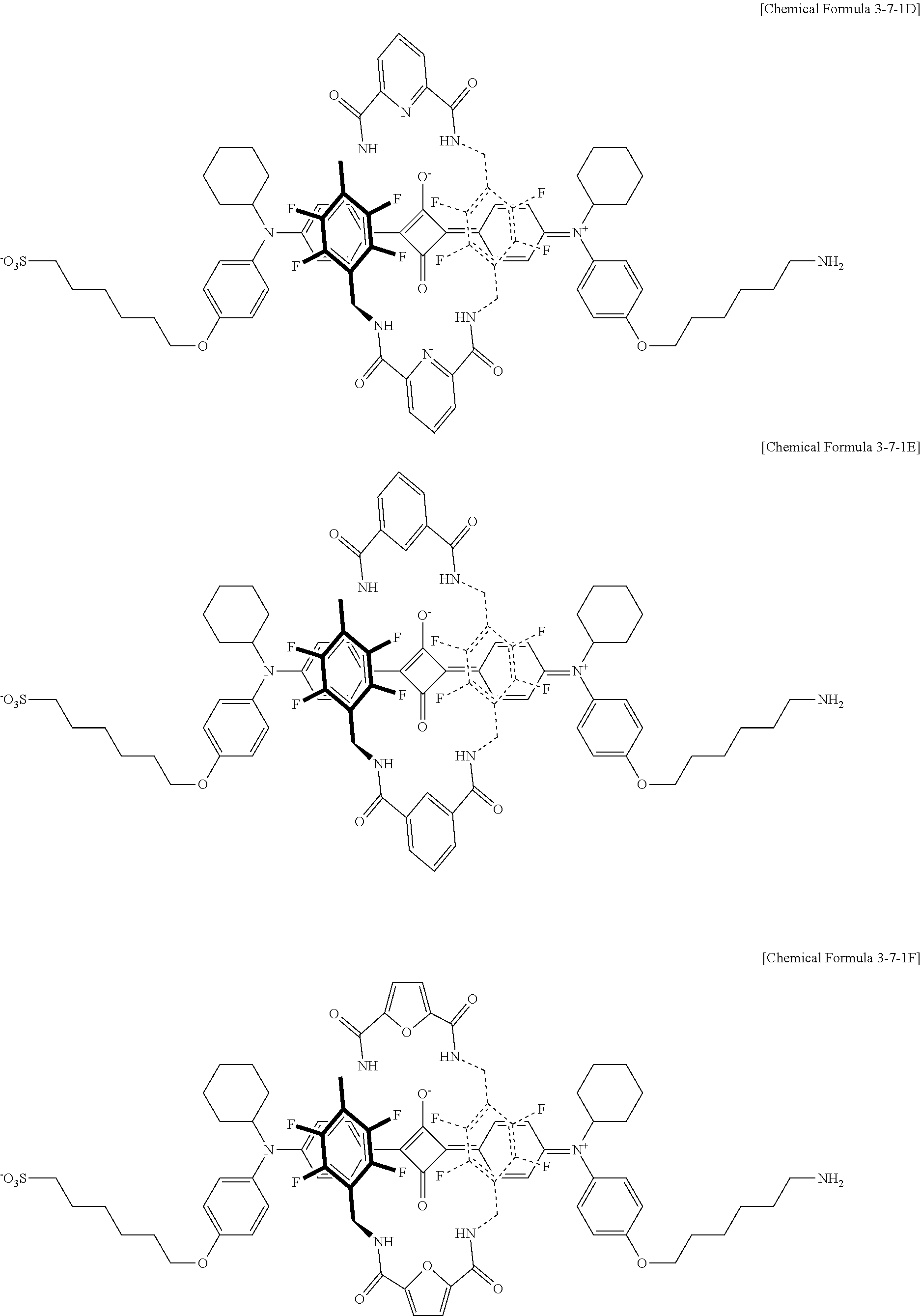

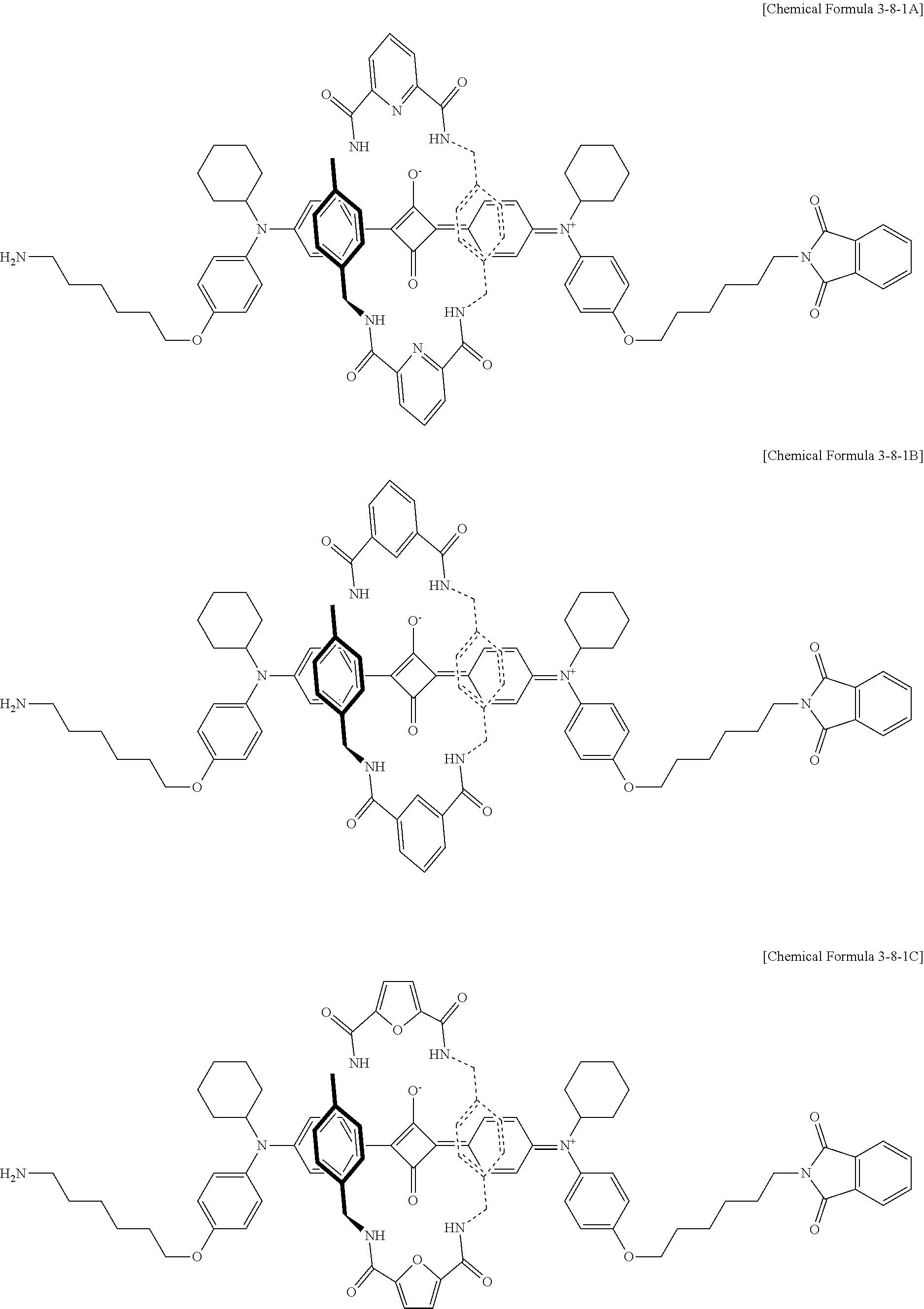

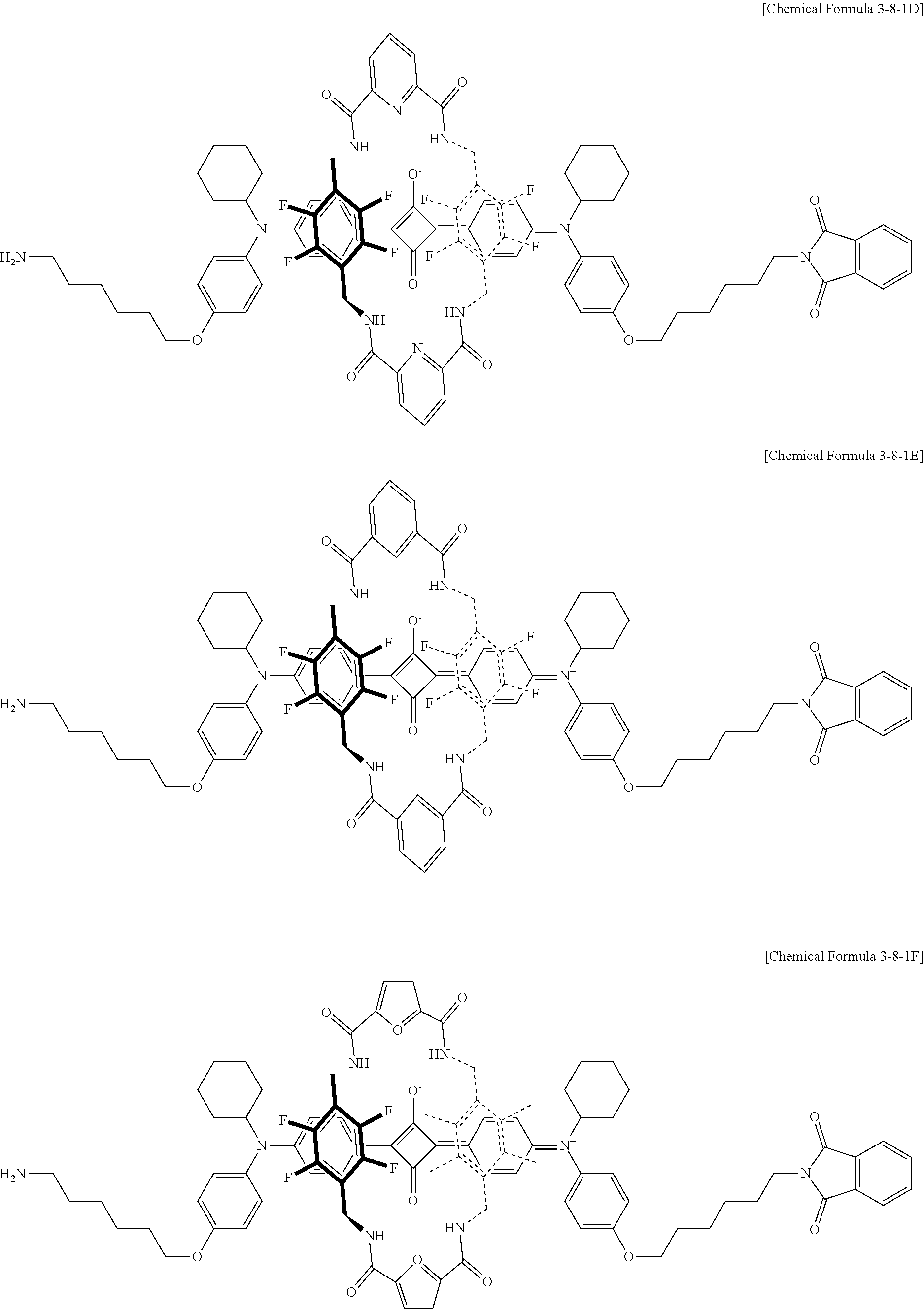

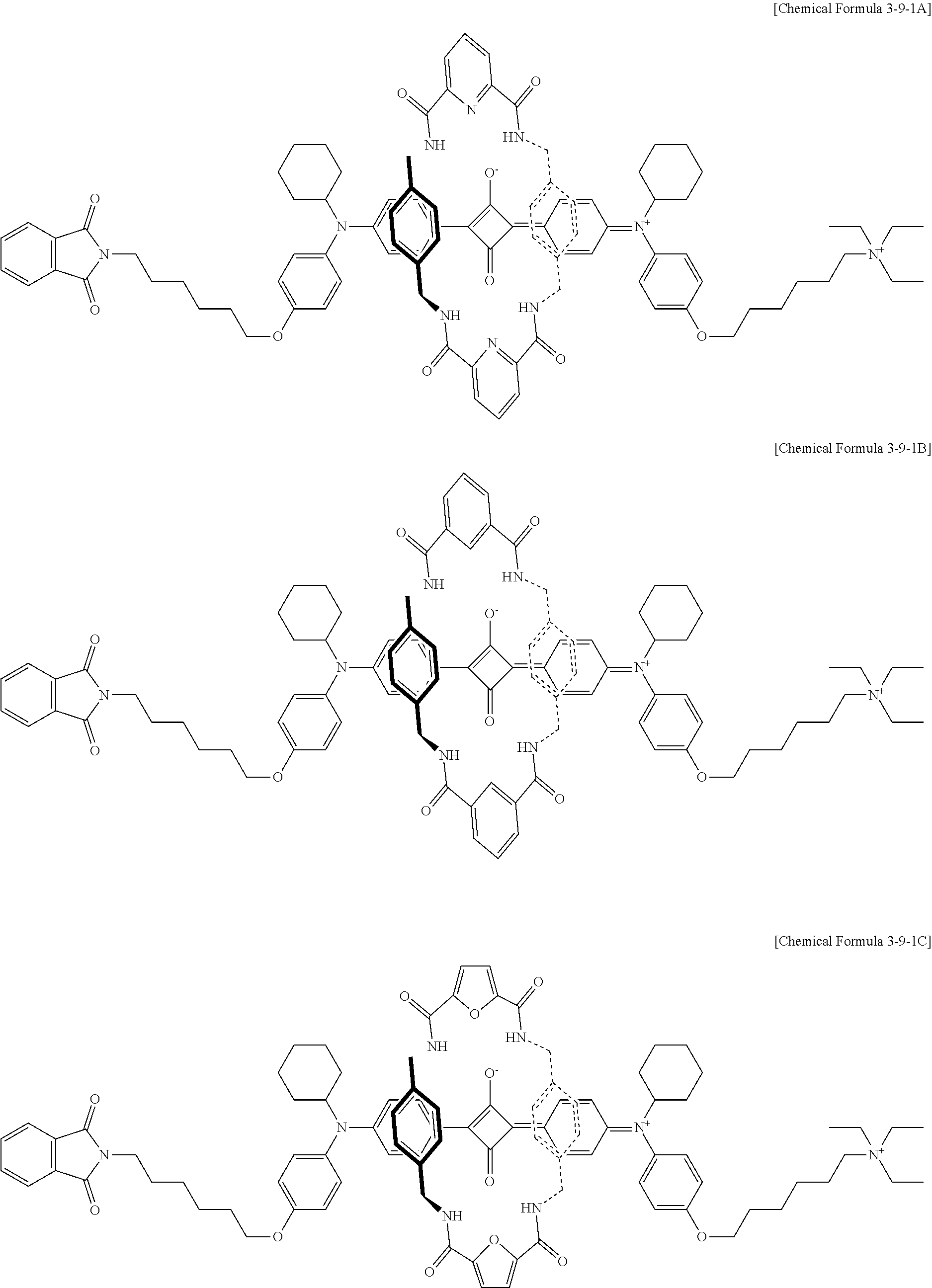

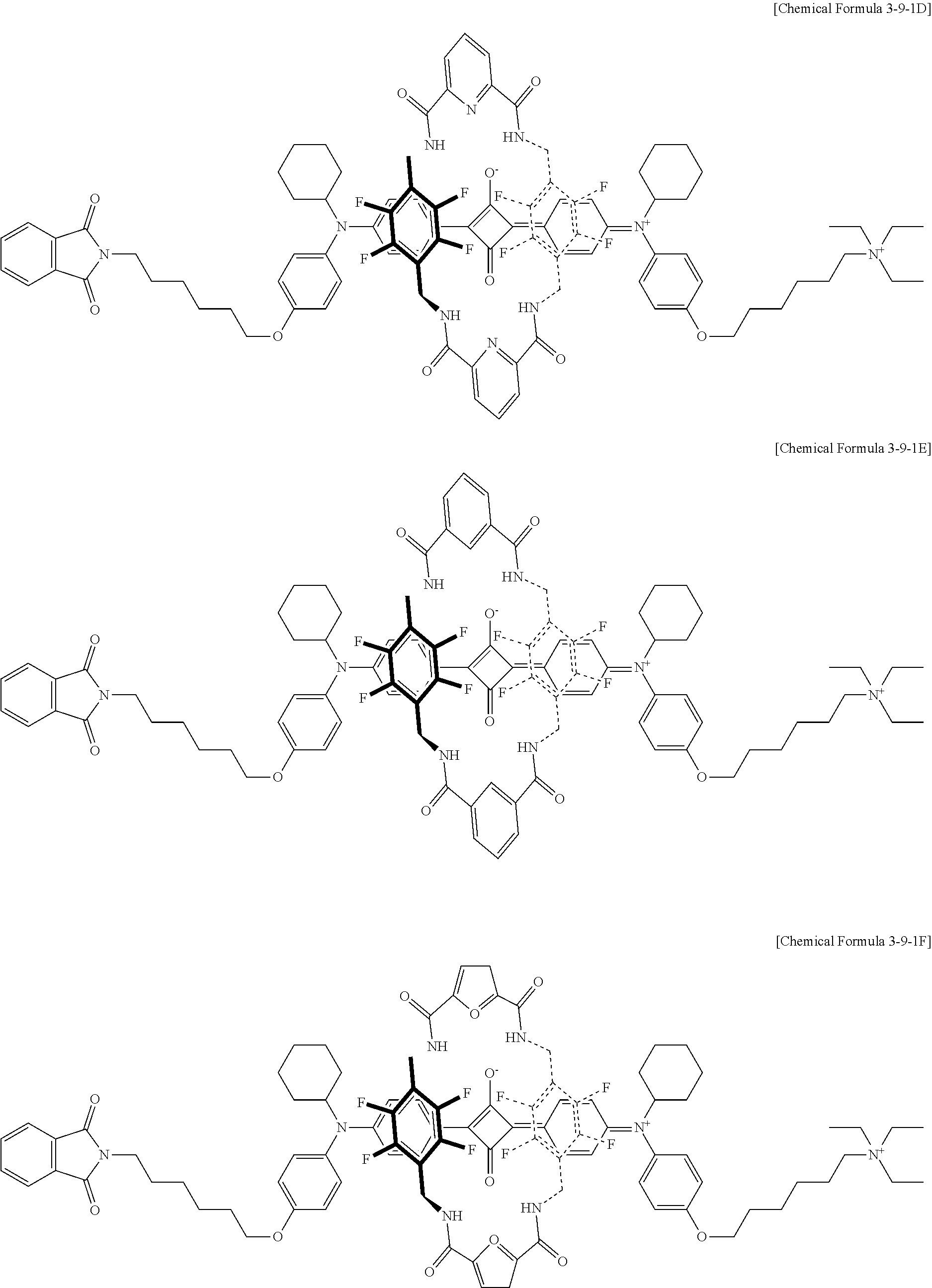

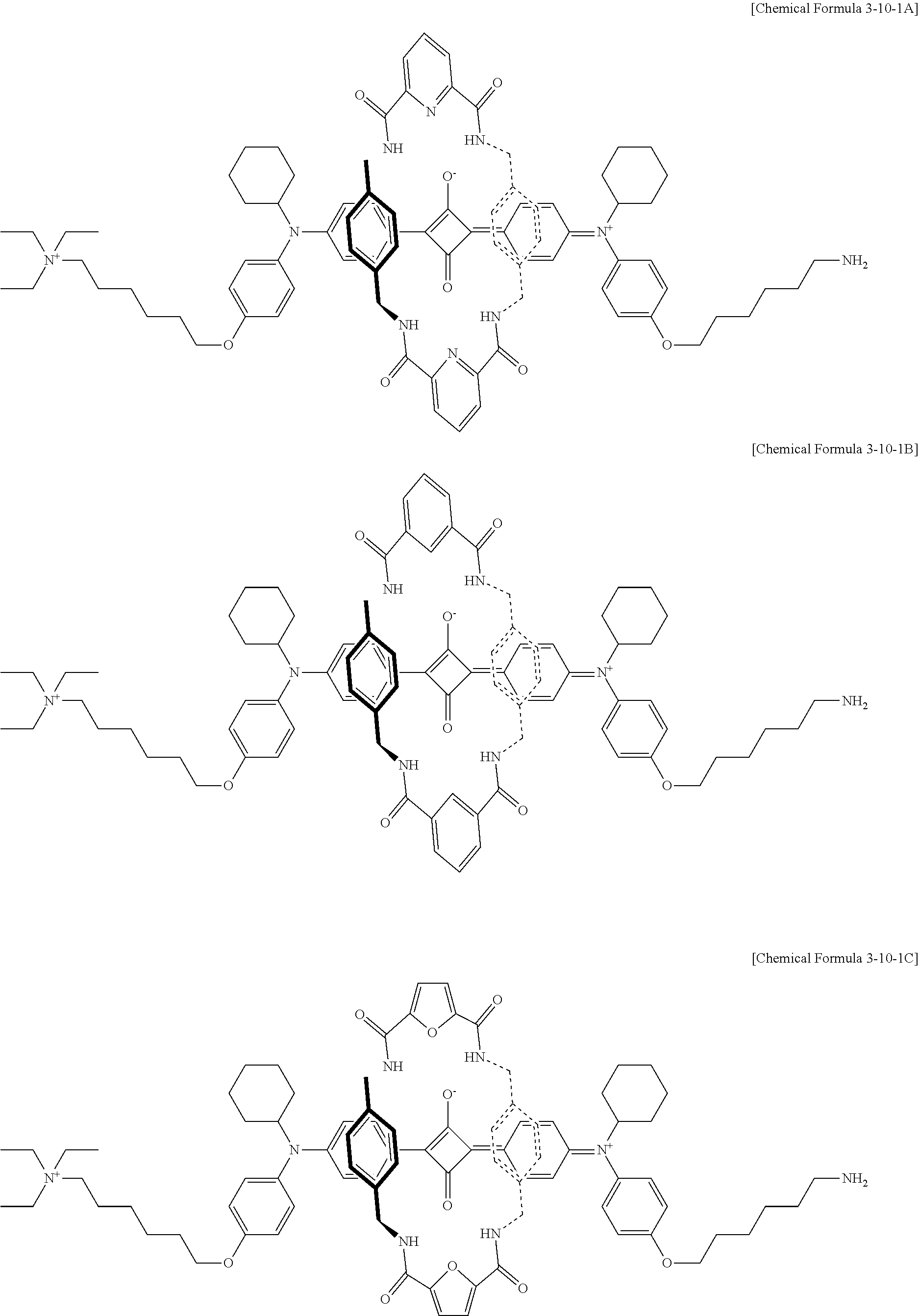

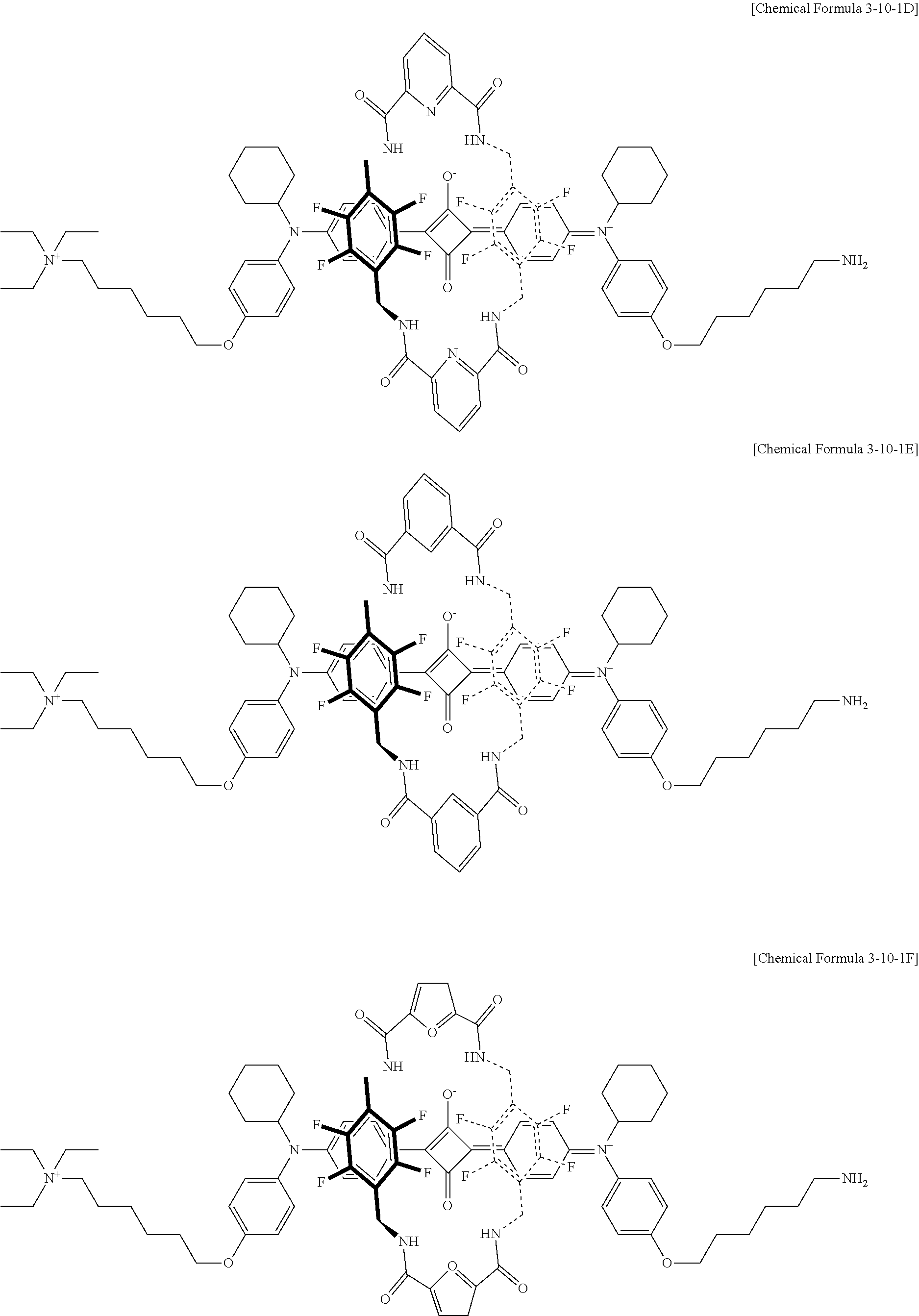

The length of the core represented by Chemical Formula 1 may be about 1 nm to about 3 nm, e.g., about 1.5 nm to about 2 nm. Within the above ranges, a core-shell structured compound may be easily formed. In an implementation, within the above ranges, the shell of the macrocyclic compound may surround the core represented by Chemical Formula 1. If a different core (that does not fall within the above range or embodiments) were to be used, it could be difficult to expect improvement in durability because it could be difficult for the shell to form a structure surrounding the core.

A cage width in this disclosure refers to an internal distance of the shell, e.g., in a shell represented by Chemical Formula 2, a distance between two different phenylene groups in which both methylene groups are linked.

The wider the cage width of the shell, the more likely slip-off of the cage could occur, and the higher the possibility that the shell could come out of the dye, which in turn could reduce the durability of the dye. However, if the cage width of the shell were to be too small, synthesis itself could be impossible. Accordingly, the cage size of the shell may be appropriately set.

A cage width of the shell may range from about 6.5 Å to about 7.5 Å and a volume of the shell may range from about 10 Å to about 16 Å. If the shell has a cage width within the range, a core-shell dye having a structure surrounding the core represented by Chemical Formula 1 may be obtained, and thus a color filter having improved durability may be realized when the core-shell dye is added to a photosensitive resin composition.

The shell represented by Chemical Formula 2 may include an amide bond (—CONH—). In an implementation, the hydrogen atom included in the amide bond of the shell represented by Chemical Formula 2 may form a non-covalent bond with the oxygen atom of the compound represented by Chemical Formula 1. In an implementation, the two atoms may form a hydrogen bond, which may help enhance the durability of the core-shell dye.

In an implementation, the dispersion aid may have a squarene mother moiety that expresses green color, and may help further improve the green coloring power and contrast ratio of the photosensitive resin composition.

In an implementation, the dispersion aid may have a maximum absorption wavelength (λₘₐₓ) of about 530 to about 700 nm.

In an implementation, the core itself represented by Chemical Formula 1 may have a maximum absorption peak at a wavelength of about 530 nm to about 680 nm. In an implementation, the maximum absorption peak of the core-shell dye may vary depending on whether a halogen group is introduced into the shell represented by Chemical Formula 2. In an implementation, the halogen group may be introduced into the shell represented by Chemical Formula 2, and the dispersion aid may have a maximum absorption peak at a wavelength of about 530 nm to about 700 nm, e.g., about 550 to about 700 nm.

In an implementation, the halogen group may be introduced into the shell represented by Chemical Formula 2 and, compared to the case where a halogen group is not introduced, the maximum absorption peak of the core-shell compound may shift to a long wavelength region of about 20 nm, and excellent matching to the green wavelength band may be achieved.

In an implementation, the dispersion aid may be a compound of a core-shell structure, and it may include a core containing the compound represented by Chemical Formula 1 and the shell at a molar ratio of about 1:1. In the above molar ratio, a coating layer (shell) surrounding the core containing the compound represented by Chemical Formula 1 may be well formed.

The dispersion aid may be included in an amount of about 0.01 wt % to about 10 wt %, e.g., about 0.03 wt % to about 1 wt %, about 0.05 wt % to about 0.3 wt %, or about 0.06 wt % to about 0.24 wt %, based on a total weight of the photosensitive resin composition.

In an implementation, the dispersion aid may be included in an amount of about 0.01 wt % to about 10 wt %, e.g., about 0.05 wt % to about 5 wt %, about 0.1 wt % to about 1.5 wt %, or about 0.3 wt % to about 1.2 wt %, based on a total weight of the colorant.

In an implementation, in the colorant, a weight ratio of the dispersion aid and the pigment may be about 1:5 to about 1:100, e.g., about 1:5 to about 1:70, about 1:10 to about 1:50, or about 1:10 to about 1:40.

Within the above ranges, the dispersibility and dispersion stability of the photosensitive resin composition according to some example embodiments may be improved while improving the coloring power and contrast ratio.

The colorant may include a pigment, and the pigment may include a green pigment, a blue pigment, a red pigment, a violet pigment, a yellow pigment, or a black pigment.

The red pigment may include, e.g., C.I. Red Pigment 254, C.I. Red Pigment 255, C.I. Red Pigment 264, C.I. Red Pigment 270, C.I. Red Pigment 272, C.I. Red Pigment 177, C.I. Red Pigment 89, or the like in the color index, which may be used alone or in a mixture of two or more.

The violet pigment may include, e.g., C.I. Violet Pigment 23 (V.23), C.I. Violet Pigment 29, Dioxazine Violet, First Violet B, Methyl Violet Lake, Indanethrene Brilliant Violet, or the like in the color index, which may be used alone or in a mixture of two or more.

The green pigment may include, e.g., C.I. Green Pigment 7, C.I. Green Pigment 36, C.I. Green Pigment 58, C.I. Green Pigment 59, or the like in the color index, which may be used alone or in a mixture of two or more.

The blue pigment may include, e.g., copper phthalocyanine pigments such as C.I. Blue Pigment 15:6, C.I. Blue Pigment 15, C.I. Blue Pigment 15:1, C.I. Blue Pigment 15:2, C.I. Blue Pigment 15:3, C.I. Blue Pigment 15:4, C.I. Blue Pigment 15:5, C.I. Blue Pigment 15:6, C.I. Blue Pigment 16, or the like in the color index, which may be used alone or in a mixture of two or more.

The yellow pigment may include, e.g., an isoindoline pigment such as C.I. Yellow Pigment 185, C.I. Yellow Pigment 139, or the like, a quinophthalone pigment such as C.I. Yellow Pigment 138, a nickel complex pigment such as C.I. Yellow Pigment 150, or the like in the color index, which may be used alone or in a mixture of two or more.

The black pigment may include, e.g., aniline black, perylene black, titanium black, carbon black, or the like in the color index, which may be used alone or in a mixture of two or more.

The pigments may be used alone or in a mixture of two or more. In an implementation, the pigment may be a green pigment, a yellow pigment, or a mixture thereof.

The dispersant may help the pigment to be uniformly dispersed in the dispersion, and nonionic, anionic or cationic dispersants may be used, respectively. In an implementation, polyalkylene glycol or its ester, polyoxy alkylene, a polyhydric alcohol ester alkylene oxide adduct, an alcohol alkylene oxide adduct, sulfonic acid ester, sulfonic acid salt, carboxylic acid ester, carboxylic acid salt, alkyl amide alkylene oxide adduct, an alkylamine, or the like may be used, and these may be used alone or in combination of two or more.

The pigment may be included in the photosensitive resin composition for a color filter in the form of a dispersion. This pigment dispersion may further include a dispersion solvent, a dispersion resin, or the like. in addition to the pigment, the dispersant, and the dispersion aid. Solid pigment excluding the solvent may be included in an amount of about 5 wt % to about 20 wt %, e.g., about 8 wt % to about 15 wt %, based on a total weight of the pigment dispersion.

Solvents for the pigment dispersion may include, e.g., ethylene glycol acetate, ethyl cellosolve, propylene glycol methyl ether acetate, ethyl lactate, polyethylene glycol, cyclohexanone, propylene glycol methyl ether, or the like. In an implementation, the solvent may include, e.g., propylene glycol methyl ether acetate.

The dispersion resin may be an acrylic resin containing a carboxy group may be used, which may help improve stability of the pigment dispersion and also improve pixel patternability.

The colorant may include the pigment and may further include a dye, and in this case, the resin composition of some example embodiments may be a hybrid type composition. In an implementation, the dye may include a metal complex dye.

The metal complex dye may be a compound having maximum absorbance in the wavelength range of 200 nm to 650 nm, and if the compound were to have absorbance in the above range in order to match the color coordinates to the combination of dyes, the metal complex dye of all colors that dissolves in an organic solvent may be used.

In an implementation, the metal complex dye may be a green dye having maximum absorbance in a wavelength range of 530 nm to 680 nm, a yellow dye having maximum absorbance in a wavelength range of 200 nm to 400 nm, an orange dye having a maximum absorbance in a wavelength range of 300 nm to 500 nm, a red dye having maximum absorbance in a wavelength range of 500 nm to 650 nm, or a combination thereof.

The metal complex dye may be a direct dye, an acidic dye, a basic dye, an acidic mordant dye, a sulfide dye, a reduction dye, an azoic dye, a dispersion dye, a reactive dye, an oxidation dye, an oil-soluble dye, an azo dye, an anthraquinone dye, an indigoid dye, a carbonium ion dye, a phthalocyanine dye, a nitro dye, a quinoline dye, a cyanine dye, a polymethine dye, or a combination thereof.

The metal complex dye may include a metal ion of, e.g., Mg, Ni, Cu, Co, Zn, Cr, Pt, Pd, or Fe.

The metal complex dye may be a complex of, e.g., C.I. Solvent Dye such as C.I. Solvent Green 1, 3, 4, 5, 7, 28, 29, 32, 33, 34, 35, or the like; C.I. Acid Dye such as C.I. Acid Green 1, 3, 5, 6, 7, 8, 9, 11, 13, 14, 15, 16, 22, 25, 27, 28, 41, 50, 50:1, 58, 63, 65, 80, 104, 105, 106, 109, or the like; C.I. Direct Dye such as C.I. Direct Green 25, 27, 31, 32, 34, 37, 63, 65, 66, 67, 68, 69, 72, 77, 79, 82, or the like; C.I. Basic Dye such as C.I. Basic Green 1, or the like; C.I. Mordant Dye such as C.I. Mordant Green 1, 3, 4, 5, 10, 13, 15, 19, 21, 23, 26, 29, 31, 33, 34, 35, 41, 43, 53, or the like; C.I. Green pigments such as Pigment Green 7, 36, 58, or the like; Solvent Yellow 19, Solvent Yellow 21, Solvent Yellow 25, Solvent Yellow 79, Solvent Yellow 82, Solvent Yellow 88, Solvent Orange 45, Solvent Orange 54, Solvent Orange 62, Solvent Orange 99, Solvent Red 8, Solvent Red 32, Solvent Red 109, Solvent Red 112, Solvent Red 119, Solvent Red 124, Solvent Red 160, Solvent Red 132, or Solvent Red 218, and the metal ion.

The metal complex dye may have a solubility of greater than or equal to about 5, e.g., about 5 to about 10, in a solvent used in the photosensitive resin composition according to some embodiments. The solubility may be obtained by an amount (g) of the dye dissolved in 100 g of the solvent. Within the above ranges, compatibility with other components constituting the photosensitive resin composition according to some embodiments and coloring power may be secured, and precipitation of the dye may be prevented.

The solvent may include, e.g., propylene glycol monomethyl ether acetate (PGMEA), ethyl lactate (EL), ethylene glycol ethyl acetate (EGA), cyclohexanone, 3-methoxy-1-butanol, or a combination thereof.

Within the above ranges, it may be usefully used for color filters such as LCDs and LEDs that express high luminance and high contrast ratio in a desired color coordinate.

The metal complex dye may be included in an amount of about 0.01 wt % to about 1 wt %, e.g., about 0.01 wt % to about 0.5 wt %, based on a total weight of the photosensitive resin composition. Within the above ranges, high luminance and contrast ratio may be exhibited in a desired color coordinate.

In an implementation, the dye and the pigment may be mixed and used, e.g., in a weight ratio of about 0.1:99.9 to about 99.9:0.1, or about 1:9 to about 9:1. Within the above weight ratio ranges, chemical resistance and maximum absorption wavelength may be controlled within an appropriate range, and high luminance and contrast ratio may be exhibited in a desired color coordinate.

The colorant may be included in an amount of about 5 wt % to about 50 wt %, e.g., about 5 wt % to about 40 wt % or about 10 wt % to about 30 wt %, based on a total solid content of the photosensitive resin composition. Within the above ranges, a coloring effect and developability may be improved.

### (B) Photopolymerizable Compound

The photopolymerizable compound may be a mono-functional or multi-functional ester of (meth)acrylic acid including at least one ethylenic unsaturated double bond.

The photopolymerizable compound may cause sufficient polymerization during exposure in a pattern-forming process and form a pattern having excellent heat resistance, light resistance, and chemical resistance due to the ethylenic unsaturated double bond.

Examples of the photopolymerizable compound may include ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolacepoxy (meth)acrylate, and the like.

Commercially available examples of the photopolymerizable compound may be as follows. The mono-functional (meth)acrylic acid ester may include Aronix M-101®, Aronix M-111®, Aronix M-114® (Toagosei Chemistry Industry Co., Ltd.); KAYARAD TC-110S®, KAYARAD TC-120S® (Nippon Kayaku Co., Ltd.); V-158®, V-2311® (Osaka Organic Chemical Ind., Ltd.), or the like. Examples of a difunctional (meth)acrylic acid ester may include Aronix M-210®, Aronix M-240®, Aronix M-6200® (Toagosei Chemistry Industry Co., Ltd.), KAYARAD HDDA®, KAYARAD HX-220®, KAYARAD R-604® (Nippon Kayaku Co., Ltd.), V-260®, V-312®, V-335 HP® (Osaka Organic Chemical Ind., Ltd.), and the like. Examples of a tri-functional (meth)acrylic acid ester may include Aronix M-309®, Aronix M-400®, Aronix M-405®, Aronix M-450®, Aronix M-7100®, Aronix M-8030®, Aronix M-8060® (Toagosei Chemistry Industry Co., Ltd.); KAYARAD TMPTA®, KAYARAD DPCA-20®, KAYARAD DPCA-30®, KAYARAD DPCA-60®, KAYARAD DPCA-120® (Nippon Kayaku Co., Ltd.); V-295®, V-300®, V-360®, V-GPT®, V-3PA®, V-400® (Osaka Yuki Kayaku Kogyo Co. Ltd.), and the like. These may be used alone or as a mixture of two or more.

The photopolymerizable compound may be used by treating it with an acid anhydride to provide better developability.

The photopolymerizable compound may be included in an amount of about 0.1 wt % to about 20 wt %, e.g., about 1 wt % to about 15 wt %, or about 3 wt % to about 10 wt %, based on a total weight of the photosensitive resin composition. Within the above ranges, sufficient curing may occur during exposure to light in the pattern formation process, resulting in excellent reliability and excellent developability in an alkaline developer.

### (C) Photopolymerization Initiator

The photopolymerization initiator may be a suitable initiator for photosensitive resin compositions, e.g., an acetophenone compound, a benzophenone compound, a thioxanthone compound, a benzoin compound, a triazine compound, an oxime compound, or a combination thereof.

Examples of the acetophenone compound may include 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

Examples of the benzophenone compound may include benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

Examples of the thioxanthone compound may include thioxanthone, 2-methylthioxanthone, isopropyl thioxanthone, 2,4-diethyl thioxanthone, 2,4-diisopropyl thioxanthone, 2-chlorothioxanthone, and the like.

Examples of the benzoin compound may include benzoin, benzoin methyl ether, benzoin ethyl ether, benzoin isopropyl ether, benzoin isobutyl ether, benzyldimethylketal, and the like.

Examples of the triazine compound may include 2,4,6-trichloro-s-triazine, 2-phenyl 4,6-bis(trichloromethyl)-s-triazine, 2-(3′, 4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloro methyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

Examples of the oxime compound may include an O-acyloxime-based compound, 2-(o-benzoyloxime)-1-[4-(phenylthio)phenyl]-1,2-octanedione, 1-(o-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. Specific examples of the O-acyloxime-based compound may be 1,2-octanedione, 2-dimethylamino-2-(4-methylbenzyl)-1-(4-morpholin-4-yl-phenyl)-butan-1-one, 1-(4-phenylsulfanyl phenyl)-butane-1,2-dione2-oxime-O-benzoate, 1-(4-phenylsulfanyl phenyl)-octane-1,2-dione2-oxime-O-benzoate, 1-(4-phenylsulfanyl phenyl)-octan-1-oneoxime-O-acetate and 1-(4-phenylsulfanyl phenyl)-butan-1-oneoxime-O-acetate, and the like.

In an implementation, in addition to the above compounds, the photopolymerization initiator may include a carbazole compound, a diketone compound, a sulfonium borate compound, a diazo compound, an imidazole compound, a biimidazole compound, or a fluorene compound.

The photopolymerization initiator may be used with a photosensitizer capable of causing a chemical reaction by absorbing light and becoming excited and then, transferring its energy.

Examples of the photosensitizer may include tetraethylene glycol bis-3-mercapto propionate, pentaerythritol tetrakis-3-mercapto propionate, dipentaerythritol tetrakis-3-mercapto propionate, and the like.

The photopolymerization initiator may be included in an amount of about 0.1 wt % to about 5 wt %, e.g., about 1 wt % to about 3 wt %, based on a total weight of the photosensitive resin composition. Within these ranges, sufficient photopolymerization may occur during exposure in a pattern-forming process, excellent reliability may be realized, heat resistance, light resistance, and chemical resistance of patterns, resolution and close contacting properties may be improved, and decrease of transmittance due to a non-reaction initiator may be prevented.

### (D) Binder Resin

The binder resin may include, e.g., an acrylic binder resin.

The acrylic resin may be, e.g., a copolymer of a first ethylenic unsaturated monomer and a second ethylenic unsaturated monomer that is copolymerizable therewith, e.g., may be a resin including at least one acryl repeating unit.

The first ethylenic unsaturated monomer may be an ethylenic unsaturated monomer including at least one carboxyl group and examples of the monomer may include acrylic acid, methacrylic acid, maleic acid, itaconic acid, fumaric acid, and a combination thereof.

The first ethylenic unsaturated monomer may be included in an amount of about 5 wt % to about 50 wt %, e.g., about 10 wt % to about 40 wt %, based on a total weight of the acrylic binder resin.

The second ethylenic unsaturated monomer may include, e.g., an aromatic vinyl compound such as styrene, α-methylstyrene, vinyl toluene, vinylbenzylmethylether, or the like; an unsaturated carboxylate ester compound such as methyl(meth)acrylate, ethyl(meth)acrylate, butyl(meth)acrylate, 2-hydroxyethyl(meth)acrylate, 2-hydroxy butyl(meth)acrylate, benzyl(meth)acrylate, cyclohexyl(meth)acrylate, phenyl(meth)acrylate, or the like; an unsaturated amino alkyl carboxylate ester compound such as 2-aminoethyl(meth)acrylate, 2-dimethylaminoethyl(meth)acrylate, or the like; a carboxylic acid vinyl ester compound such as vinyl acetate, vinyl benzoate, or the like; an unsaturated glycidyl carboxylate ester compound such as glycidyl(meth)acrylate, or the like; a vinyl cyanide compound such as (meth)acrylonitrile or the like; an unsaturated amide compound such as (meth)acrylamide, or the like; or the like, and may be used alone or as a mixture of two or more.

Examples of the acrylic resin may include a (meth)acrylic acid/benzylmethacrylate copolymer, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and the like, and these may be used alone or as a mixture of two or more.

In an implementation, the binder resin may include an epoxy binder resin.

The binder resin may help improve heat resistance by further including an epoxy-based binder resin. The epoxy binder resin may include, e.g., a phenol novolac epoxy resin, a tetramethyl biphenyl epoxy resin, a bisphenol A epoxy resin, a bisphenol F epoxy resin, an alicyclic epoxy resin, or a combination thereof.

In an implementation, the binder resin including the epoxy binder resin may help secure dispersion stability of a colorant such as a pigment, and may help to form a pixel having a desired resolution during a developing process.

The epoxy binder resin may be included in an amount of about 1 wt % to about 10 wt %, e.g., about 5 wt % to about 10 wt %, based on a total amount of the binder resin. Within the above ranges, film residue ratio and chemical resistance may be greatly improved.

An epoxy equivalent weight of the epoxy resin may be about 150 g/eq to about 200 g/eq. Within this range, there may be an advantageous effect in improving a curing degree of the formed pattern and fixing the colorant in the structure in which the pattern is formed.

The binder resin may be dissolved in a solvent in a solid form to form a photosensitive resin composition. In an implementation, the binder resin in the solid form may be about 0.1 wt % to about 30 wt %, e.g., about 20 wt % to about 30 wt %, based on a total weight of the binder resin solution dissolved in the solvent.

The binder resin may be included in an amount of about 0.1 wt % to about 20 wt %, e.g., about 0.5 wt % to about 15 wt %, or about 1 wt % to about 10 wt %, based on a total solid content of the photosensitive resin composition. Within the above ranges, it is possible to obtain excellent surface smoothness due to excellent developability and improved crosslinking property during manufacture of the color filter.

### (E) Solvent

The solvent may be a material having compatibility with the colorant, the binder resin, the photopolymerizable compound, and the photopolymerization initiator but not reacting therewith.

Examples of the solvent may include alcohols such as methanol, ethanol, and the like; ethers such as dichloroethyl ether, n-butyl ether, diisoamyl ether, methylphenyl ether, tetrahydrofuran, and the like; glycol ethers such as ethylene glycol monomethylether, ethylene glycol monoethylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol monomethylether acetate, propylene glycol propylether acetate, and the like; aromatic hydrocarbons such as toluene, xylene and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; oxy acetic acid alkyl esters such as oxy methyl acetate, oxy ethyl acetate, butyl oxyacetate, and the like; alkoxy acetic acid alkyl esters such as methoxy methyl acetate, methoxy ethyl acetate, methoxy butyl acetate, ethoxy methyl acetate, ethoxy ethyl acetate, and the like; 3-oxy propionic acid alkyl esters such as 3-oxy methyl propionate, 3-oxy ethyl propionate, and the like; 3-alkoxy propionic acid alkyl esters such as 3-methoxy methyl propionate, 3-methoxy ethyl propionate, 3-ethoxy ethyl propionate, 3-ethoxy methyl propionate, and the like; 2-oxy propionic acid alkyl esters such as 2-oxy methyl propionate, 2-oxy ethyl propionate, 2-oxy propyl propionate, and the like; 2-alkoxy propionic acid alkyl esters such as 2-methoxy methyl propionate, 2-methoxy ethyl propionate, 2-ethoxy ethyl propionate, 2-ethoxy methyl propionate, and the like; 2-oxy-2-methyl propionic acid esters such 2-oxy-2-methyl methyl propionate, 2-oxy-2-methyl ethyl propionate, and the like, monooxy monocarboxylic acid alkyl esters of 2-alkoxy-2-methyl alkyl propionates such as 2-methoxy-2-methyl methyl propionate, 2-ethoxy-2-methyl ethyl propionate, and the like; esters such as 2-hydroxy ethyl propionate, 2-hydroxy-2-methyl ethyl propionate, hydroxy ethyl acetate, 2-hydroxy-3-methyl methyl butanoate, and the like; ketonate esters such as ethyl pyruvate, and the like. In an implementation, high boiling point solvent such as N-methylformamide, N,N-dimethylformamide, N-methylformanilide, N-methylacetamide, N,N-dimethylacetamide, N-methylpyrrolidone, dimethylsulfoxide, benzylethylether, dihexylether, acetylacetone, isophorone, caproic acid, caprylic acid, 1-octanol, 1-nonanol, benzylalcohol, benzyl acetate, ethyl benzoate, diethyl oxalate, diethyl maleate, γ-butyrolactone, ethylene carbonate, propylene carbonate, phenyl cellosolve acetate, or the like may be also used.

Among these, considering compatibility and reactivity, the solvents include propylene glycol monomethyl ether acetate (PGMEA), n-butyl acetate (n-BA), and ethylene glycol dimethyl ether, or a combination thereof may be used.

The solvent may be included in a balance amount, e.g., about 30 wt % to about 90 wt %, about 40 wt % to about 70 wt %, or about 50 wt % to about 60 wt %, based on a total weight of the photosensitive resin composition. Within the above ranges, the photosensitive resin composition may have excellent applicability and a coating film with excellent flatness can be obtained.

### (F) Other Additives

In an implementation, the photosensitive resin composition may further include an additive, e.g., malonic acid; 3-amino-1,2-propanediol; a coupling agent containing a vinyl group or a (meth)acryloxy group; or a radical polymerization initiator, in order to prevent stains or spots during the coating, to improve leveling performance, and to prevent the generation of undeveloped residues.

The additives may be easily adjusted according to desired physical properties.

The coupling agent may include a silane coupling agent, e.g., trimethoxysilyl benzoic acid, γ methacryl oxypropyl trimethoxysilane, vinyl triacetoxysilane, vinyl trimethoxysilane, γ isocyanate propyl triethoxysilane, γ glycidoxy propyl trimethoxysilane, or β epoxycyclohexyl) ethyltrimethoxysilane, which can be used alone or in mixture of 2 or more types.

The silane coupling agent may be included in an amount of 0.01 part by weight to 1 part by weight, based on 100 parts by weight of the photosensitive resin composition.

In an implementation, the photosensitive resin composition for a color filter may further include a surfactant, e.g., a fluorine surfactant.

Examples of the fluorine surfactant may include F-482, F-484, and F-478 of DIC Co., Ltd.

The surfactant may be included in an amount of 0.01 wt % to 5 wt %, e.g., 0.01 wt % to 2 wt %, based on a total weight of the photosensitive resin composition. Within these ranges, the generation of foreign substances after development may be reduced or prevented.

In an implementation, other additives such as an antioxidant, a stabilizer, or the like may be added to the photosensitive resin composition within a range that does not impair physical properties.

### (Photosensitive Resin Layer, Color Filter, and Display Device)

Some example embodiments may provide a photosensitive resin layer manufactured using the photosensitive resin composition according to some example embodiments.

The photosensitive resin layer or composition of some example embodiments may include color positive photoresist composition and a color negative photoresist composition.

The photosensitive resin layer of some example embodiments may be a color negative photoresist. This has the advantage that coloring caused by the photoresist does not occur and that light sensitivity is relatively higher than that of positive photoresist.

Some embodiments provide a color filter manufactured using the aforementioned photosensitive resin composition.

A method of manufacturing the color filter may be as follows.

The aforementioned photosensitive resin composition may be coated to form a photosensitive resin composition layer with a thickness of 0.5 μm to 10 μm on a glass substrate in an appropriate method such as spin coating, roller coating, spray coating, or the like.

Subsequently, the substrate having the photosensitive resin composition layer may be radiated by or exposed to light or energy to form a pattern required for a color filter. The radiation may be performed by using UV, an electron beam, or an X-ray as a light or energy source, and the UV may be radiated, e.g., in a region of 190 nm to 450 nm or 200 nm to 400 nm. The radiation may be performed by further using a photoresist mask. After performing the radiation process in this way, the photosensitive resin composition layer exposed to the light source may be treated with a developer. Herein, a non-exposed region in the photosensitive resin composition layer may be dissolved and may form the pattern for a color filter. This process may be repeated as many times as the number of desired colors, obtaining a color filter having a desired pattern. In an implementation, the image pattern obtained through development in the above process may be cured by reheating or radiating an actinic ray thereinto, and crack resistance, solvent resistance, and the like may be improved.

According to some example embodiments, a display device including the aforementioned color filter is provided.

The display device may be a liquid crystal display device, a CMOS image sensor, or the like.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis Example 1: Compound Represented by Chemical Formula 3-1-1A

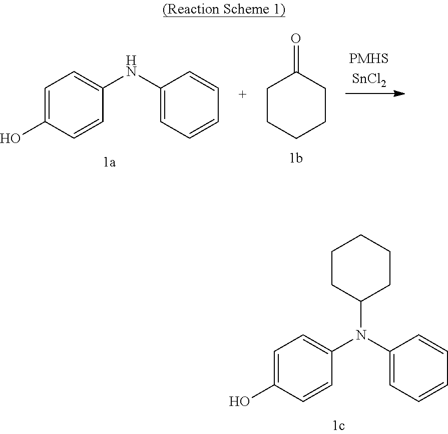 [SMILES: Oc1ccc(Nc2ccccc2)cc1 ; O=C1CCCCC1 ; Oc1ccc(N(c2ccccc2)C2CCCCC2)cc1]

20.0 g (108 mmol) of the compound 1a and 16.8 mL (162 mmol) of the compound 1b were added to 120 mL of methanol, and 4.88 g (25.6 mmol) of tin (II) chloride was added thereto at once. After increasing the temperature to 60° C., 13.0 g (216 mmol) of polymethylhydrosiloxane (PMHS) was slowly added thereto. After stirring the obtained mixture for 2 hours at the same temperature, tin (II) chloride and polymethylhydrosiloxane in each equal amount were additionally added thereto. After a reaction overnight, the resultant was cooled to ambient temperature, and a polymer product therefrom was removed through vacuum filtration. The corresponding solution was added to distilled water and then, stirred at ambient temperature for 30 minutes and filtered under a reduced pressure to obtain 21.3 g (79.7 mmol) of the compound 1c.

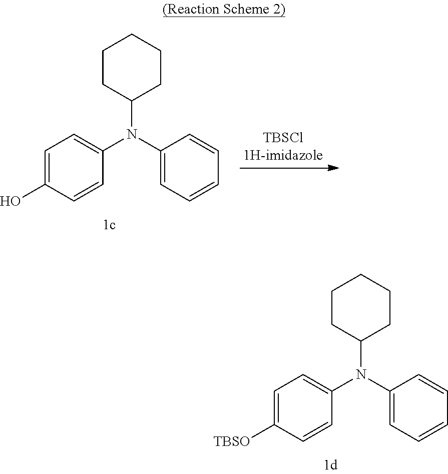 [SMILES: Oc1ccc(N(c2ccccc2)C2CCCCC2)cc1 ; CC(C)(C)[Si](C)(C)Oc1ccc(N(c2ccccc2)C2CCCCC2)cc1]

78.5 g (294 mmol) of the compound 1c was dissolved in 600 mL of N,N-dimethyl formamide, and 53.1 g (352 mmol) of tert-butylchlorodimethylsilane (TBSCl) and 40.1 g (588 mmol) of 1H-imidazole were sequentially added thereto. After increasing the temperature to 40° C., the obtained mixture was stirred for 3 hours. Subsequently, 1.5 L of distilled water was added thereto and then, extracted with ethyl acetate. An organic layer therefrom was washed with distilled water and passed through MgSO₄. After removing the solvent under a reduced pressure, 92.3 g (242 mmol) of the compound 1d was obtained by purifying through column chromatography (eluent: n-hexane 100%).

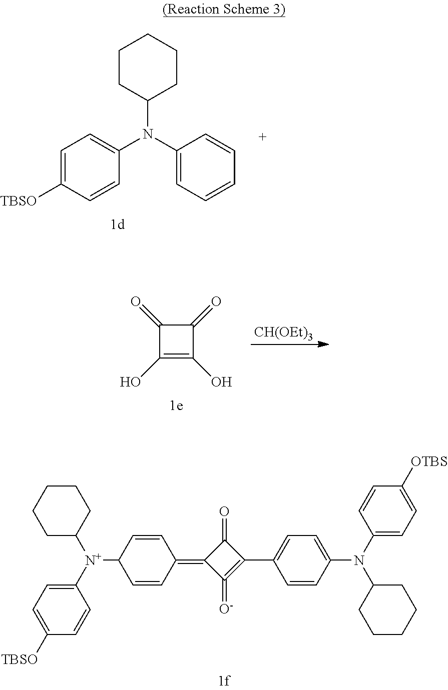

92.3 g (242 mmol) of the compound 1d and 121 mL (726 mmol) of triethyl orthoformate were dissolved in 484 mL of n-amylalcohol, and 19.3 g (169 mmol) of the compound 1e was added thereto at ambient temperature. The corresponding solution was stirred at 90 ºC for 4 hours, and a reaction progress thereof was checked through TLC. After completely removing the solvent under a reduced pressure, the residue was dispersed in n-hexane. The reaction mixture was cooled to 0° C. for 15 minutes to precipitate solid products. The precipitates were separated from the mixture through vacuum filtration and washed by using n-hexane. 55.8 g (66.0 mmol) of Compound 1f was used without additional purification in the following reaction step.

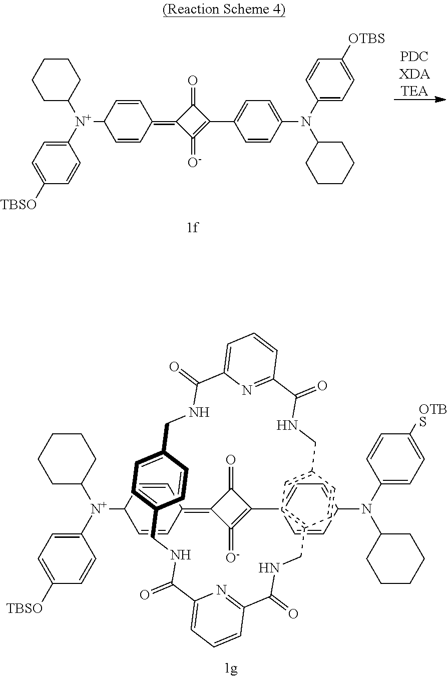

After dissolving 4.2 g (5.0 mmol) of the compound 1f in 42 mL of chloroform and then, cooling the solution to 0° C., the following two types of solutions were prepared: (i) a solution prepared by dissolving 2.0 g (15 mmol) of p-xylxylenediamine (XDA) and 3.0 g (30 mmol) of triethylamine in chloroform and (ii) a solution prepared by dissolving 3.0 g (15 mmol) of pyridine-2,6-dicarbonyl dichloride (PDC) in chloroform. These two solutions were slowly added to the solution of the compound 1f in the order of (i) and (ii) and then, stirred for 2 hours at ambient temperature. After removing the solvent under the reduced pressure condition, the residue was redissolved in ethyl acetate to precipitate polymer by-products. After removing the polymer by-products through vacuum filtration, the solvent was removed under the reduced pressure condition. After redissolving the obtained product in chloroform, the above step was repeated two more times. 2.6 g (1.9 mmol) of the compound 1g was obtained by purifying through column chromatography (eluent: DCM/EtOAC=9/1 to DCM/EtOAC=4/1).

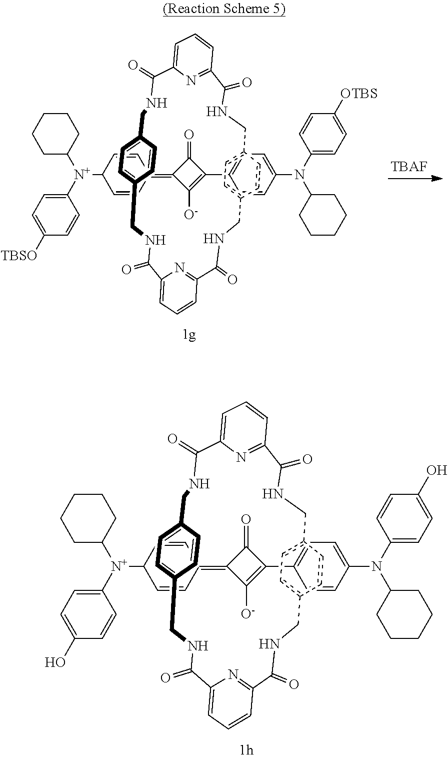

6.20 g (4.51 mmol) of the compound 1g was dissolved in 62.0 mL of tetrahydrofuran, and 9.91 mL of a 1.0 M TBAF (tetrabutylammonium fluoride) solution was added thereto. After stirring the obtained mixture at ambient temperature for 1 hour, the solvent was removed under the reduced pressure condition. The residual mixture was redissolved in 30.0 mL of acetone and then, dispersed in 150 mL of distilled water to produce solids. The solids were separated through the vacuum filtration and washed with distilled water to obtain 5.07 g (4.42 mmol) of the compound 1h.

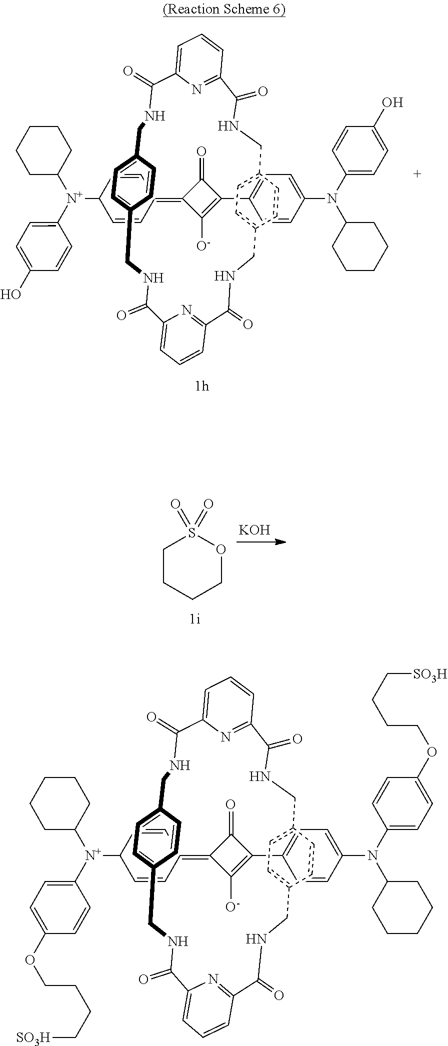

5.0 g (4.36 mmol) of the compound 1h and 1.23 g (21.8 mmol) of KOH were dissolved in 33.0 mL of DMSO, and 5.93 g (43.6 mmol) of the compound 1i was added thereto and then, heated to 60° C. After stirring for 2 hours, the temperature was slowly decreased to ambient temperature. Subsequently, diethyl ether was added to the reaction mixture to produce solids, and the solids were separated through the vacuum filtration. The corresponding solid was washed with a 10% sodium chloride aqueous solution and dried overnight in a 40° C. vacuum oven to obtain 5.80 g (4.09 mmol) of a compound represented by Chemical Formula 3-1-1A.

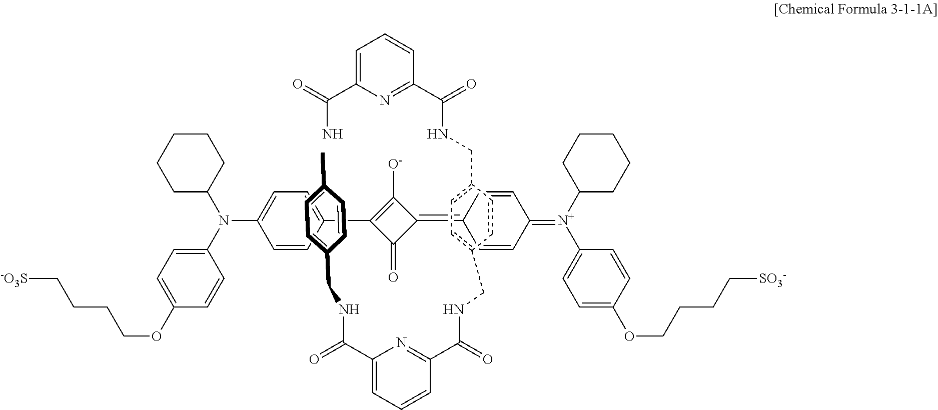

The HRMS analysis results of the compound represented by Chemical Formula 3-1-1A are as follows.

m/z calcd for C₇₈H₈₃N₈O₁₄S₂, 1419.5465; found, 1419.5465.

### Synthesis Example 2: Compound Represented by Chemical Formula 3-2-1A

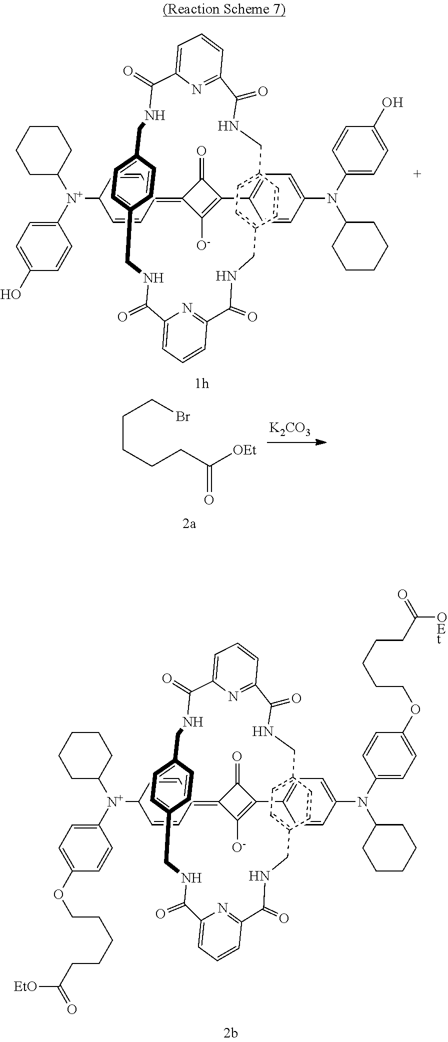

5.0 g (4.36 mmol) of the compound 1h and 6.03 g (43.6 mmol) of K₂CO₃ were dissolved in 35.0 mL of DMSO to prepare a solution, and 9.72 g (43.6 mmol) of the compound 2a was added thereto and then, heated to 80° C. After stirring overnight, the temperature was slowly decreased to ambient temperature. Subsequently, diethyl ether was added to the reaction mixture to produce solids, and the solids were separated through the vacuum filtration. The corresponding solid was washed with a 10% sodium chloride aqueous solution and dried in a 40° C. vacuum oven to obtain 5.58 g (3.90 mmol) of the compound 2b.

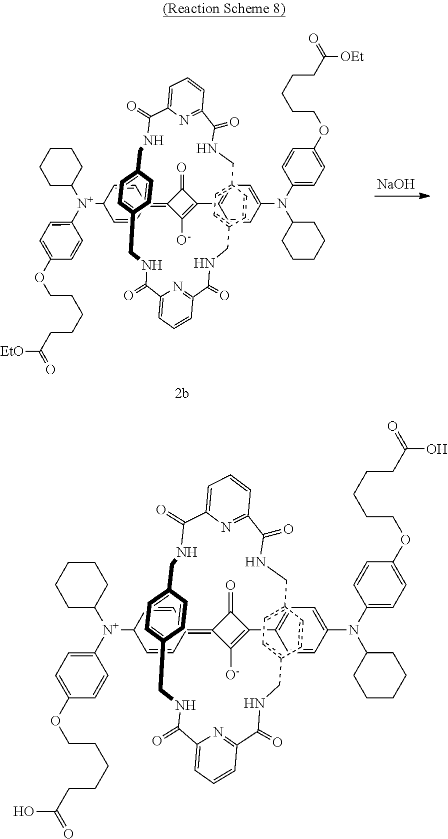

3.00 g (2.09 mmol) of the compound 2b was dissolved in 20.0 mL of tetrahydrofuran to obtain a solution, and 20.0 mL of a 1 N sodium hydroxide aqueous solution was added thereto and then, stirred at ambient temperature overnight. Subsequently, a 1 N hydrochloric acid aqueous solution was slowly added to the reaction mixture and then, extracted with dichloromethane. The corresponding organic layer was passed through MgSO₄, and the solvent therefrom was removed under the reduced pressure condition to obtain 2.74 g (1.99 mmol) of a compound represented by Chemical Formula 3-2-1A.

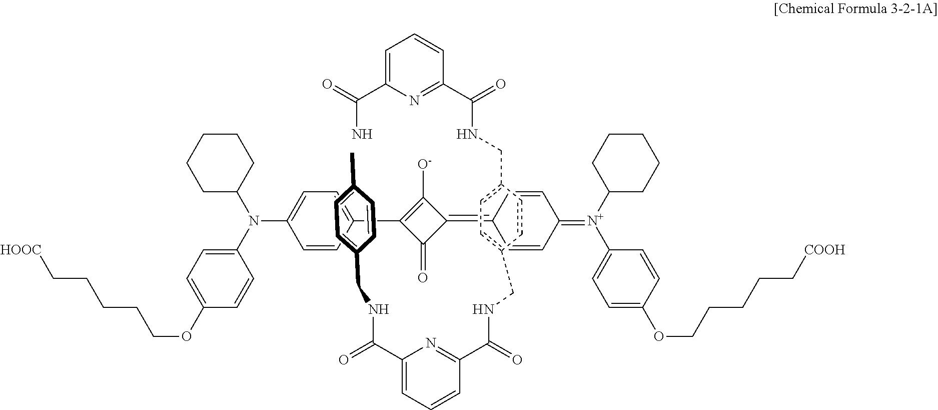

The HRMS analysis results of the compound represented by Chemical Formula 3-2-1A are as follows.

m/z calcd for C₈₂H₈₇N₈O₁₂, 1375.6443; found, 1375.6411

### Synthesis Example 3: Compound Represented by Chemical Formula 3-3-1A

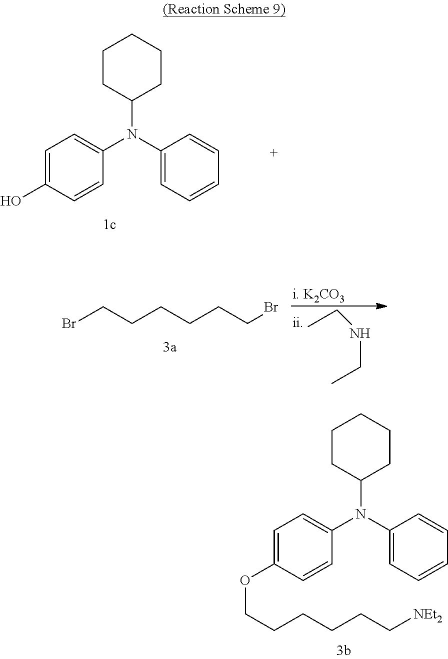

5.35 g (20.0 mmol) of the compound 1c and 5.53 g (40.0 mmol) of K₂CO₃ were dissolved in 30 mL of acetonitrile to obtain a solution, and 24.4 g (100 mmol) of the compound 3a was added thereto. The corresponding reaction mixture was heated at 60° C. and stirred overnight. After removing the acetonitrile under the reduced pressure condition, distilled water was added thereto and then, extracted by using ethyl acetate. The corresponding organic layer was rewashed with distilled water and then, passed through MgSO₄. After removing the solvent under the reduced pressure condition, an excess of the compound 3a was removed at 180° C. through distillation under a reduced pressure. As a result, the produce compound was dissolved with 4.14 mL (40.0 mmol) of N,N-diethylamine in 30 mL of acetonitrile and then, proceeded with a reaction overnight at 80° C. After removing the acetonitrile under the reduced pressure condition, after adding distilled water thereto, extraction was performed by using ethyl acetate. The corresponding organic layer was washed with distilled water, passed through MgSO₄, and then, concentrated under reduced pressure. 4.48 g (10.6 mmol) of the compound 3b was obtained through column chromatography (eluent: n-hexane/EtOAC=9/1).

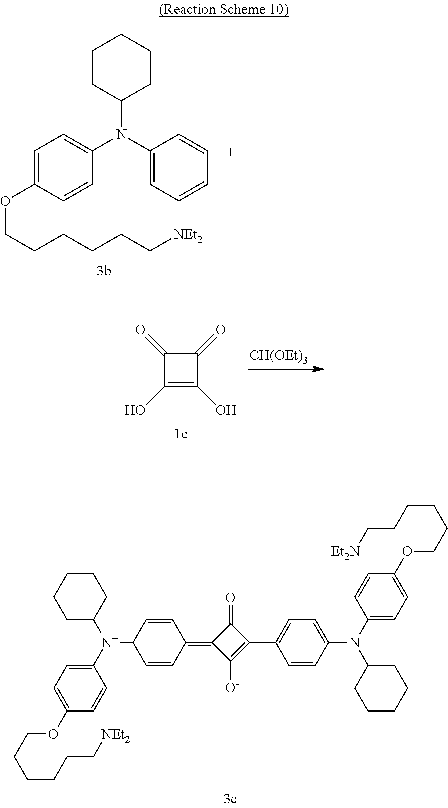

The compound 3c was synthesized in a similar manner as in the compound 1f.

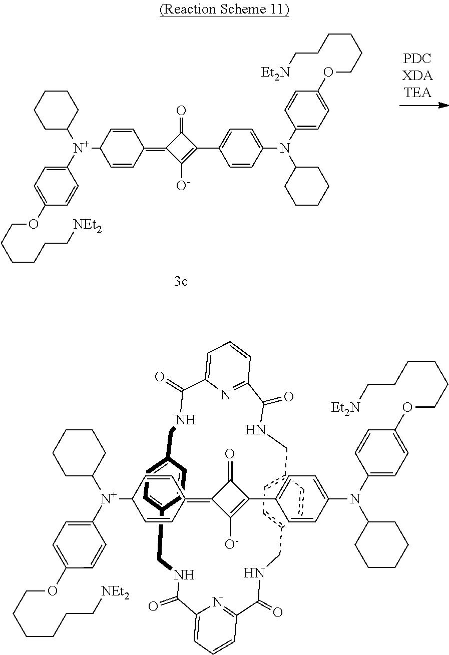

The following compound represented by Chemical Formula 3-3-1A was synthesized in a similar manner as in the compound 1g.

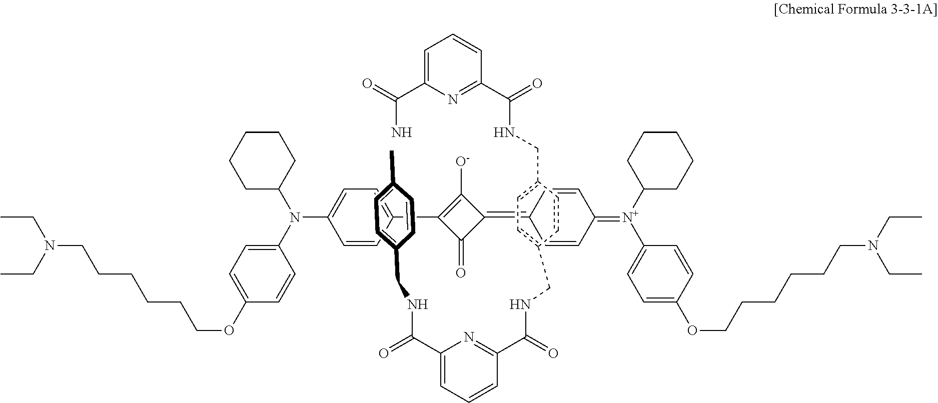

The results of MALDI-TOF analysis of the compound represented by Chemical Formula 3-3-1A are as follows.

m/z calcd for C₉₀H₁₀₉N₁₀O₈, 1457.84; found, 1457.84.

### Synthesis Example 4: Compound Represented by Chemical Formula 3-4-1A

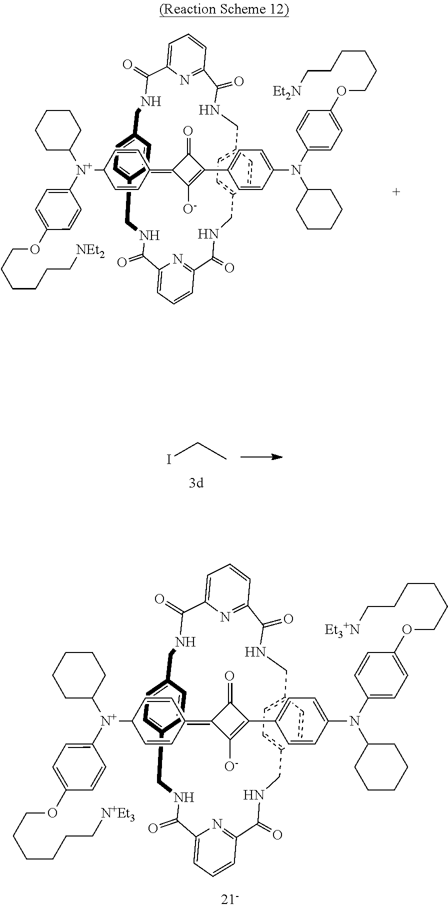

2.00 g (1.37 mmol) of the compound represented by Chemical Formula 3-3-1A and 2.14 g (13.7 mmol) of the compound 3d were dissolved in 20 mL of acetonitrile and then, proceeded with a reflux reaction. After slowly cooling to ambient temperature, diethyl ether was added thereto to produce solids. The corresponding solids were separated through the vacuum filtration and washed with a 10% sodium chloride aqueous solution to obtain a compound represented by Chemical Formula 3-4-1A.

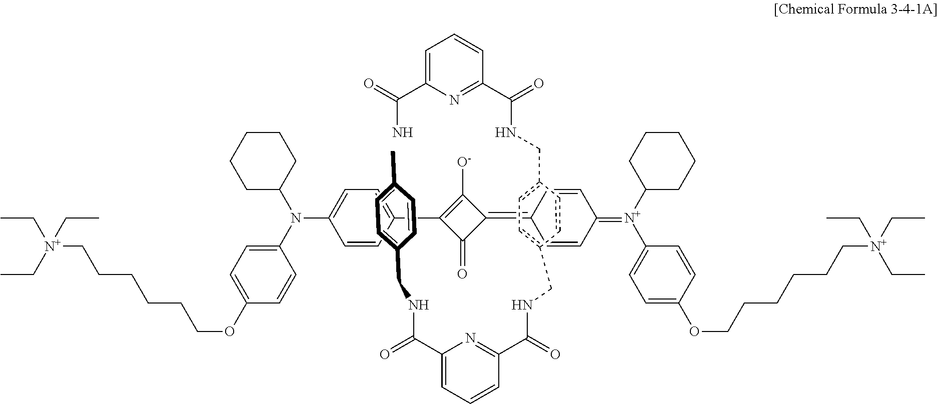

The results of MALDI-TOF analysis of the compound represented by Chemical Formula 3-4-1A are as follows.

m/z calcd for C₉₄H₁₁₈N₁₀O₈, 1514.91; found, 1514.91.

### Synthesis Example 5: Compound Represented by Chemical Formula 3-5-1A

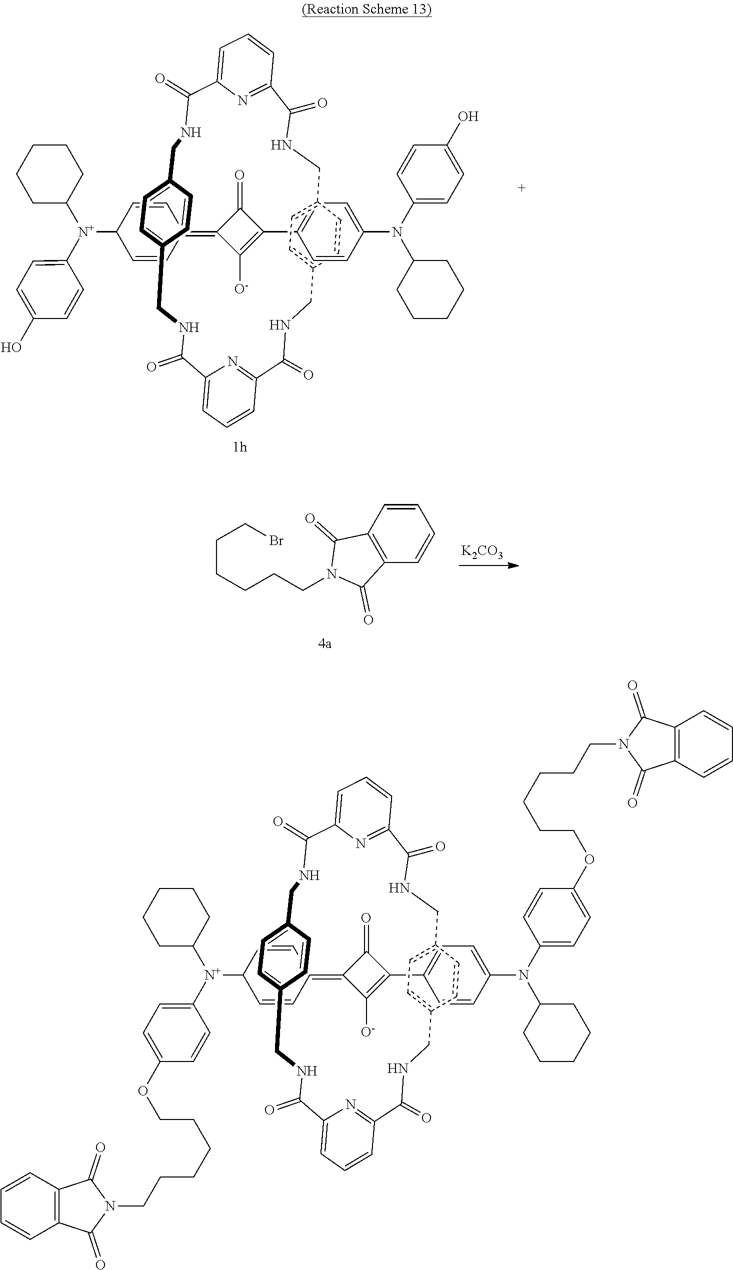

The compound represented by Chemical Formula 3-5-1A was synthesized in a similar manner as in the compound 2b.

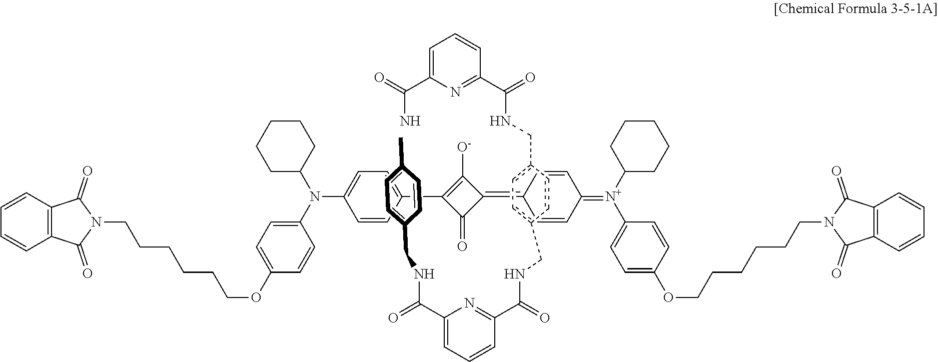

The results of MALDI-TOF analysis of the compound represented by Chemical Formula 3-5-1A are as follows.

m/z calcd for C₉₈H₉₇N₁₀O₁₂, 1605.73; found, 1605.72.

### Comparative Synthesis Example 1

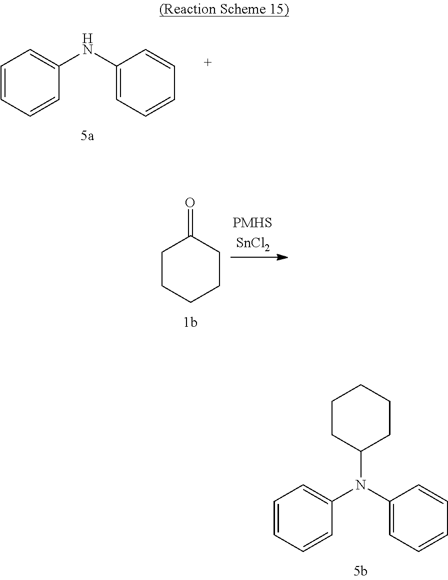 [SMILES: c1ccc(Nc2ccccc2)cc1 ; O=C1CCCCC1 ; c1ccc(N(c2ccccc2)C2CCCCC2)cc1]

The compound 5b was synthesized in a similar manner as in the compound 1c.

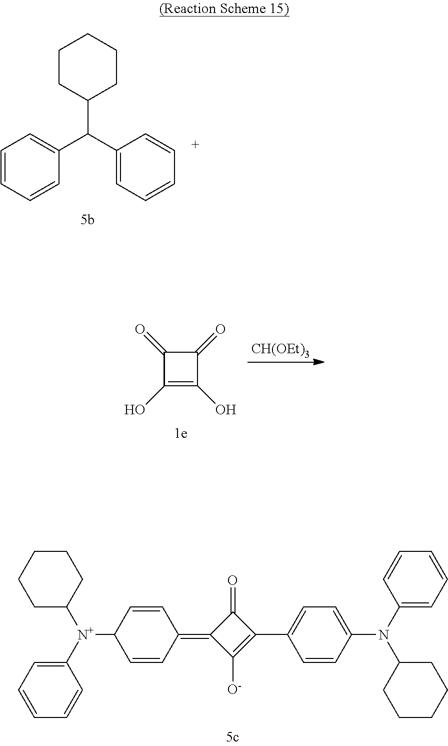

The compound 5c was synthesized in a similar manner as in the compound 1f.

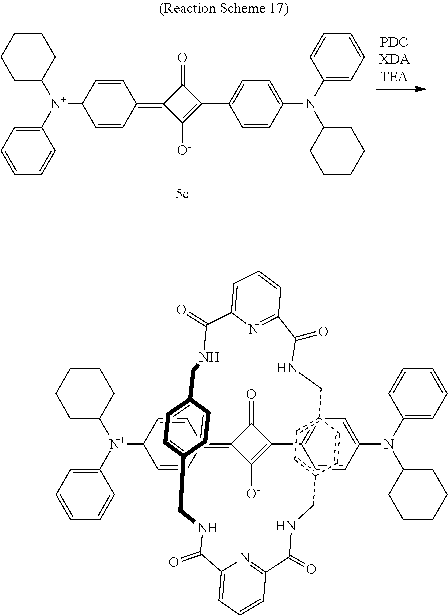

A compound represented by Chemical Formula A was synthesized in a similar manner as in the compound 1g.

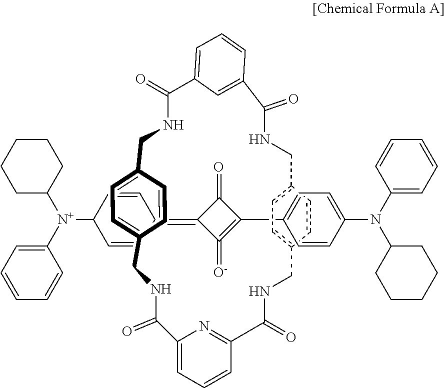

The results of MALDI-TOF analysis of the compound represented by Chemical Formula A are as follows.

m/z calcd for C₇₀H₆₇N₋₈O₆, 1115.52; found, 1115.52.

### Comparative Synthesis Example 2

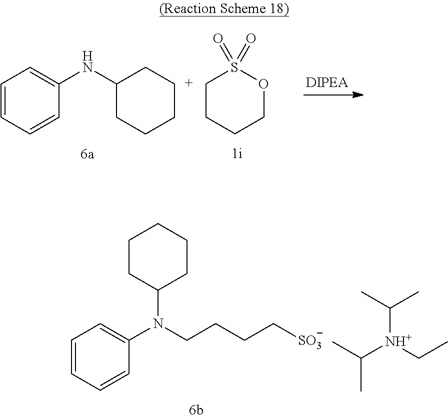

1.75 g (10.0 mmol) of the compound 6a and 3.83 mL (22.0 mmol) of N,N-diisopropylethylamine (DIPEA) were dissolved in 10 mL of acetonitrile to prepare a solution in a high pressure tube, and 1.63 g (12 mmol) of the compound 1i was added thereto. The corresponding reaction mixture was heated at 120° C. for 6 hours. After removing the solvent under the reduced pressure condition, ethyl acetate was added thereto. A solid by-product produced therefrom was removed through the vacuum filtration, and the solvent was also removed therefrom under the vacuum condition to obtain the compound 6b.

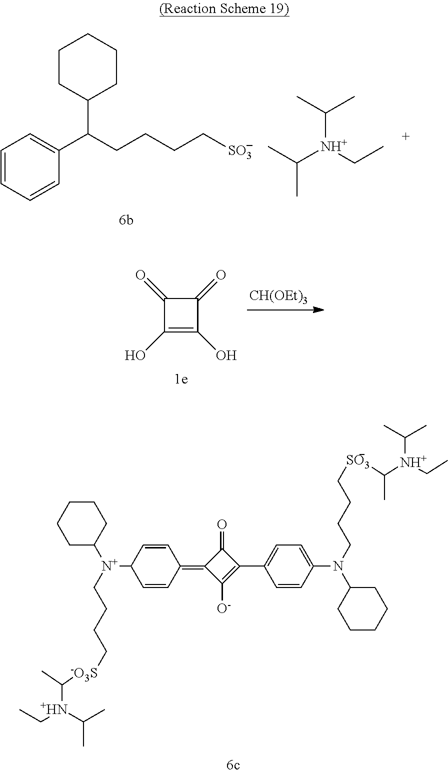

The compound 6c was synthesized in a similar manner as in the compound 1g.

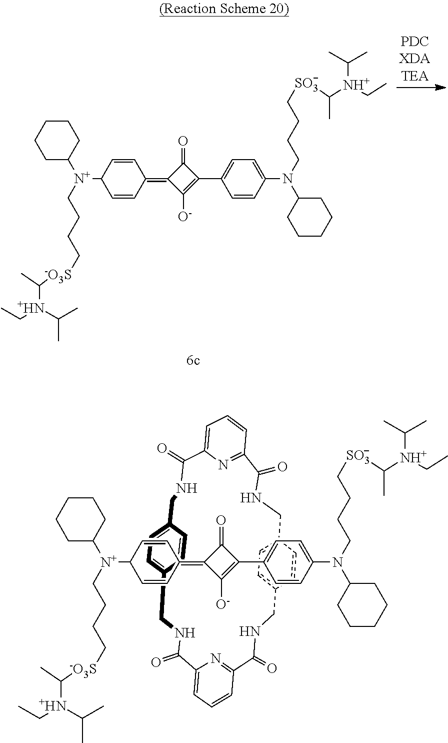

A compound represented by Chemical Formula B was synthesized in a similar manner as in the compound 1g.

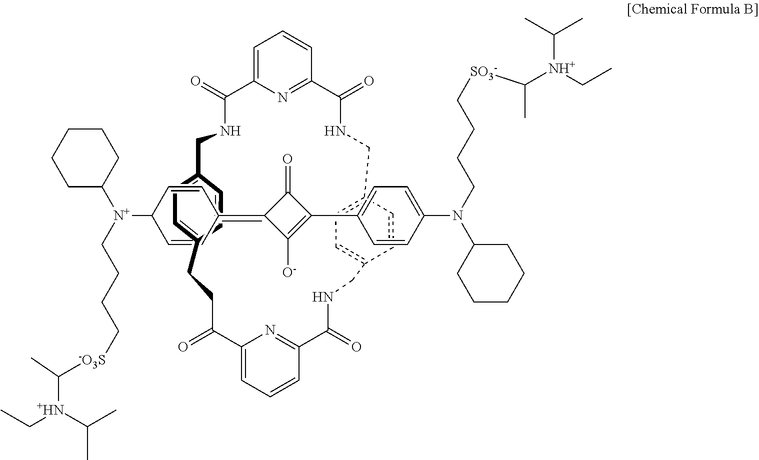

The results of MALDI-TOF analysis of the compound represented by Chemical Formula B are as follows.

m/z calcd for C₆₆H₇₅N₋₈O₁₂S₂, 1235.49; found, 1235.49.

### Preparation of Green Pigment Dispersion

Green pigment dispersion of Preparation Examples 1 to 10 and Comparative Examples 1 to 3 was prepared to have each composition shown in Tables 1 to 3.

The green pigment dispersion was obtained by mixing a green pigment, a dispersant, a dispersion aid, and a solvent, adding 300 parts by weight of zirconia beads (diameter: 0.4 μm) based on 100 parts by weight of this mixture thereto, shaking and dispersing the mixture for 3 hours by using a paint shaker, and removing the zirconia beads therefrom by filtration.

TABLE 1
(unit: wt %)

| | | Preparation | Preparation | Preparation | Preparation | Preparation |
|---|---|---|---|---|---|---|
| | | Example 1 | Example 2 | Example 3 | Example 4 | Example 5 |
| Green pigment | | 12.0 | 12.0 | 12.0 | 12.0 | 12.0 |
| Dispersant | | 2.5 | 2.5 | 2.5 | 2.5 | 2.5 |
| Dispersion | Synthesis | 0.5 | — | — | — | — |
| aid | Example 1 | | | | | |
| | Synthesis | — | 0.5 | — | — | — |
| | Example 2 | | | | | |
| | Synthesis | — | — | 0.5 | — | — |
| | Example 3 | | | | | |
| | Synthesis | — | — | — | 0.5 | — |
| | Example 4 | | | | | |
| | Synthesis | — | — | — | — | 0.5 |
| | Example 5 | | | | | |
| | Synthesis | — | — | — | — | — |
| | Example 6 | | | | | |

| | | | | | |
|---|---|---|---|---|---|
| Solvent | 85.0 | 85.0 | 85.0 | 85.0 | 85.0 |

TABLE 2
(unit: wt %)

| | | Preparation | Preparation | Preparation | Preparation | Preparation | Preparation |
|---|---|---|---|---|---|---|---|
| | | Example 6 | Example 7 | Example 3 | Example 8 | Example 9 | Example 10 |
| Green pigment | | 12.0 | 12.0 | 12.0 | 12.0 | 12.0 | 12.0 |
| Dispersant | | 2.5 | 2.5 | 2.5 | 2.5 | 2.5 | 2.5 |
| Dispersion | Synthesis | — | — | — | — | — | — |
| aid | Example 1 | | | | | | |
| | Synthesis | — | — | — | — | — | — |
| | Example 2 | | | | | | |
| | Synthesis | 0.3 | 0.4 | 0.5 | 0.6 | 1.0 | 1.2 |
| | Example 3 | | | | | | |
| | Synthesis | — | — | — | — | — | — |
| | Example 4 | | | | | | |
| | Synthesis | — | — | — | — | — | — |
| | Example 5 | | | | | | |
| | Synthesis | — | — | — | — | — | — |
| | Example 6 | | | | | | |

| | | | | | | |
|---|---|---|---|---|---|---|
| Solvent | 85.2 | 85.1 | 85.0 | 84.9 | 84.5 | 84.3 |

TABLE 3
(unit: wt %)

| | | Comparative | Comparative | Comparative |
|---|---|---|---|---|
| | | Preparation | Preparation | Preparation |
| | | Example 1 | Example 2 | Example 3 |
| Green pigment | | 12.0 | 12.0 | 12.0 |
| Dispersant | | 2.5 | 2.5 | 2.5 |
| Dispersion aid | Comparative | — | 0.5 | — |
| | Synthesis | | | |
| | Example 1 | | | |
| | Comparative | — | — | 0.5 |
| | Synthesis | | | |
| | Example 2 | | | |

| | | | |
|---|---|---|---|
| Solvent (PGMEA) | 85.5 | 85.0 | 85.0 |

The materials used in Tables 1 to 3 are as follows.
Green pigment: C.I. PIGMENT Green 58 G58
Dispersant: BYK-LPN6919 (Manufacturer: BYK)
Dispersing aid: each compound of Synthesis Examples 1 to 6, Comparative Synthesis Examples 1 and 2

### Solvent: propylene glycol monomethylether acetate (PGMEA)

### Preparation of Yellow Pigment Dispersion

Yellow pigment dispersion was prepared by mixing 12.0 parts by weight of a yellow pigment (C.I. PIGMENT Yellow 138), 3.0 parts by weight of a dispersant (BYK-LPN6919, Manufacturer: BYK), and 85.0 parts by weight of a solvent (propylene glycol monomethylether acetate, PGMEA), adding 300 parts by weight of zirconia beads (diameter: 0.4 μm) based on 100 parts by weight of this mixture thereto, shaking and dispersing the mixture by a paint shaker for 3 hours, and removing the zirconia beads by filtration.

### Preparation of Photosensitive Resin Composition

The photosensitive resin compositions of Examples 1 to 10 and Comparative Examples 1 to 3 were prepared by mixing the compositions shown in Tables 4 to 6.

Each photosensitive colored resin composition was prepared by mixing the green pigment dispersion, the yellow pigment dispersion, the photopolymerizable compound, the photopolymerization initiator, the binder resin, and the solvent.

TABLE 4

| | | | Example 1 | Example 2 | Example 3 | Example 4 | Example 5 |
|---|---|---|---|---|---|---|---|
| (A) | Green | Preparation | 20.0 | — | — | — | — |
| Colorant | pigment | Example 1 | | | | | |
| | dispersion | Preparation | — | 20.0 | — | — | — |
| | | Example 2 | | | | | |
| | | Preparation | — | — | 20.0 | — | — |
| | | Example 3 | | | | | |
| | | Preparation | — | — | — | 20.0 | — |
| | | Example 4 | | | | | |
| | | Preparation | — | — | — | — | 20.0 |
| | | Example 5 | | | | | |

| | | | | | |
|---|---|---|---|---|---|
| Yellow pigment dispersion | 15.0 | 15.0 | 15.0 | 15.0 | 15.0 |

| (B) | DPHA | 5.0 | 5.0 | 5.0 | 5.0 | 5.0 |
|---|---|---|---|---|---|---|
| Photopolymerizable | | | | | | |
| compound | | | | | | |
| (C) | A1 | 1.0 | 1.0 | 1.0 | 1.0 | 1.0 |
| Photopolymerization | A2 | 0.5 | 0.5 | 0.5 | 0.5 | 0.5 |
| initiator | | | | | | |
| (D) Binder resin | | 3.5 | 3.5 | 3.5 | 3.5 | 3.5 |
| (E) Solvent | PGMEA | 55.0 | 55.0 | 55.0 | 55.0 | 55.0 |

TABLE 5

| | | | Example | Example | Example | Example | Example | Example |
|---|---|---|---|---|---|---|---|---|
| | | | 6 | 7 | 3 | 8 | 9 | 10 |
| (A) | Green | Preparation | 20.0 | — | — | — | — | — |
| Colorant | pigment | Example 6 | | | | | | |
| | dispersion | Preparation | — | 20.0 | — | — | — | — |
| | | Example 7 | | | | | | |
| | | Preparation | — | — | 20.0 | — | — | — |
| | | Example 3 | | | | | | |
| | | Preparation | — | — | — | 20.0 | — | — |
| | | Example 8 | | | | | | |
| | | Preparation | — | — | — | — | 20.0 | — |
| | | Example 9 | | | | | | |
| | | Preparation | — | — | — | — | — | 20.0 |
| | | Example 10 | | | | | | |

| | | | | | | |
|---|---|---|---|---|---|---|
| Yellow pigment dispersion | 15.0 | 15.0 | 15.0 | 15.0 | 15.0 | 15.0 |

| (B) | DPHA | 5.0 | 5.0 | 5.0 | 5.0 | 5.0 | 5.0 |
|---|---|---|---|---|---|---|---|
| Photopolymerizable | | | | | | | |
| compound | | | | | | | |
| (C) | A1 | 1.0 | 1.0 | 1.0 | 1.0 | 1.0 | 1.0 |
| Photopolymerization | A2 | 0.5 | 0.5 | 0.5 | 0.5 | 0.5 | 0.5 |
| initiator | | | | | | | |
| (D) Binder resin | | 3.5 | 3.5 | 3.5 | 3.5 | 3.5 | 3.5 |
| (E) Solvent | PGMEA | 55.0 | 55.0 | 55.0 | 55.0 | 55.0 | 55.0 |

TABLE 6

| | | | Comparative | Comparative | Comparative |
|---|---|---|---|---|---|
| | | | Example 1 | Example 2 | Example 3 |
| (A) | Green pigment | Comparative | 20.0 | — | — |
| Colorant | dispersion | Preparation | | | |
| | | Example 1 | | | |
| | | Comparative | — | 20.0 | — |
| | | Preparation | | | |
| | | Example 2 | | | |
| | | Comparative | — | — | 20.0 |
| | | Preparation | | | |
| | | Example 3 | | | |

| | | | |
|---|---|---|---|
| Yellow pigment dispersion | 15.0 | 15.0 | 15.0 |

| (B) Photopolymerizable | DPHA | 5.0 | 5.0 | 5.0 |
|---|---|---|---|---|
| compound | | | | |
| (C) Photopolymerization | C-1 | 1.0 | 1.0 | 1.0 |
| initiator | C-2 | 0.5 | 0.5 | 0.5 |
| (D) Binder resin | | 3.5 | 3.5 | 3.5 |
| (E) Solvent | PGMEA | 55.0 | 55.0 | 55.0 |

The materials used in Tables 4 to 6 are as follows.
(A) Colorant
(A-1) Green pigment dispersion: Each green pigment dispersion of Preparation Examples 1 to 10 and Comparative Preparation Examples 1 to 3
(A-2) Yellow pigment dispersion
(B) Photopolymerizable compound

Dipentaerythritol hexaacrylate (DPHA, manufacturer: Nippon Kayaku Co., Ltd.)
(C) Photopolymerization initiator
(C-1) 1,2-octanedione
(C-2) 2-dimethylamino-2-(4-methyl-benzyl)-1-(4-morpholin-4-yl-phenyl)-butan-1-one
(D) Binder resin

Resin copolymerized with benzyl methacrylate and methacrylic acid at 85:15 (Mw=22,000)
(E) Solvent

Propylene glycol monomethylether acetate (PGMEA)

### Evaluation Example 1: Dispersibility and Dispersion Stability

Each of the photosensitive resin compositions according to Examples 1 to 10 and Comparative Examples 1 to 3 was measured a solid particle diameter by using dynamic light scattering analysis equipment, and the results are shown in Table 7.

In addition, the photosensitive resin compositions according to Examples 1 to 10 and Comparative Examples 1 to 3 were evaluated with respect to viscosity before and after stored at 23° C. for 1 week at 5 rpm (rpm with a Torque value of 50% to 100%) by using Brookfield DV-II Pro viscometer and CPE-52 Spindle at 25° C., and the results are shown in Table 7.

TABLE 7

| | Solid particle diameter (nm) | | | Viscosity (cPs) | | |
|---|---|---|---|---|---|---|
| | After | After | | After | After | |
| | preparation | 1 week | Difference | preparation | 1 week | Difference |
| Example 1 | 52 | 52 | 0 | 4.31 | 4.33 | +0.02 |
| Example 2 | 51 | 52 | +1 | 4.27 | 4.29 | +0.02 |
| Example 3 | 53 | 51 | −2 | 4.44 | 4.42 | −0.02 |
| Example 4 | 52 | 52 | 0 | 4.52 | 4.55 | +0.03 |
| Example 5 | 54 | 53 | −1 | 4.42 | 4.44 | +0.02 |
| Example 6 | 55 | 54 | −1 | 4.44 | 4.46 | +0.02 |
| Example 7 | 53 | 52 | −1 | 4.34 | 4.34 | 0.00 |
| Example 8 | 52 | 54 | +2 | 4.27 | 4.28 | +0.01 |
| Example 9 | 52 | 54 | +2 | 4.31 | 4.29 | −0.02 |
| Example 10 | 54 | 52 | −2 | 4.33 | 4.32 | −0.01 |
| Comparative | 52 | 52 | 0 | 4.33 | 4.32 | −0.01 |
| Example 1 | | | | | | |
| Comparative | 51 | 52 | +1 | 4.27 | 4.30 | +0.03 |
| Example 2 | | | | | | |
| Comparative | 52 | 52 | 0 | 4.39 | 4.41 | +0.02 |
| Example 3 | | | | | | |

* In Table 7, when a change in a solid particle diameter and viscosity was 10% or less, “satisfactory” was given.

Referring to Table 7, the photosensitive resin compositions according to Examples 1 to 10 exhibited a smaller change in the viscosity as well as in the solid particle diameter before and after stored for 1 week than the photosensitive resin compositions according to Comparative Examples 1 and 2.

### Evaluation Example 2: Coloring Power and Contrast Ratio

Each photosensitive resin composition of Examples 1 to 10 and Comparative Examples 1 to 3 was coated to be 1 to 3 μm thick on a 1 mm-thick glass substrate, which was degreased and washed, and then, dried on a hot plate at 90° C. for 2 minutes to obtain a film. Subsequently, the film was exposed to light by using a high-pressure mercury lamp with a main wavelength of 365 nm and dried in a forced convection drying furnace at 200° C. for 5 minutes to obtain a color filter specimen.

A pixel layer was evaluated were measuring a color coordinate (x, y), luminance (Y), thickness, and a contrast ratio of the color filter specimens by using a spectrophotometer (MCPD3000, Otsuka Electronics Co., Ltd.), and the results are shown in Tables 8 to 10.

TABLE 8

| | x | y | Y | THICK (μm) |
|---|---|---|---|---|
| Example 1 | 0.354 | 0.561 | 70.81 | 5,400 |
| Example 2 | | | 70.55 | 5,800 |
| Example 3 | | | 70.94 | 5,200 |
| Example 4 | | | 70.92 | 5,200 |
| Example 5 | | | 71.01 | 4,800 |

TABLE 9

| | x | y | Y | THICK (μm) |
|---|---|---|---|---|
| Example 6 | 0.354 | 0.561 | 70.77 | 5,600 |
| Example 7 | | | 70.79 | 5,500 |
| Example 3 | | | 70.94 | 5,200 |
| Example 8 | | | 70.98 | 5,120 |
| Example 9 | | | 71.01 | 4,780 |
| Example 10 | | | 71.11 | 4,540 |

TABLE 10

| | x | y | Y | THICK (μm) |
|---|---|---|---|---|
| Comparative | 0.354 | 0.561 | 70.21 | 6,100 |
| Example 1 | | | | |
| Comparative | | | 70.34 | 6,050 |
| Example 2 | | | | |
| Comparative | | | 70.27 | 6,100 |
| Example 3 | | | | |

* In Table 10, the higher Y and the thinner, the more excellent characteristics.

Referring to Tables 8 to 10, the color filter specimens of Examples 1 to 10, compared to the color filter specimens of Comparative Examples 1 and 3, exhibited improved coloring power and contrast ratio.

In the Examples, a dispersion aid represented by Chemical Formula 1 was used, and a photosensitive resin composition having excellent coloring power and contrast ratio as well as high pigment dispersibility and dispersion stability was realized.

Embodiments may be adjusted within the ranges of some example embodiments to control dispersibility, dispersion stability, coloring power, a contrast ratio, and the like to a desired level.

By way of summation and review, a photosensitive resin composition (pigment-type photosensitive resin composition) used to manufacture a color filter according to the pigment dispersion method may include an alkali-soluble resin, a photopolymerizable compound, a photopolymerization initiator, an epoxy resin, a solvent, and other additives. The pigment dispersion method having the above characteristics may used to manufacture LCDs for mobile phones, laptops, monitors, TVs, or the like.

A photosensitive resin composition for a color filter for the pigment dispersion method having improved performance as well as excellent pattern characteristics has been considered. High color reproducibility and luminance and high contrast ratio characteristics may be desirable.

One or more embodiments may provide a photosensitive resin composition that has high dispersibility and dispersion stability and has excellent coloring power and contrast ratio when implementing a color filter.

The photosensitive resin composition according to some example embodiments may have high dispersibility and dispersion stability, and may be excellent in coloring power and contrast ratio when implementing a color filter. Accordingly, excellent color filters and display devices may be implemented by using the photosensitive resin composition according to some example embodiments.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photosensitive resin composition, comprising:
a colorant;
a photopolymerizable compound;
a photopolymerization initiator;
a binder resin; and
a solvent;
wherein:
the colorant includes a pigment, a dispersant, and a dispersion aid represented by Chemical Formula 1, 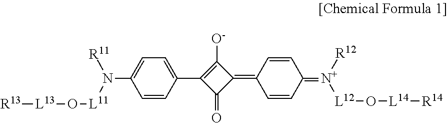
in Chemical Formula 1,
R¹¹ and R¹² are each independently a substituted or unsubstituted C1 to C20 alkyl group, a substituted or unsubstituted C3 to C20 cycloalkyl group, a substituted or unsubstituted C6 to C20 aryl group, or a substituted or unsubstituted C2 to C20 heteroaryl group,
R¹³ and R¹⁴ are each independently *—SO₃⁻, *—COOH, *—N(R^{a})₂, *—N⁺(R^{b})₃, or a N-phthalimidyl group,
R^{a} and R^{b} are each independently a hydrogen atom or a substituted or unsubstituted C1 to C20 alkyl group,
L¹¹ and L¹² are each independently a substituted or unsubstituted C6 to C20 arylene group, and
L¹³ and L¹⁴ are each independently a substituted or unsubstituted C1 to C20 alkylene group.

2. The photosensitive resin composition as claimed in claim 1, wherein
the dispersion aid is represented by Chemical Formula 1-1: 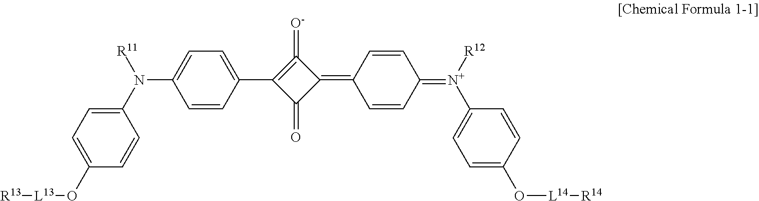
in Chemical Formula 1-1, R¹¹ to R¹⁴, L¹³, and L¹⁴ are defined the same as those of Chemical Formula 1.

3. The photosensitive resin composition as claimed in claim 1, wherein R¹¹ and R¹² are each independently a substituted or unsubstituted C5 or C6 cycloalkyl group.

4. The photosensitive resin composition as claimed in claim 1, wherein R¹³ and R¹⁴ are each independently *—SO₃⁻, *—COOH, *—NH₂, *—N(CH₂CH₃)₂, *—N⁺H₃, *—N⁺(CH₂CH₃)₃, or a N-phthalimidyl group.

5. The photosensitive resin composition as claimed in claim 1, wherein L¹³ and L¹⁴ are each independently a substituted or unsubstituted C4 to C6 alkylene group.

6. The photosensitive resin composition as claimed in claim 1, wherein the dispersion aid is represented by one of the following chemical formulae:

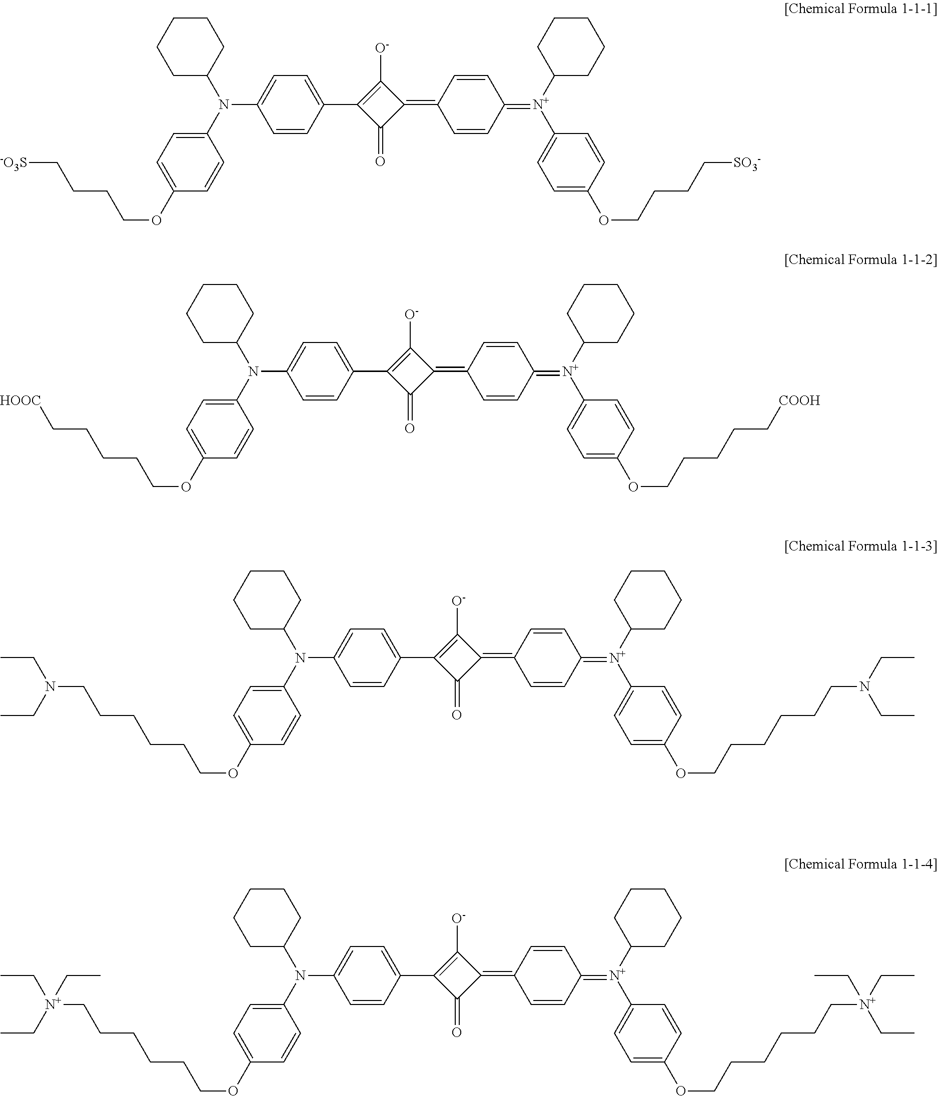

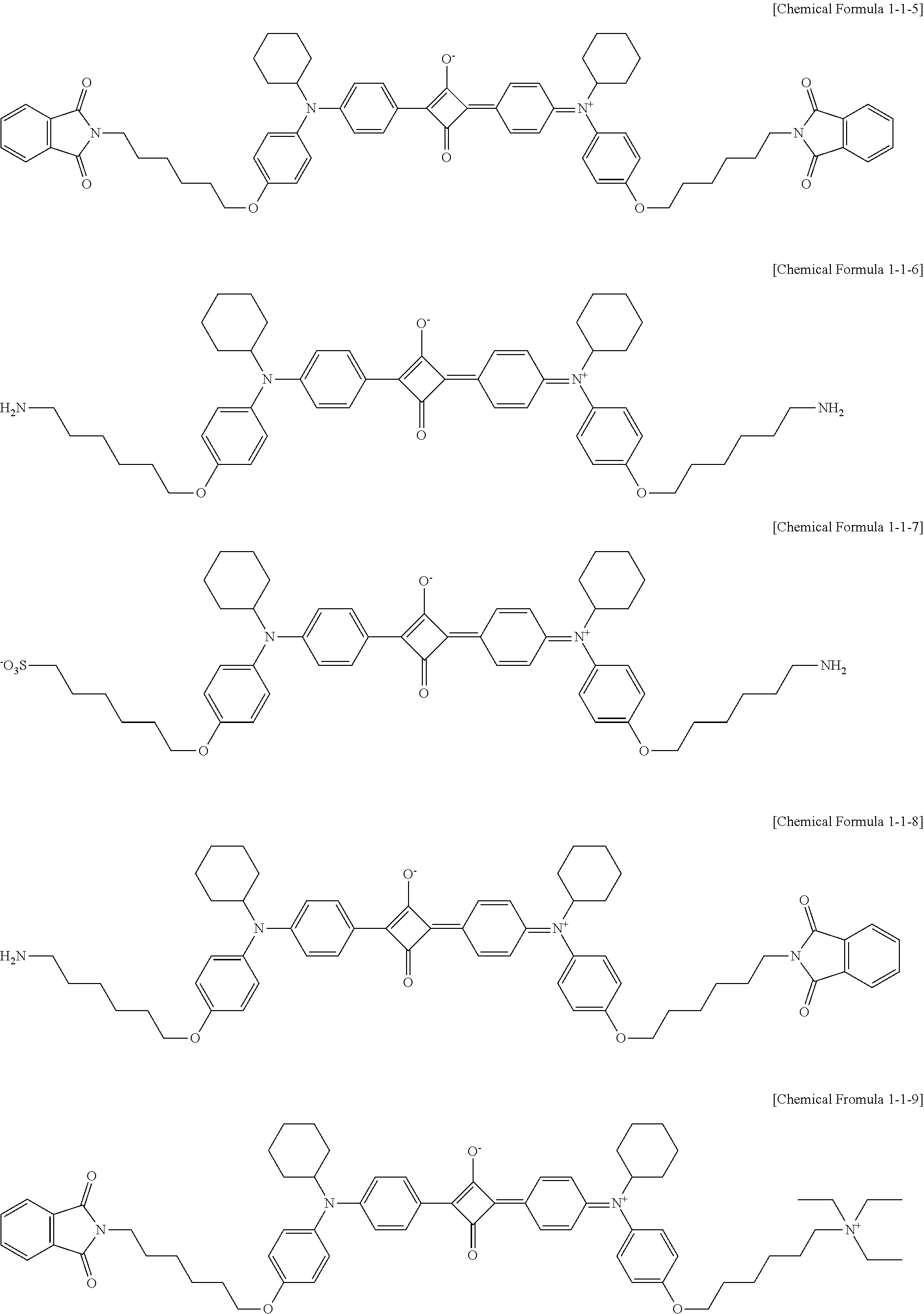

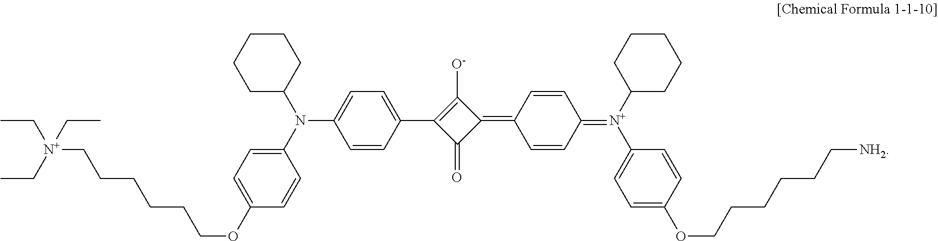 [SMILES: CC[N+](CC)(CC)CCCCCCOc1ccc(N(c2ccc(C3=C([O-])C(=C4C=CC(=[N+](c5ccc(OCCCCCCN)cc5)C5CCCCC5)C=C4)C3=O)cc2)C2CCCCC2)cc1]

7. The photosensitive resin composition as claimed in claim 1, wherein:
the dispersion aid includes the compound represented by Chemical Formula 1 as a core and further includes a shell surrounding the core,
the shell is a compound represented by Chemical Formula 2, 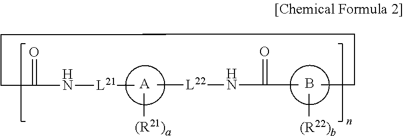
in Chemical Formula 2,
A and B are each independently a benzene ring, a pyridine ring, or a furan ring,
R²¹ and R²² are each independently a halogen atom or a substituted or unsubstituted C1 to C10 alkyl group,
L²¹ and L²² are each independently a substituted or unsubstituted C1 to C20 alkylene group or a substituted or unsubstituted C6 to C20 arylene group,
a and b are each independently an integer of 0 to 4, and
n is an integer or 2 to 10.

8. The photosensitive resin composition as claimed in claim 7, wherein
the shell is represented by one of Chemical Formulae 2-1 to 2-3: 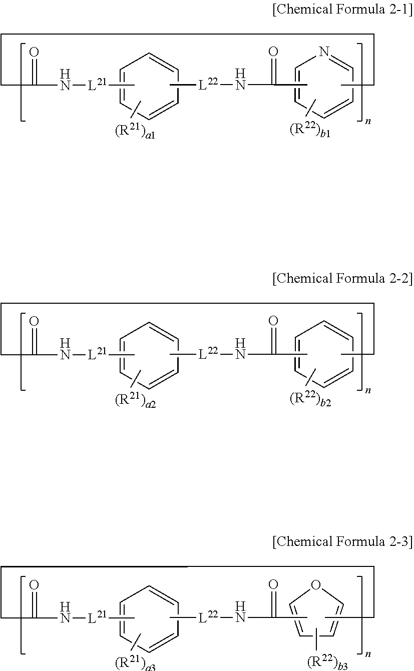
in Chemical Formulae 2-1 to 2-3,
R²¹ and R²² are each independently a halogen atom,
L²¹ and L²² are each independently a substituted or unsubstituted C1 to C20 alkylene group,
a1 and b1 are each independently an integer of 0 to 3,
a2 and b2 are each independently an integer of 0 to 4,
a3 and b3 are each independently an integer of 0 to 2, and
n is an integer of 2 to 10.

9. The photosensitive resin composition as claimed in claim 7, wherein L²¹ and L²² are each independently a substituted or unsubstituted C1 alkylene group.

10. The photosensitive resin composition as claimed in claim 7, wherein n is 2.

11. The photosensitive resin composition as claimed in claim 7, wherein the shell is represented by one of the following chemical formulae:

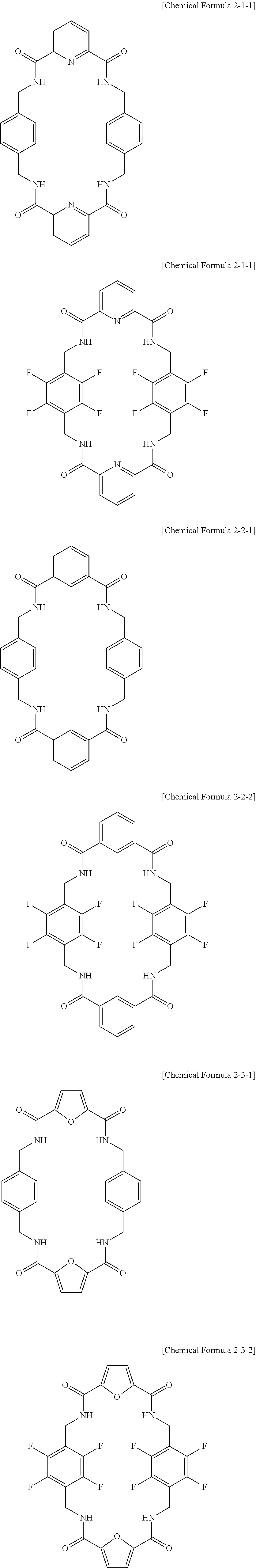 [SMILES: O=C1NCc2ccc(cc2)CNC(=O)c2cccc(n2)C(=O)NCc2ccc(cc2)CNC(=O)c2cccc1n2 ; O=C1NCc2c(F)c(F)c(c(F)c2F)CNC(=O)c2cccc(n2)C(=O)NCc2c(F)c(F)c(c(F)c2F)CNC(=O)c2cccc1n2 ; O=C1NCc2ccc(cc2)CNC(=O)c2cccc(c2)C(=O)NCc2ccc(cc2)CNC(=O)c2cccc1c2 ; O=C1NCc2c(F)c(F)c(c(F)c2F)CNC(=O)c2cccc(c2)C(=O)NCc2c(F)c(F)c(c(F)c2F)CNC(=O)c2cccc1c2 ; O=C1NCc2ccc(cc2)CNC(=O)c2ccc(o2)C(=O)NCc2ccc(cc2)CNC(=O)c2ccc1o2 ; O=C1NCc2c(F)c(F)c(c(F)c2F)CNC(=O)c2ccc(o2)C(=O)NCc2c(F)c(F)c(c(F)c2F)CNC(=O)c2ccc1o2]

12. The photosensitive resin composition as claimed in claim 1, wherein the dispersion aid is represented by one of the following chemical formulae:

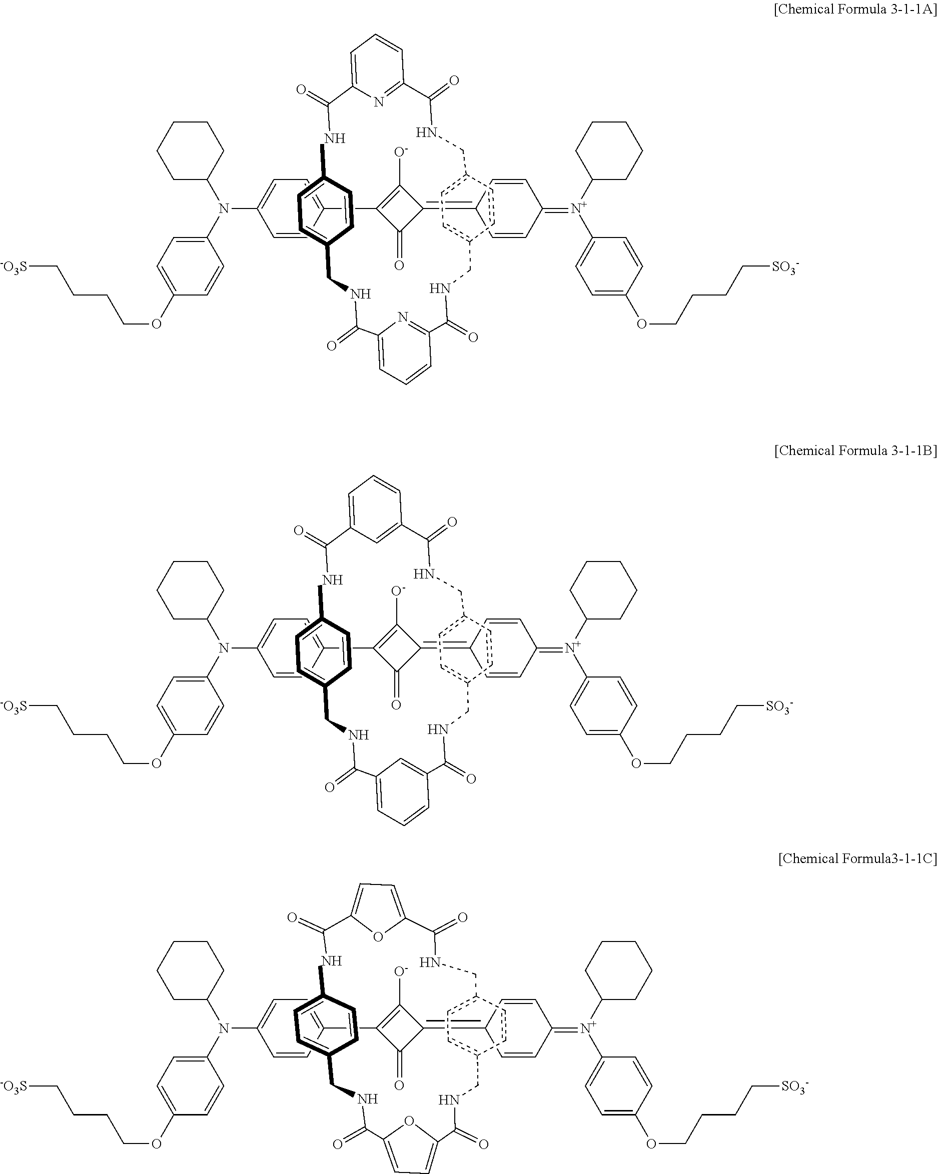

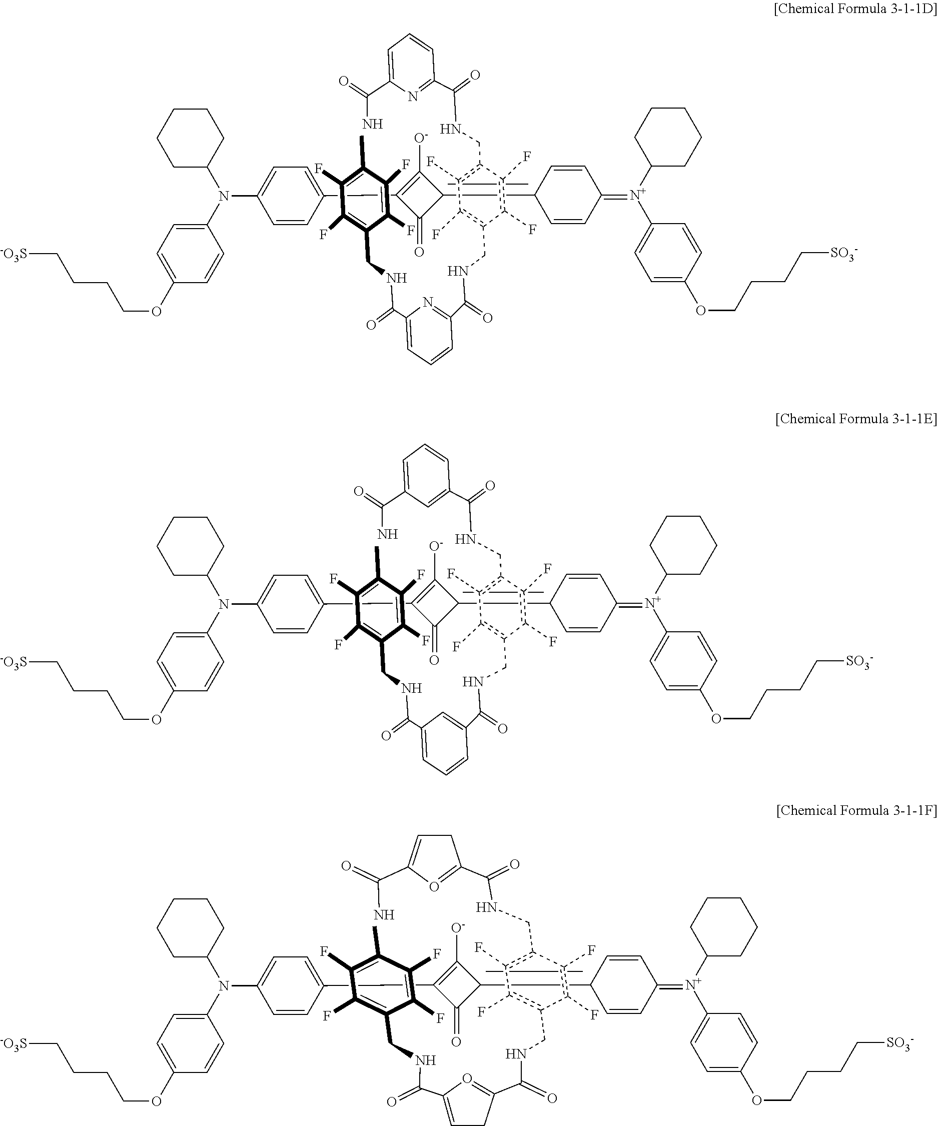

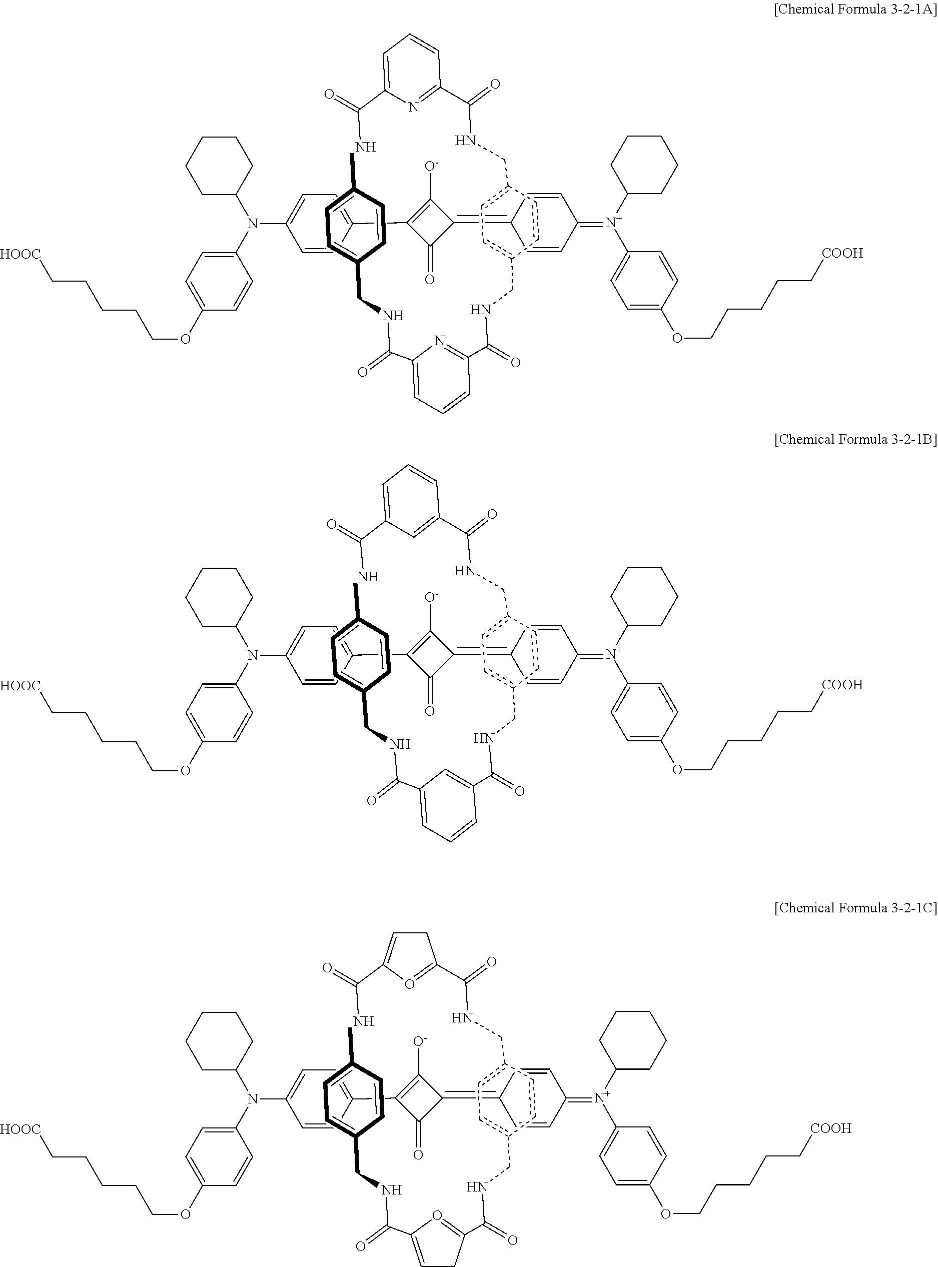

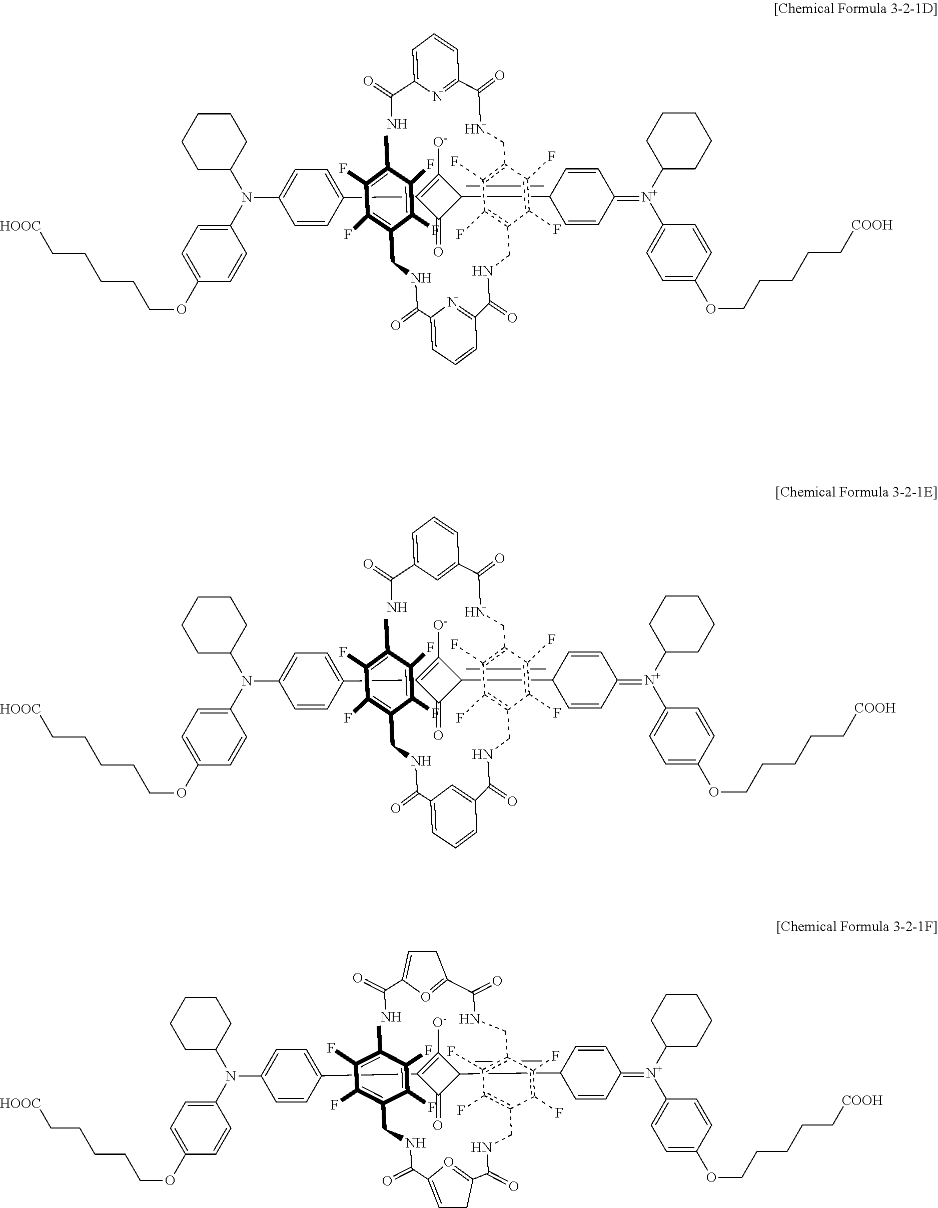

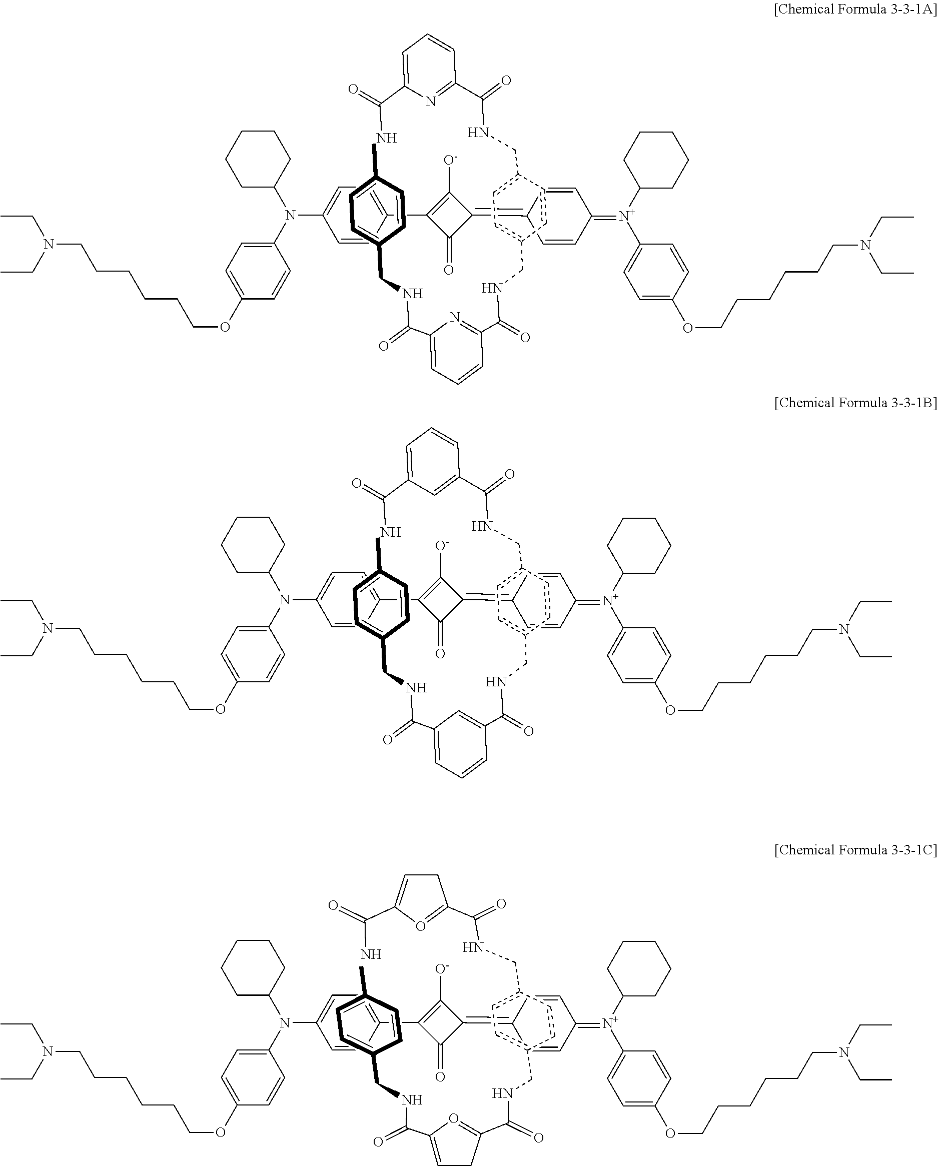

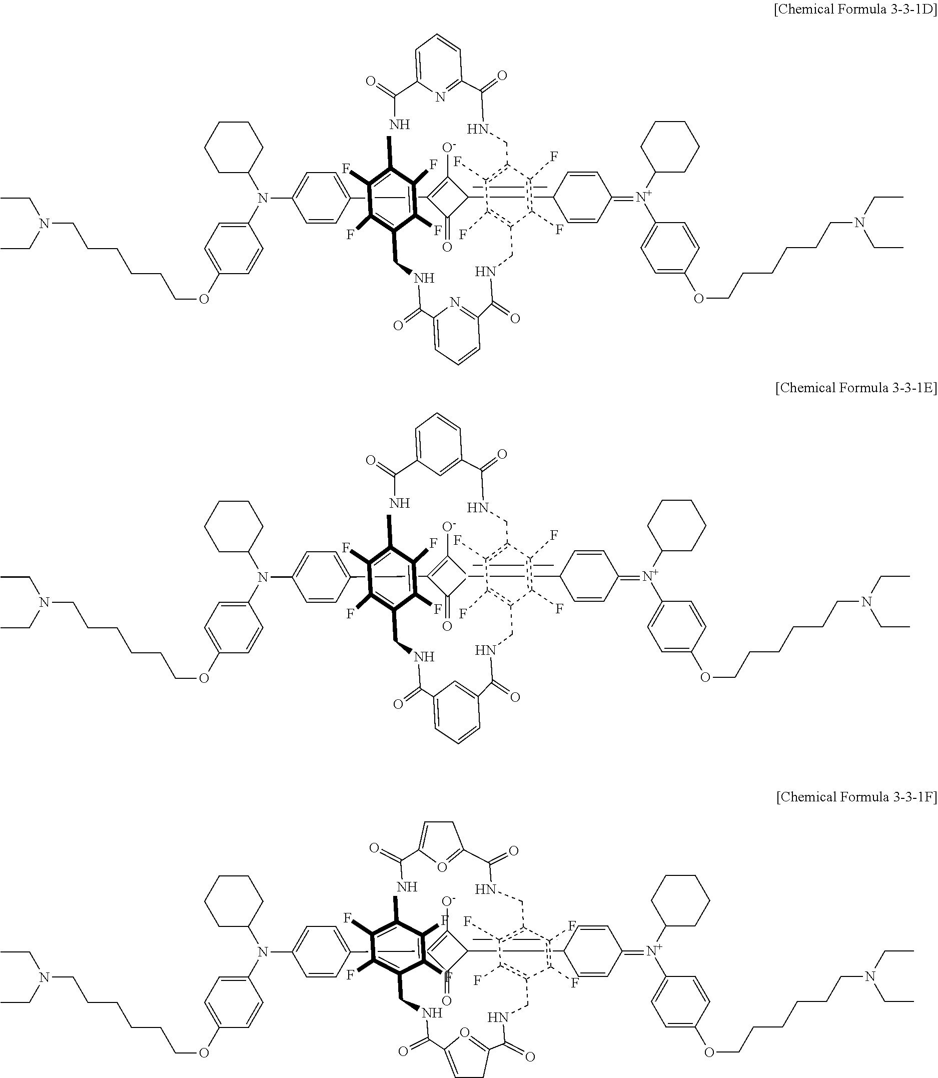

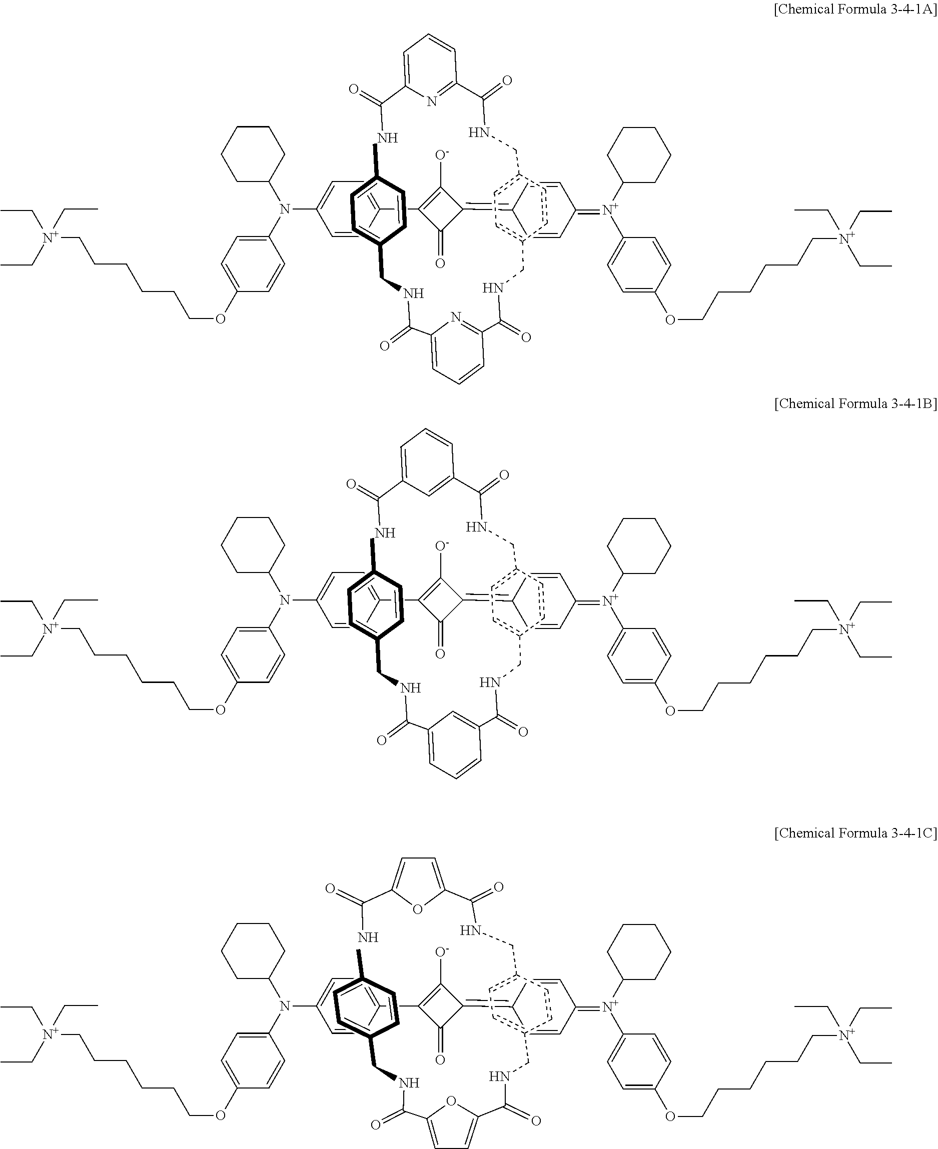

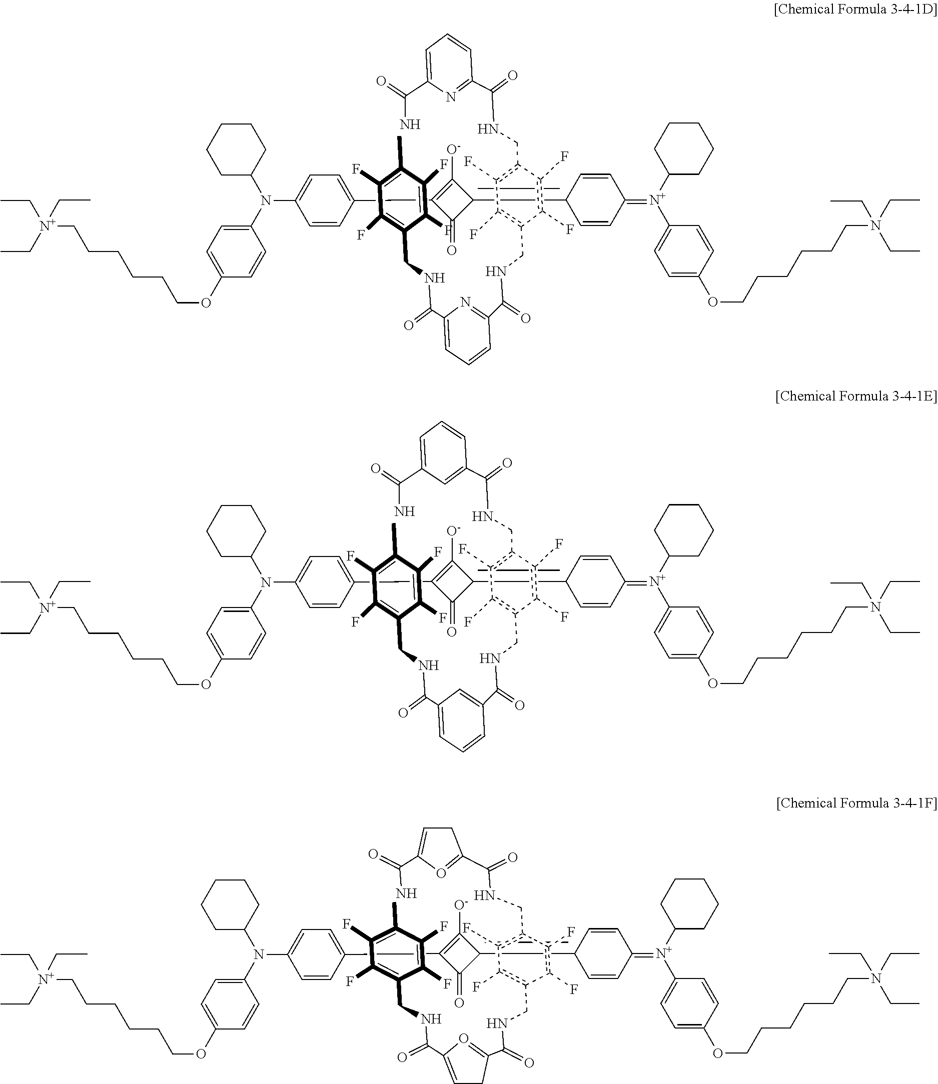

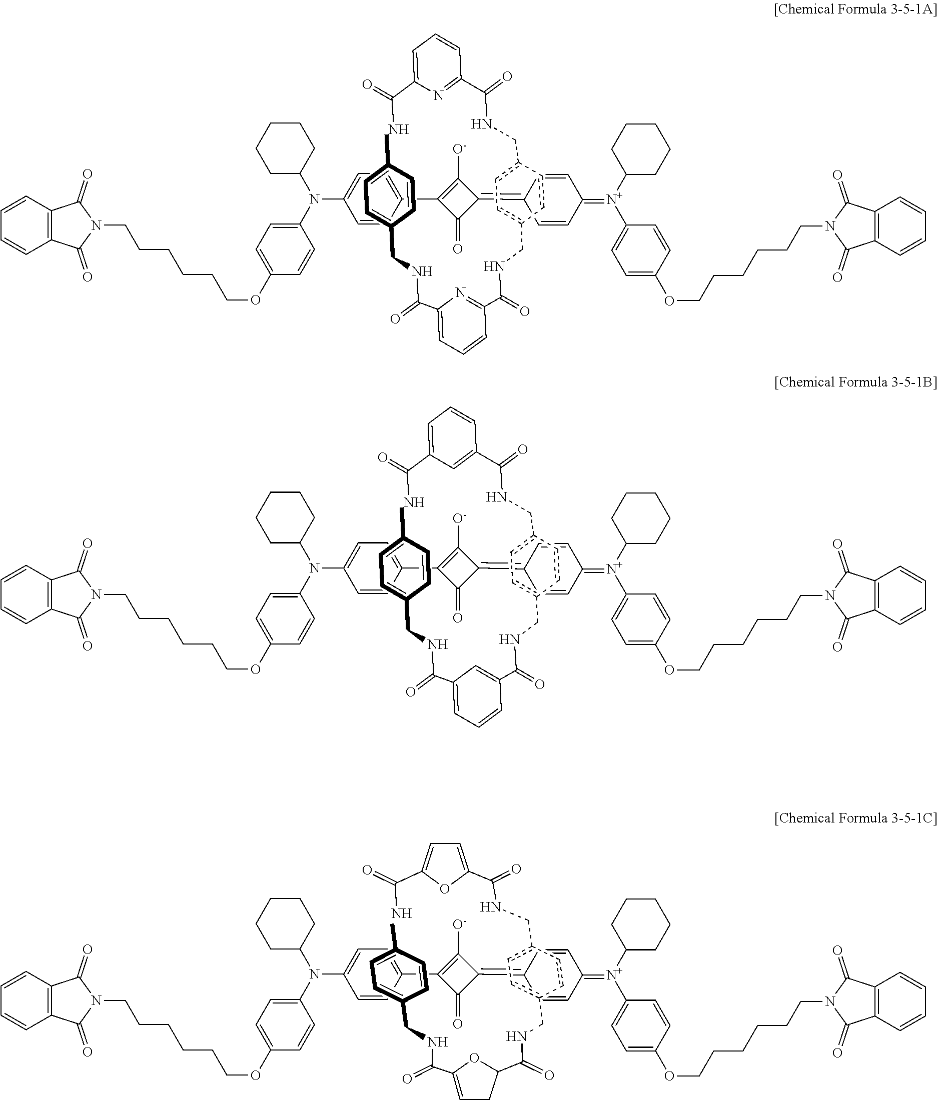

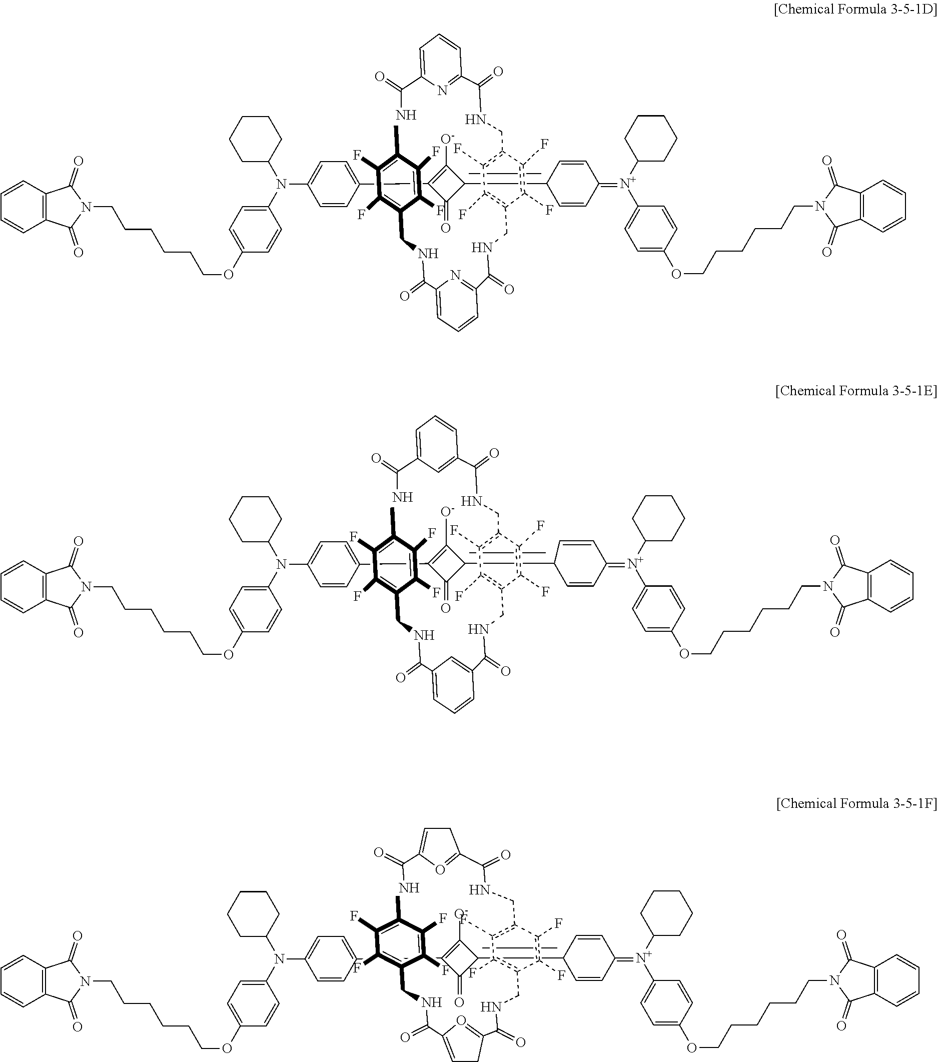

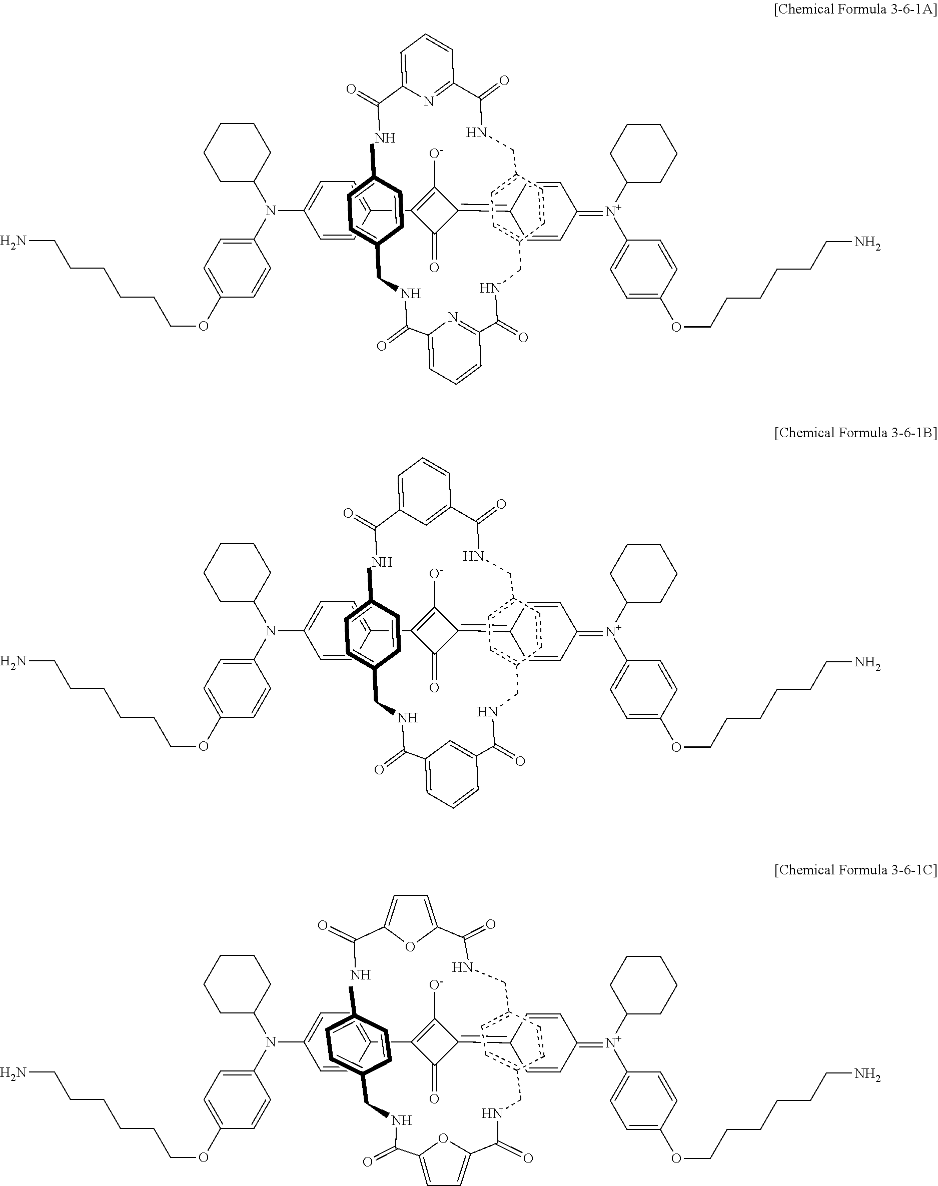

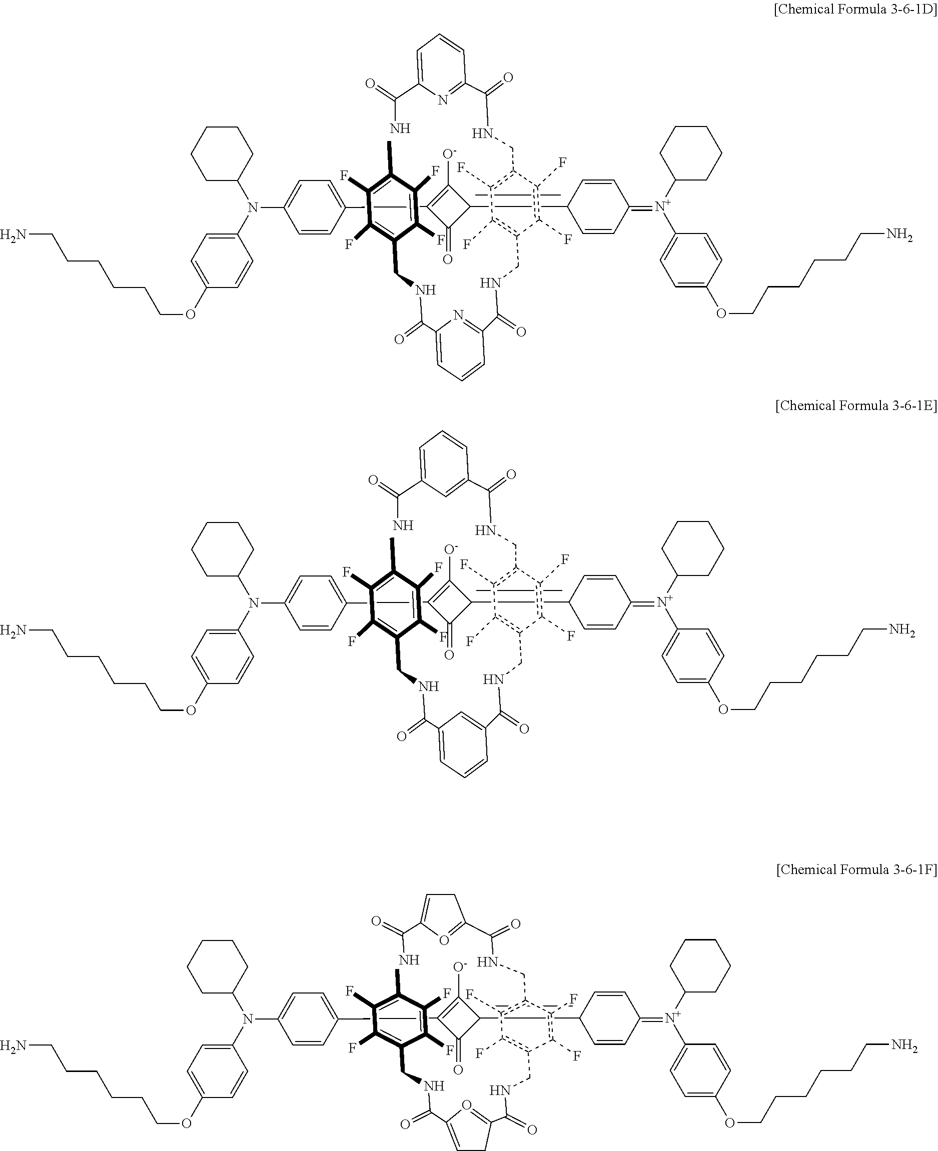

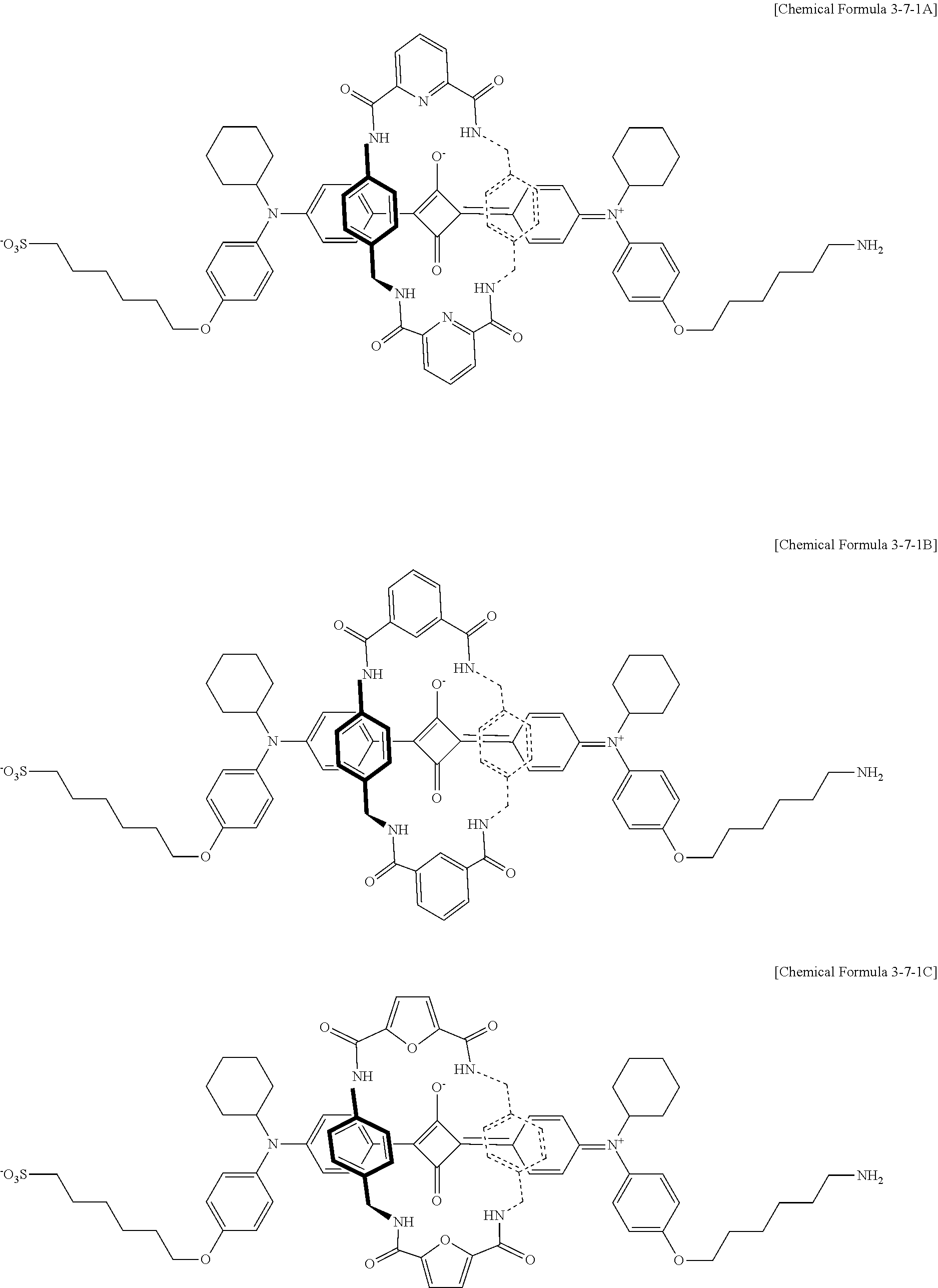

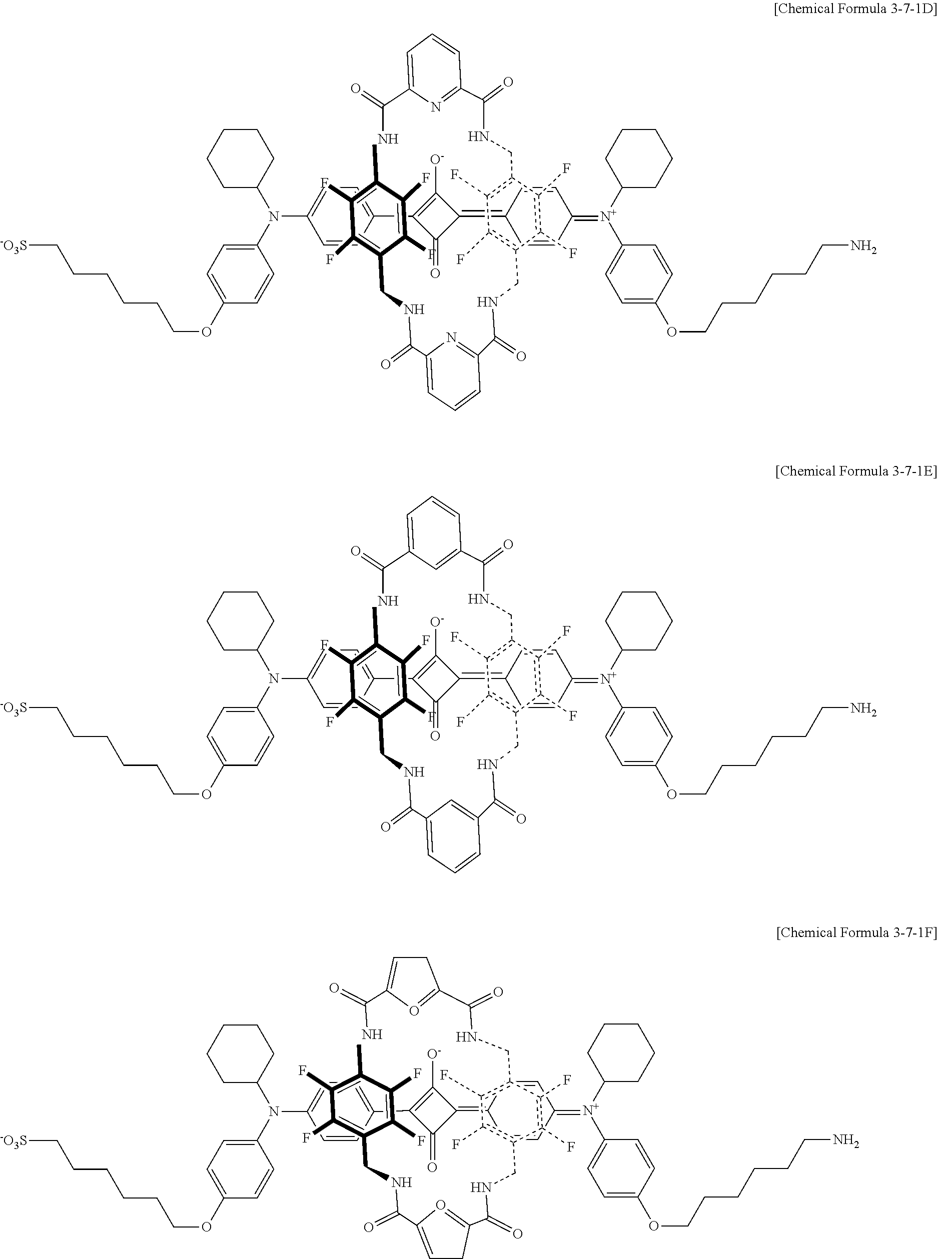

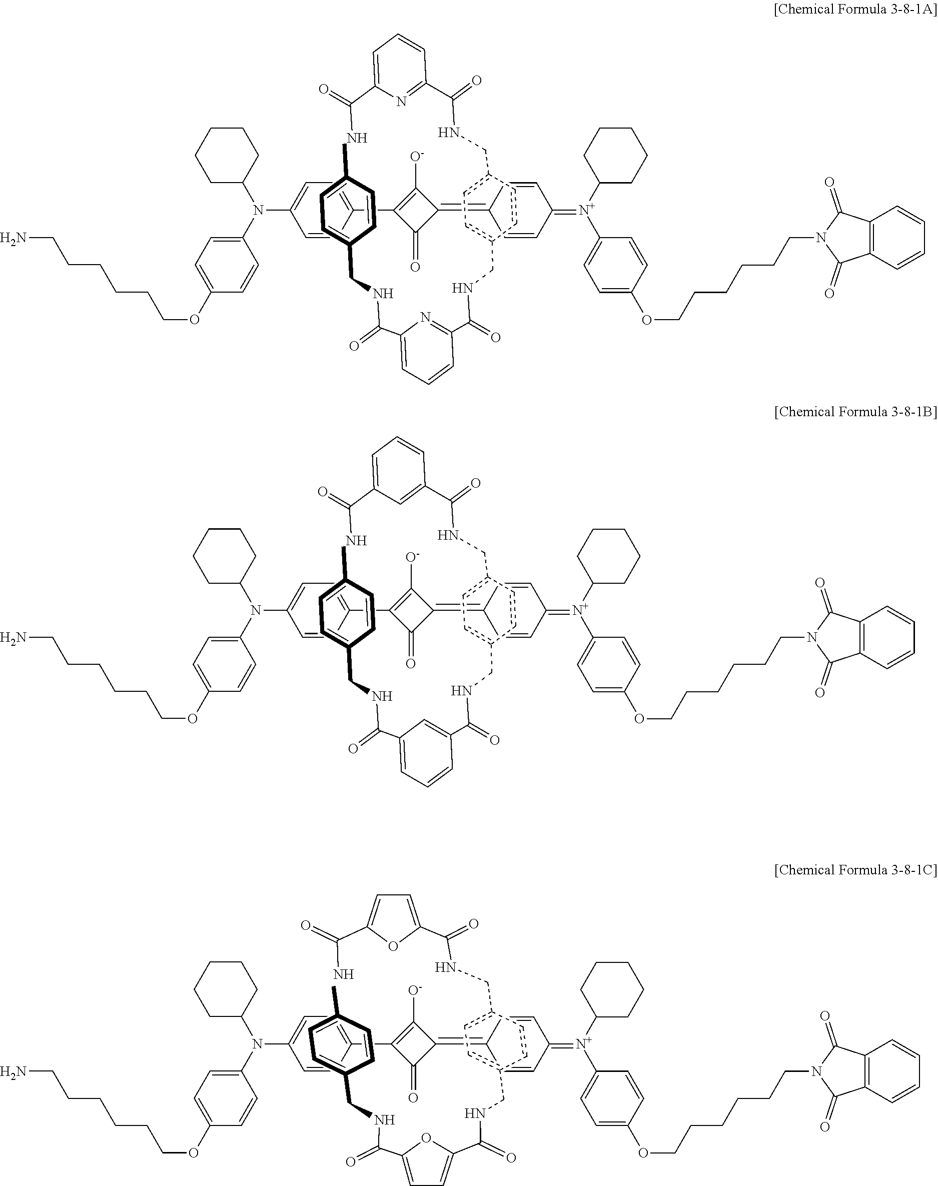

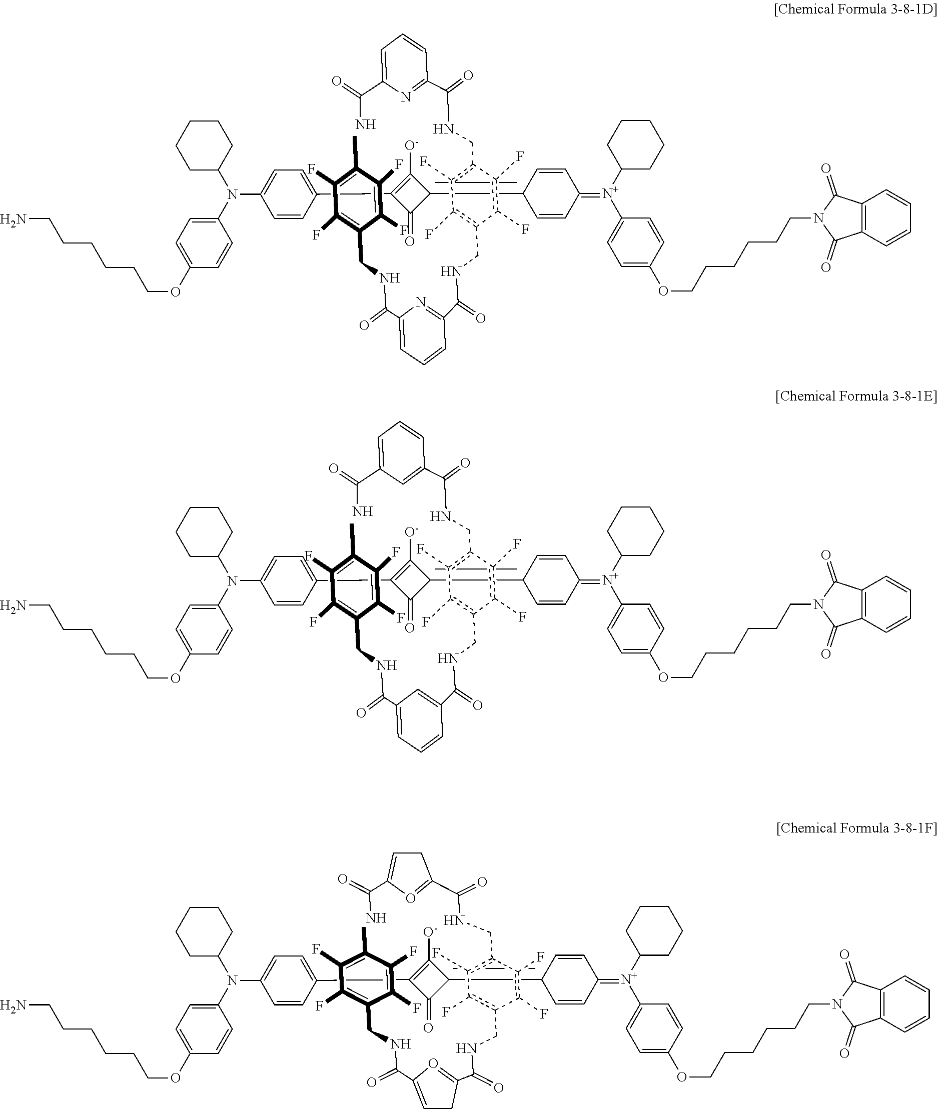

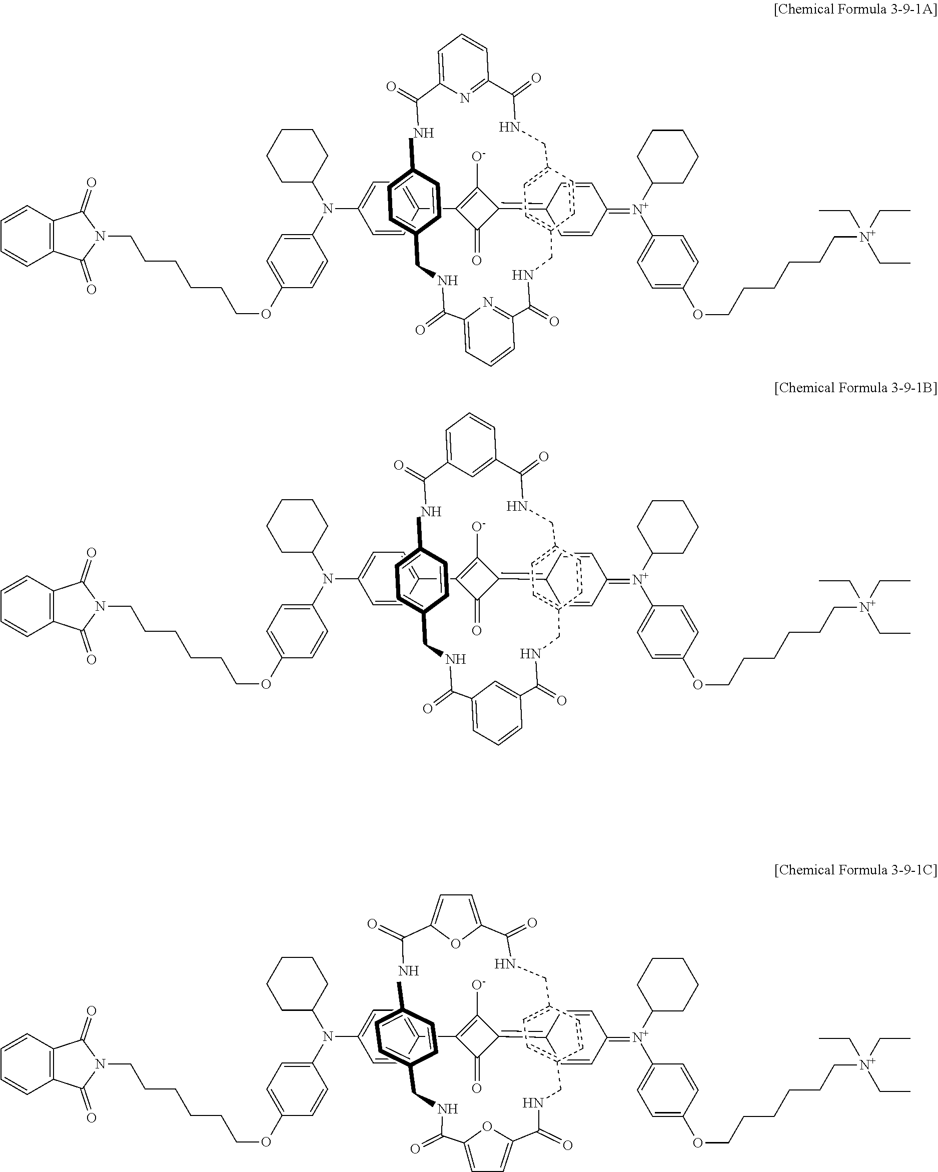

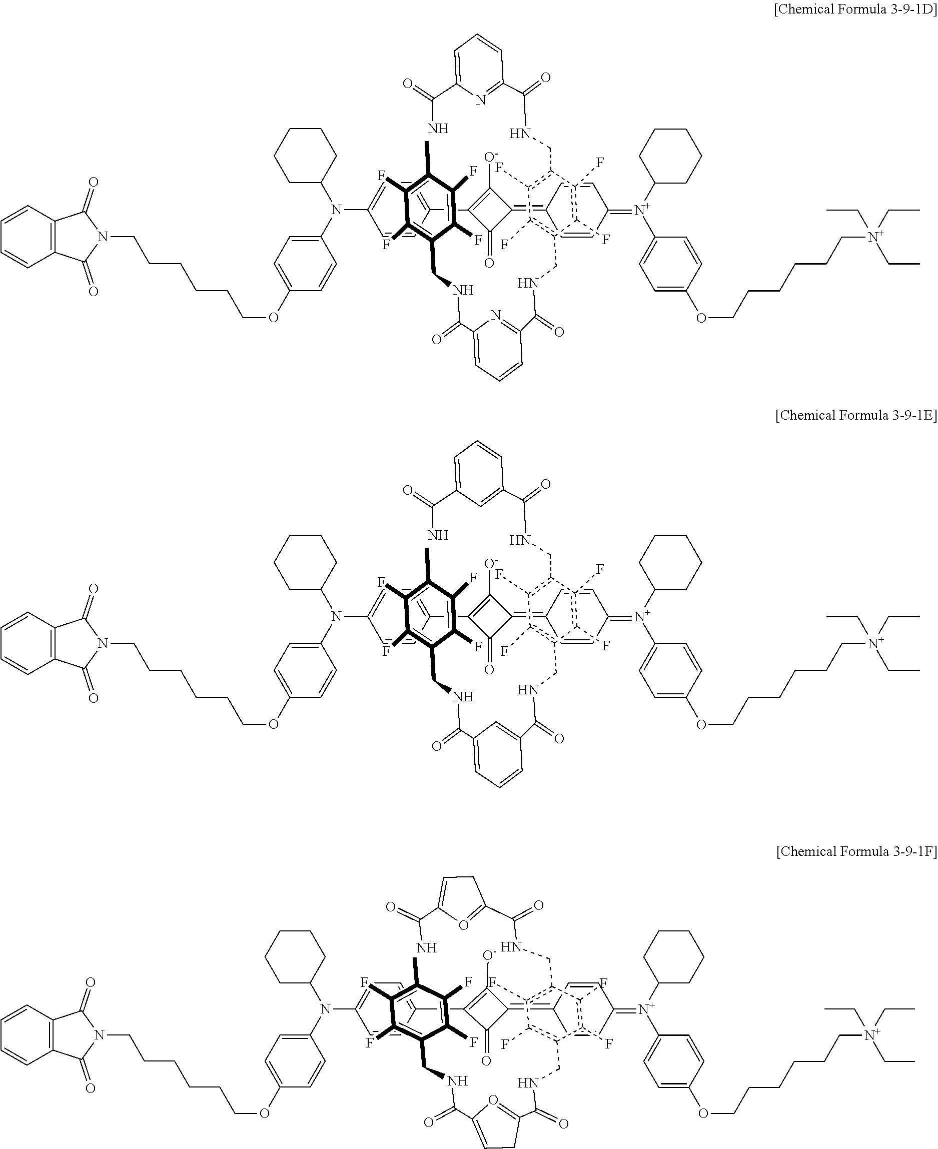

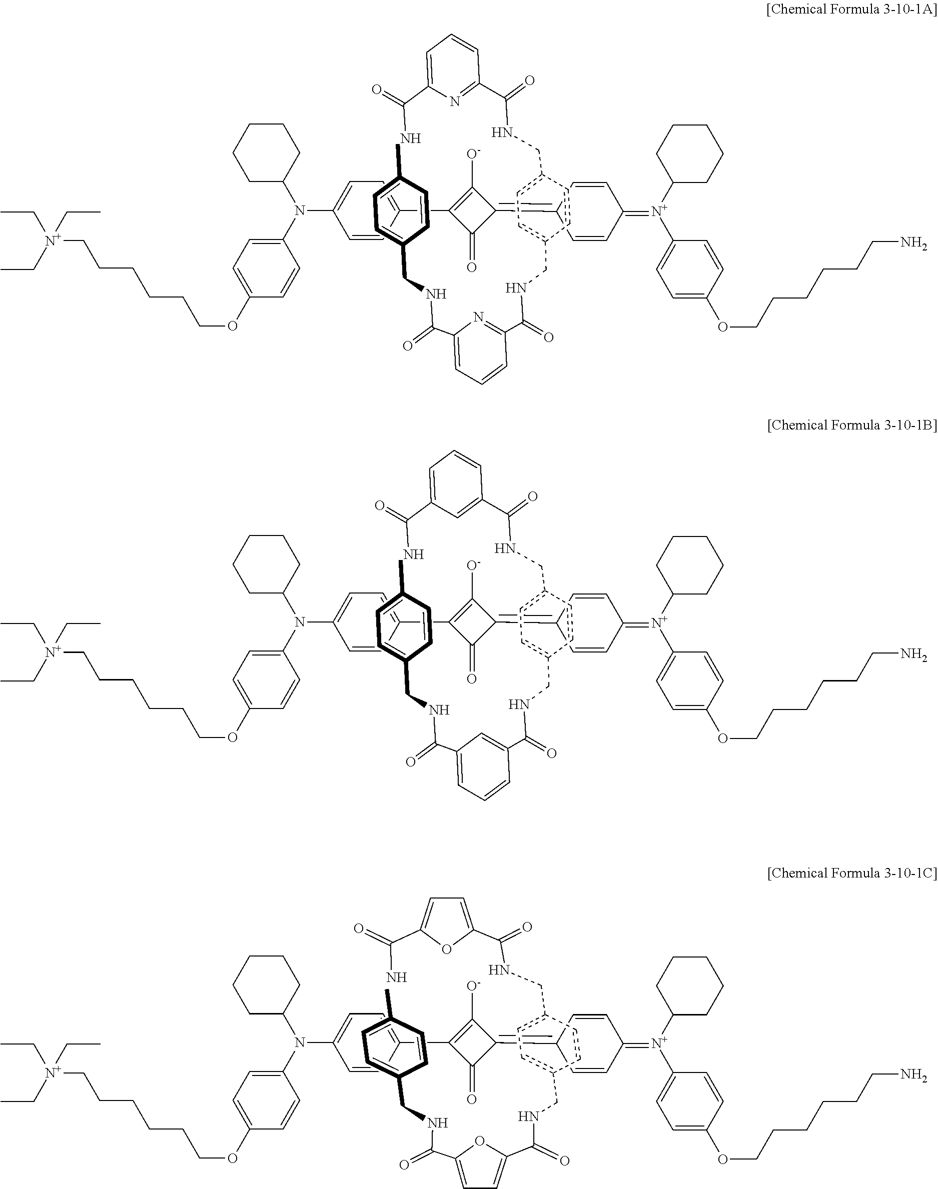

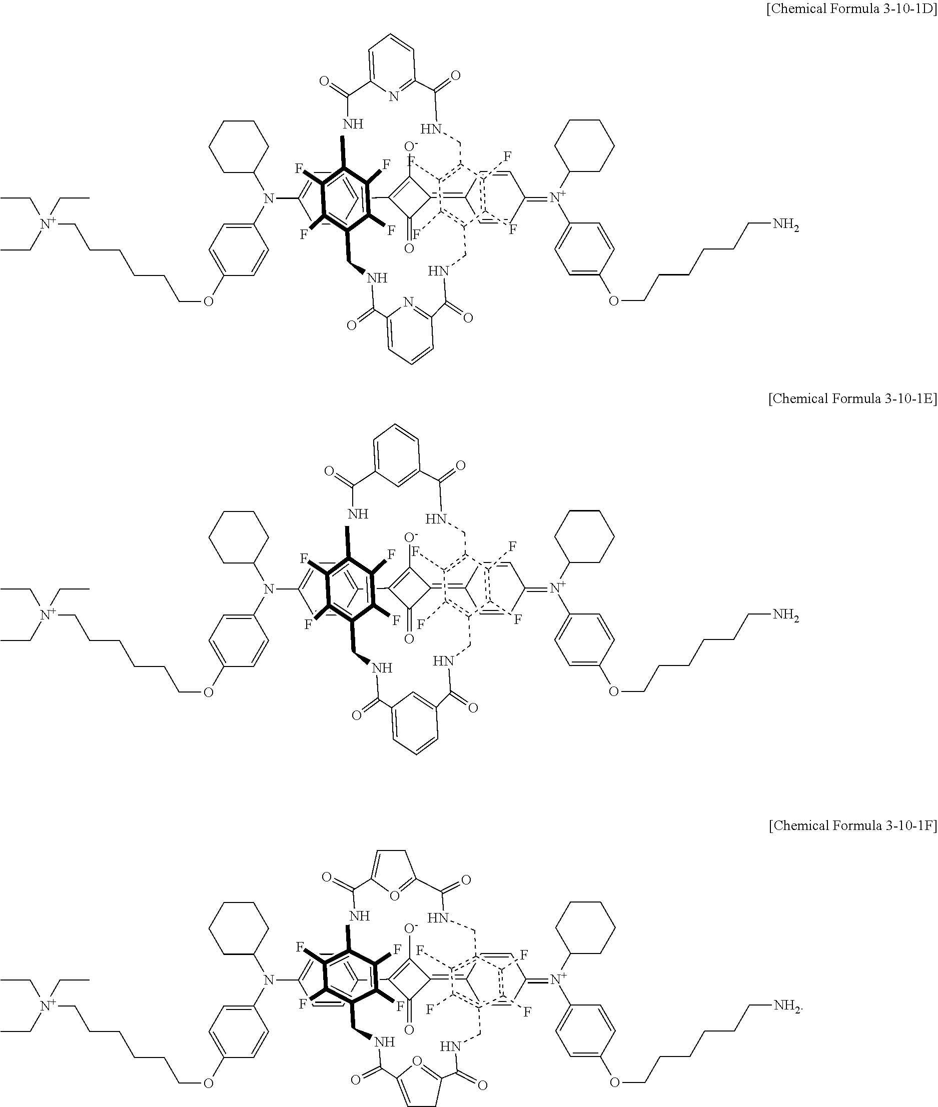

13. The photosensitive resin composition as claimed in claim 1, wherein the dispersion aid has a maximum absorption wavelength of about 530 nm to about 700 nm.

14. The photosensitive resin composition as claimed in claim 1, wherein the dispersion aid is included in the composition in an amount of about 0.01 wt % to about 10 wt %, based on a total weight of the photosensitive resin composition.

15. The photosensitive resin composition as claimed in claim 1, wherein a weight ratio of the dispersion aid and the pigment is about 1:5 to about 1:100.

16. The photosensitive resin composition as claimed in claim 1, wherein the photosensitive resin composition includes:
about 5 wt % to about 50 wt % of the colorant;
about 0.1 wt % to about 10 wt % of the photopolymerizable compound;
about 0.1 wt % to about 5 wt % of the photopolymerization initiator;
about 0.5 wt % to about 20 wt % of the binder resin; and
the solvent, all wt % being based on a total weight of the photosensitive resin composition.

17. A photosensitive resin layer manufactured using the photosensitive resin composition according to claim 1.

18. The photosensitive resin layer as claimed in claim 17, wherein the photosensitive resin layer is a color negative photoresist.

19. A color filter comprising the photosensitive resin layer according to claim 17.

20. A display device comprising the color filter according to claim 19.
